(19) United States
(12) Patent Application Publication
(10) Pub. No.: US 2012/0070944 A1
(43) Pub. Date: Mar. 22, 2012

(54) Methods of Manufacturing Three Dimensional Semiconductor Devices

(76) Inventors: Hyu-Jung Kim, Seoul (KR); Sang-Yong Park, Suwon-si (KR); JongHeun Lim, Seoul (KR); Kyunghyun Kim, Seoul (KR); ChangSup Mun, Suwon-si (KR)

(21) Appl. No.: 13/231,525

(22) Filed: Sep. 13, 2011

(30) Foreign Application Priority Data
Sep. 17, 2010 (KR) 10-2010-0091999

(51) Int. Cl. H01L 21/822

(52) U.S. Cl. 438/128; 257/E21.614

(57) ABSTRACT

Provided are methods of manufacturing a three dimensional semiconductor device. The method includes providing a substrate including a cell array region and a peripheral circuit region, forming a peripheral structure on the peripheral circuit region, forming a cell structure being thicker than the peripheral structure in the cell array region, forming an interlayer dielectric to cover the peripheral structure and the cell structure, forming a polishing stop layer on the interlayer dielectric, and planarizing the interlayer dielectric using the polishing stop layer as a planarization stop.

### CROSS-REFERENCE TO RELATED APPLICATIONS

This U.S. non-provisional patent application claims priority under 35 U.S.C. §119 to Korean Patent Application No. 10-2010-0091999, filed on Sep. 17, 2010, in the Korean Intellectual Property Office, the disclosure of which is hereby incorporated by reference.

### BACKGROUND OF THE INVENTION

Example embodiments of the inventive concepts relate generally to methods of manufacturing a semiconductor device. More particularly, example embodiments of the inventive concepts relate to methods of manufacturing a three dimensional semiconductor device.

Higher integration of semiconductor devices is desired to satisfy consumer demands for superior performance and inexpensive prices for electronic devices. In the case of semiconductor memory devices, since their integration is an important factor in determining product price, increased integration is especially desired. The integration level of typical two-dimensional or planar semiconductor memory devices is primarily determined by the area occupied by a unit memory cell. Accordingly, in such devices, integration is greatly influenced by the level of fine pattern forming technology used in their manufacture. However, the extremely expensive processing equipment needed to increase pattern fineness sets a practical limitation on increasing integration for two-dimensional or planar semiconductor devices.

To overcome such a limitation, three-dimensional semiconductor memory devices having three-dimensionally arranged memory cells have been proposed. However, in order to mass produce three-dimensional semiconductor memory devices, new process technologies are needed that can provide a lower manufacturing cost per bit than two-dimensional memory devices while maintaining or exceeding their level of reliability.

### SUMMARY

Example embodiments of the inventive concepts provide methods of easily manufacturing highly integrated three dimensional semiconductor devices.

According to example embodiments of the inventive concepts, a method of manufacturing a three-dimensional semiconductor device may include providing a substrate including a cell array region and a peripheral circuit region, forming a peripheral structure including peripheral circuits on the peripheral circuit region of the substrate, the peripheral structure exposing the cell array region of the substrate, forming a stacked layer structure including first and second layers alternatingly stacked on the substrate, the stacked layer structure having a greater height than the peripheral structure, forming a cell structure disposed on the cell array region of the substrate, forming an interlayer dielectric to cover the peripheral structure and the cell structure, forming a polishing stop layer on the interlayer dielectric, and planarizing the interlayer dielectric using a portion of the polishing stop layer disposed on the peripheral circuit region as a planarization stop.

According to other example embodiments of the inventive concepts, a method of manufacturing a three-dimensional semiconductor device may include providing a substrate including a cell array region and a peripheral circuit region, forming a stacked layer structure including first and second layers alternatingly stacked on the substrate, the stacked layer structure including a contact portion interposed between the cell array region and the peripheral circuit region to have a stepwise structure, forming penetrating structures on the cell array region, each of the penetrating structure including a semiconductor pattern penetrating the stacked layer structure, forming an interlayer dielectric having a height difference between the cell array region and the peripheral circuit region on the substrate provided with the stacked layer structure, forming a polishing stop layer on the interlayer dielectric, and planarizing the interlayer dielectric to form an interlayer insulating pattern disposed on the peripheral circuit region and the contact portion of the stacked layer structure. Planarizing the interlayer dielectric is performed using the polishing stop layer disposed on the peripheral circuit region and top surfaces of the penetrating structures as a planarization stop.

According to still other example embodiments of the inventive concepts, a method of manufacturing a three-dimensional semiconductor device may include providing a substrate including a cell array region, a peripheral circuit region, and a contact region interposed between the cell array region and the peripheral circuit region, forming a peripheral structure including peripheral circuits on the peripheral circuit region, forming a stacked layer structure including first and second layers alternatingly stacked on the cell array region, the stacked layer structure being thicker than the peripheral structure and comprising a stepwise shaped portion disposed on the contact region, forming an interlayer dielectric to cover the peripheral structure and the stacked layer structure, forming a polishing stop pattern on the interlayer dielectric, the polishing stop pattern extending from the peripheral circuit region to the contact region and overlying at least a portion of one of the first layers in the contact region, and planarizing the interlayer dielectric using the polishing stop pattern as a planarization stop point.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic block diagram illustrating a three-dimensional semiconductor memory device according to example embodiments of the inventive concepts;

FIG. 2 is a schematic circuit diagram illustrating a cell array of a three-dimensional semiconductor memory device according to example embodiments of the inventive concepts;

FIG. 3 is a perspective view illustrating a cell array of a three-dimensional semiconductor memory device according to example embodiments of the inventive concepts;

FIG. 4 is a perspective view illustrating a cell array of a three-dimensional semiconductor memory device according to example embodiments of the inventive concepts;

FIGS. 5A through 14A and 5B to FIG. 14B are sectional views illustrating a method of fabricating the three-dimensional semiconductor memory device of FIG. 4.

FIGS. 15A through 15D are enlarged sectional views of a portion A of FIG. 14B.

FIG. 16 is a sectional view of a three-dimensional semiconductor device according to modifications of the example embodiments of the inventive concepts.

FIGS. 17A through 22A and FIGS. 17B through 22B are sectional views illustrating a method of fabricating a three-dimensional semiconductor memory device according to other example embodiments of the inventive concepts.

FIGS. 23 through 29 are sectional views provided for describing modifications of other example embodiments of the inventive concepts.

FIGS. 31 through 34 are sectional views illustrating methods of fabricating a three-dimensional semiconductor memory device according to still other embodiments of the inventive concepts.

FIG. 35 is a block diagram illustrating an example of a memory system including a semiconductor memory device according to some embodiments of the inventive subject matter.

FIG. 36 is a block diagram illustrating an example of a memory card including a semiconductor memory device according to some embodiments of the inventive subject matter.

FIG. 37 is a block diagram illustrating an example of an information processing system including a semiconductor memory device according to some embodiments of the inventive subject matter.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

In a three-dimensional semiconductor memory device, forming a plurality of vertically stacked memory cells in a cell array region may result in a significant height difference between structures in the cell array region and structures in a peripheral circuit region. Thus, an interlayer dielectric formed on both the cell array region and the peripheral circuit region may have a different height (relative to the substrate) in the cell array region than in the peripheral circuit region.

It may be desirable to planarize the interlayer dielectric to reduce this height difference. However, process control for planarization of an interlayer dielectric may be difficult, resulting in undesirably small process margins. In addition, dishing may occur over the peripheral circuit region and a contact region adjacent the cell array region when planarizing the interlayer dielectric.

According to example embodiments of the inventive concepts, a polishing stop layer may be selectively formed over the peripheral circuit region before planarizing the interlayer dielectric. The polishing stop layer may reduce or prevent the dishing problem from occurring in the contact region and the peripheral circuit region as a result of planarizing the interlayer dielectric.

Furthermore, some embodiments of the inventive concept may reduce or prevent damage from occurring on contact pads on the semiconductor patterns in the cell array region as a result of planarizing the interlayer dielectric. The process of forming contact plugs and interconnection lines can thereby be performed with a sufficient process margin.

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of this specification and the relevant art and will not be interpreted in an idealized or overly formal sense unless expressly so defined herein.

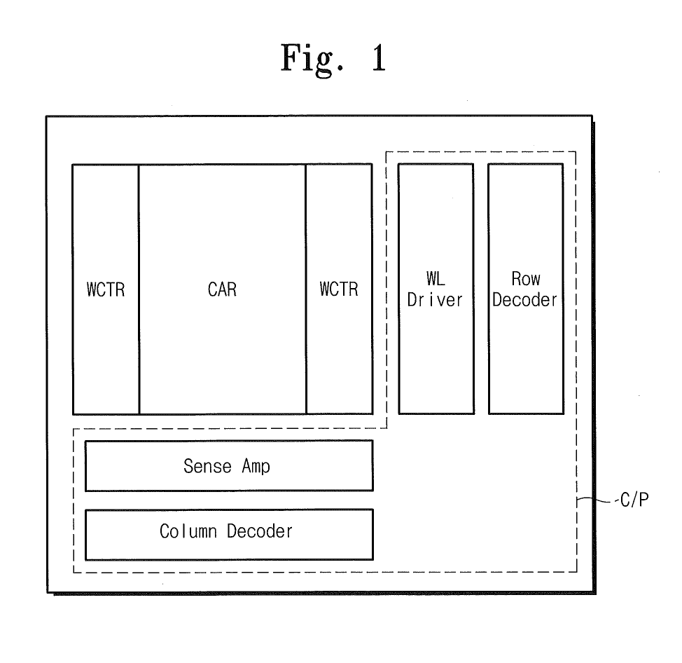

FIG. 1 is a schematic block diagram illustrating a three-dimensional semiconductor memory device according to example embodiments of the inventive concepts.

Referring to FIG. 1, the semiconductor memory device according to example embodiments of the inventive concepts may include a cell array region CAR, a word line contact region WCTR and a peripheral circuit region C/P.

In the cell array region CAR, memory cells may be three-dimensionally arranged, and bit lines and word lines may be electrically coupled to the memory cells. The word line contact region WCTR may be disposed between the cell array region CAR and the peripheral circuit region C/P, and contact plugs and interconnection lines may be disposed in the word line contact region WCTR to connect the memory cells with peripheral circuits. The peripheral circuits, which are configured to change or determine data stored in the memory cells, may be formed in the peripheral circuit region C/P. For example, the peripheral circuits may include word line drivers, sense amplifiers, row and column decoders, control circuits, etc.

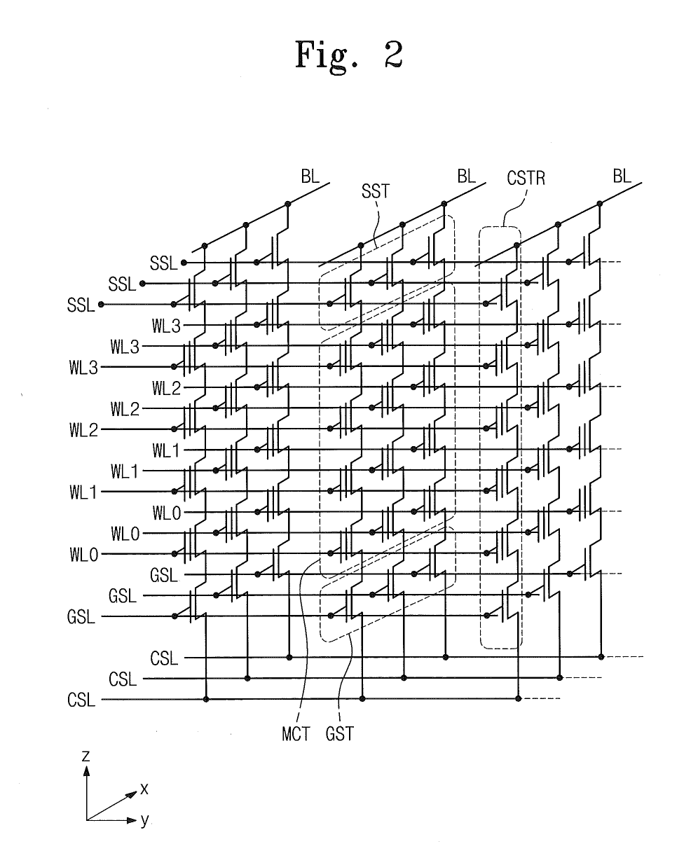

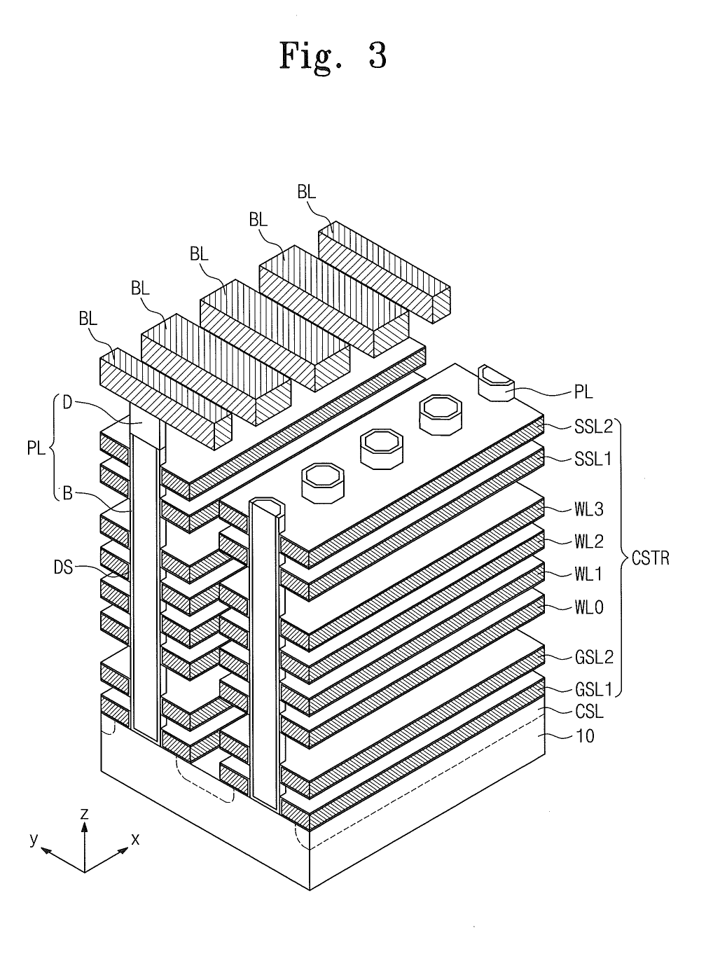

FIGS. 2 and 3 are a schematic circuit diagram and a perspective view, respectively, of a cell array of a three-dimensional semiconductor memory device according to example embodiments of the inventive concepts.

Referring to FIG. 2, in some embodiments, the cell array of the three-dimensional semiconductor memory device may include at least one common source line CSL, a plurality of bit lines BL and a plurality of cell strings CSTR interposed between the common source line CSL and the bit lines BL.

The bit lines BL may be two-dimensionally arranged and the plurality of the cell strings CSTR may be connected in parallel to each of the bit lines BL. The cell strings CSTR may be connected in common to the common source line CSL. In other words, the plurality of the cell strings CSTR may be disposed between each of the bit lines BL and the common source line CSL. The cell array region CAR may include a plurality of common source lines CSL two-dimensionally arranged. Here, in some embodiments, the common source lines CSL may be connected with one another in an equipotential state. Otherwise, in other embodiments, the common source lines CSL may be separated from one another such that they are controlled independently.

Each of the cell strings CSTR may include a ground selection transistor GST coupled to the common source line CSL, a string selection transistor SST coupled to the bit line BL, and a plurality of memory cell transistors MCT disposed between the ground and string selection transistors GST, SST. Here, the ground selection transistor GST, the memory cell transistors MCT, and the string selection transistor SST may be connected in series.

Sources regions of the ground selection transistors GST may be connected in common to the common source line CSL. In addition, at least one ground selection line GSL, a plurality of word lines WL0 to WL3 and a plurality of string selection lines SSL, which serve as gate electrodes of the ground selection transistor GST, the memory cell transistors MCT and the string selection transistors SST, respectively, may be disposed between the common source line CSL and the bit lines BL. Moreover, each of the memory cell transistors MCT may include a data storage element.

Referring to FIG. 3, the common source line CSL may be provided as a conductive layer on a substrate 10 or provided as an impurity region in the substrate 10. The bit lines BL may be conductive patterns (e.g., metal lines) disposed over the substrate 10. The bit lines BL may be two-dimensionally arranged over the substrate 10 and the plurality of the cell strings CSTR may be connected in parallel to each of the bit lines BL. Accordingly, the cell strings CSTR may be two-dimensionally disposed on the common source line CSL or the substrate 10.

Each of the cell strings CSTR may include a plurality of ground selection lines GSL1 and GSL2 interposed between the common source line CSL and the bit lines BL, a plurality of word lines WL0 to WL3, and a plurality of string selection lines SSL and SSL2. In some embodiments, the string selection lines SSL1 and SSL2 may be used as the string selection line SSL of FIG. 2, and the ground selection lines GSL1 and GSL2 may be used as the ground selection line GSL of FIG. 2. In addition, the ground selection lines GSL1 and GSL2, the word lines WL0 to WL3 and the string selection lines SSL1 and SSL2 may be conductive patterns stacked on the substrate 10.

Each of the cell strings CSTR may include a semiconductor pillar PL (or vertical semiconductor pattern), which may extend vertically from the common source line CSL and be connected to the bit line BL. The semiconductor pillar PL may penetrate the ground selection lines GSL1 and GSL2, the word lines WL0 to WL3 and the string selection lines SSL1 and SSL2. In other words, the semiconductor pillar PL may penetrate a plurality of conductive patterns stacked on the substrate 10. In addition, the semiconductor pillar PL may include a body portion B and at least one pillar impurity region D. The pillar impurity region D may be formed in one or two end portions of the semiconductor pillar PL; for example, a drain region, one of the pillar impurity regions D, may be formed in a top portion of the semiconductor pillar PL (i.e., between the body portion B and the bit line BL).

A data storing layer DS may be disposed between the word lines WL0 to WL3 and the semiconductor pillars PL. In some embodiments, the data storing layer DS may include a charge storing layer in which electrical charges can be stored. For example, the data storing layer DS may include one of a trap insulating layer, a floating gate electrode, or an insulating layer with conductive nanodots.

A dielectric layer serving as a gate dielectric layer of vertical transistor may be disposed between the ground selection lines GSL1 and GSL2 and the semiconductor pillar PL or between the string selection lines SSL1 and SSL2 and the semiconductor pillar PL. In certain embodiments, the dielectric layer may be formed of the same material as the data storing layer DS. Otherwise, the dielectric layer may be formed of a material different from the data storing layer DS: for example, it may be formed of silicon oxide.

In the above described structure, the semiconductor pillar PL may serve as a channel region of a metal-oxide-semiconductor field effect transistor (MOSFET), and the ground selection lines GSL1 and GSL2, the word lines WL0 to WL3, and the string selection lines SSL1 and SSL2 may serve as gate electrodes of the MOSFETs. In detail, the word lines WL0 to WL3 may serve as gate electrodes of memory cell transistors, and the ground selection lines GSL1 and GSL2 and the string selection lines SSL1 and SSL2 may serve as gate electrodes of selection transistors. Here, the selection transistors may be, for example, configured to control an electrical connection between the bit line or common source line BL or CSL and the channel region of the memory cell transistor. In some aspects of the inventive concepts, it can be understood that the semiconductor pillar PL constitutes MOS capacitors along with the ground selection lines GSL1 and GSL2, the word lines WL0 to WL3 and the string selection lines SSL1 and SSL2.

Energy band structures of the semiconductor pillars PL may be controlled by voltages applied to the ground selection lines GSL1 and GSL2, the word lines WL0 to WL3, and the string selection lines SSL1 and SSL2. For example, portions of the semiconductor pillars PL adjacent to the word lines WL0 to WL3 may be placed in an inversion state due to the voltages applied to the word lines WL0 to WL3. In addition, for example, other portions of the semiconductor pillars PL between the word lines WL0 to WL3 may also become in an inversion state due to a fringe field generated from the word lines WL0 to WL3. According to some embodiments, the word lines WL0 to WL3 and the selection lines SSL1 and SSL2 may be formed closely in such a way that a distance between two adjacent ones of them is shorter than half a vertical width of an inversion region induced by the fringe field. In this case, depending on the voltages applied to the lines GSL1, GSL2, SSL1, SSL2, and WL0 to WL3, the inversion regions can vertically overlap with each other, and the common source line CSL can be electrically connected to a selected bit line.

In other words, the cell string CSTR may be configured such that the selection transistors (e.g., ground and string selection transistors including the lower and upper selection lines GSL1, GSL2, SSL1 and SSL2) and the memory cell transistors (e.g., MCT of FIG. 2) are electrically connected in series.

An operation of the three-dimensional semiconductor memory device described with reference to FIGS. 2 and 3 will be briefly described below, but example embodiments of the inventive concepts may not be limited thereto and be modified in various manners.

To begin with, a program operation for writing data on memory cells will be described. The same voltage may be applied to the word lines WL0 to WL3 at the same layer and respectively different voltages may be applied to the word lines WL0 to WL3 at respectively different layers. Moreover, a program voltage V_{PGM} is applied to the word lines WL0 to WL3 of a layer including a selected memory cell and a pass voltage V_{PASS} is applied to the word lines WL0 to WL3 of an unselected layer. Here, the program voltage is a high voltage of about 10 V to about 20 V and the pass voltage V_{PASS} is a voltage for turning on memory cell transistors. Additionally, about 0 V is applied to a bit line BL connected to a selected memory cell transistor and a voltage Vcc (i.e., a power supply voltage) is applied to other bit lines BL. Moreover, about 0 V (i.e., a ground voltage) is applied to the ground selection lines GSL so that all the ground selection transistors are turned off. Furthermore, a voltage Vcc is applied to the selected string selection line SSL and about 0 V is applied to the unselected string selection line SSL. Under this voltage condition, a selected string selection transistor SST and memory cell transistors MCT in the selected cell string CSTR may be turned on. Therefore, a channel of the memory cell transistors MCT in the selected cell string CSTR is equipotential with the selected bit line BL (i.e., about 0 V). At this point, since a program voltage VPGM of a high voltage is applied to the word lines WL0 to WL3 of the selected memory cell transistor MCT, an F-N tunneling phenomenon occurs so that data may be written on the selected memory cell transistor.

Then, a read operation for reading data written on memory cells will be described. The same voltage may be applied to the word lines WL0 to WL3 at the same layer and respectively different voltages may be applied to the word lines WL0 to WL3 at respectively different layers. In more detail, for a read operation, about 0 V is applied to the word lines WL0 to WL3 connected to a selected memory cell transistor MCT and a read voltage Vread is applied to the word lines WL0 to WL3 of unselected memory cell transistors at a different layer. Here, the read voltage Vread is a voltage for turning on the unselected memory cell transistors. Moreover, a bit line voltage of about 0.4 V to about 0.9 V may be applied to a selected bit line BL and about 0 V is applied to other bit lines BL. Moreover, about 0 V is applied to the common source line CSL and a read voltage Vread is applied to the ground selection lines GSL, so that a channel of the selected memory cell transistor MCT may be connected to the common source line CSL. Additionally, a read voltage Vread is applied to the selected string selection line SSL and about 0 V is applied to the unselected string selection line SSL. Under this voltage condition, according to data (0 or 1) of the selected memory cell, the memory cell transistor MCT may be turned on or off. When the selected memory cell transistor MCT is turned on, current flow may occur in the cell string CSTR and a change of current flowing in the cell string CSTR may be sensed through the selected bit line BL.

For example, after electrons are stored in the selected memory cell transistor MCT, the selected memory cell transistor MCT is turned off and a voltage of the selected bit line BL is not delivered to the common source line CSL. Unlike this, when electrons are not stored in the selected memory cell transistor MCT, the selected memory cell is turned on by a read voltage and a voltage of the bit line BL is delivered to the common source line CSL.

Then, an erase operation of a three-dimensional semiconductor memory device will be described. In some embodiments, the erase operation may be performed by emitting charges stored in the memory cell transistor MCT to the semiconductor pillar PL. In other embodiments, the erase operation may be performed by injecting charges having an opposite type to charges stored in the data storage layer into the data storage layer. In still other embodiments, one of memory cell transistors may be selected and erased or memory cell transistors MCT of a block unit may be simultaneously erased.

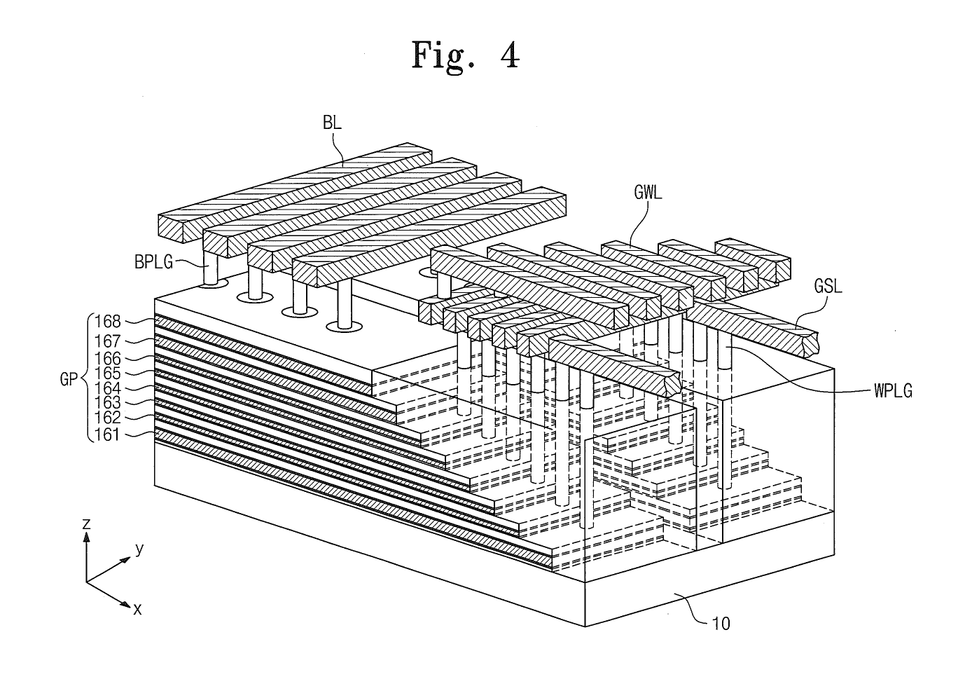

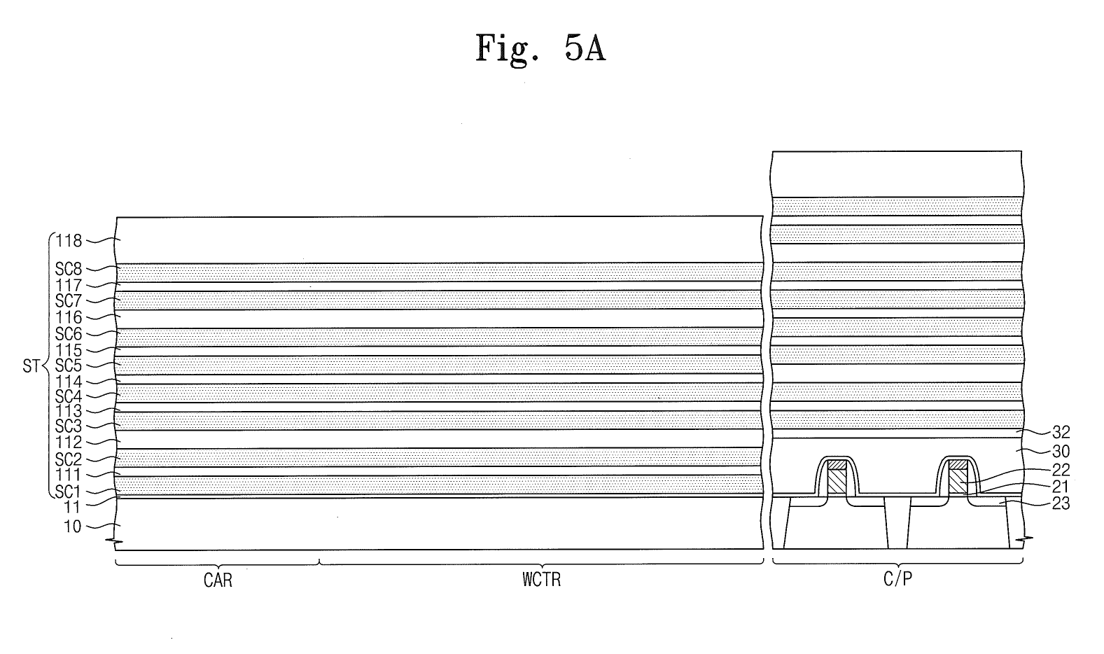

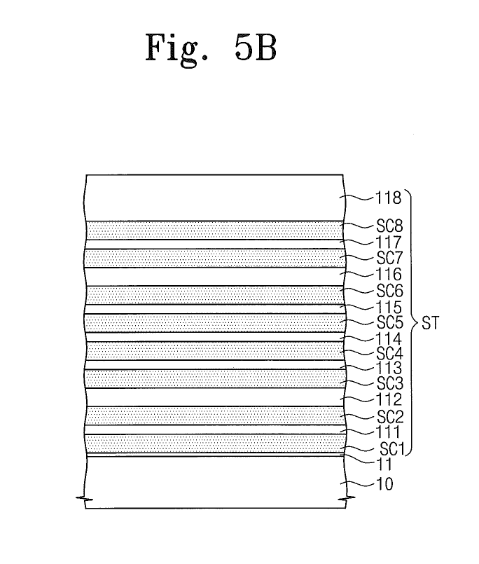

Hereinafter, methods of fabricating a three-dimensional semiconductor memory device according to example embodiments of the inventive concepts will be described in detail with reference to FIG. 4, FIGS. 5A through 14A, and FIGS. 5B through 14B.

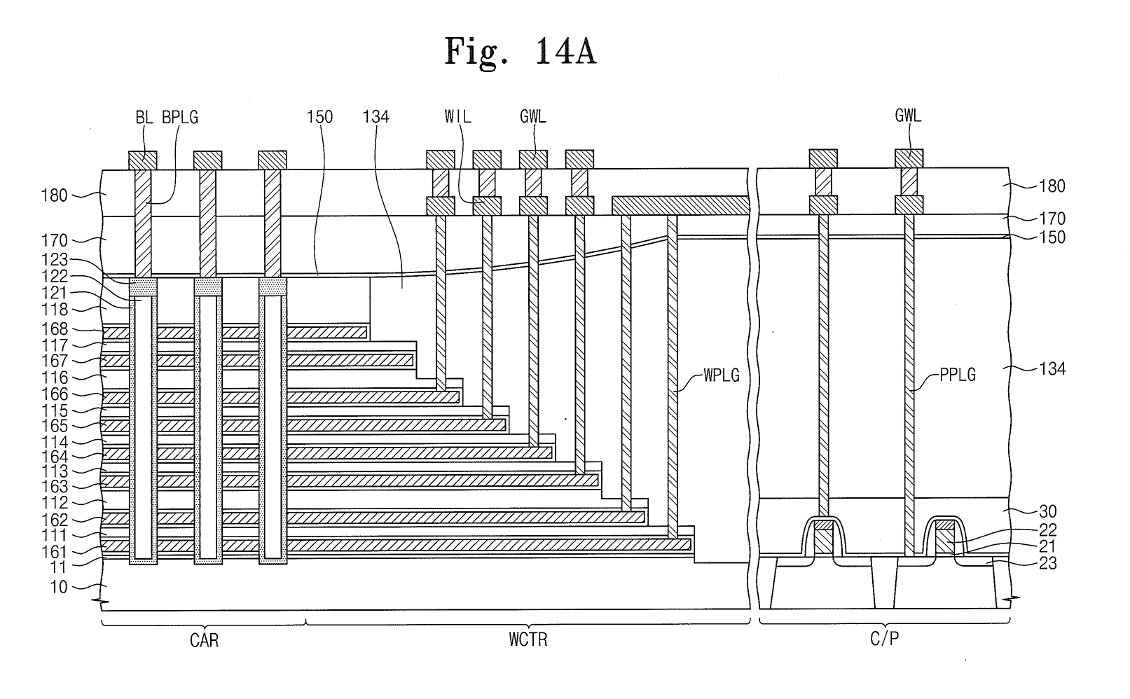

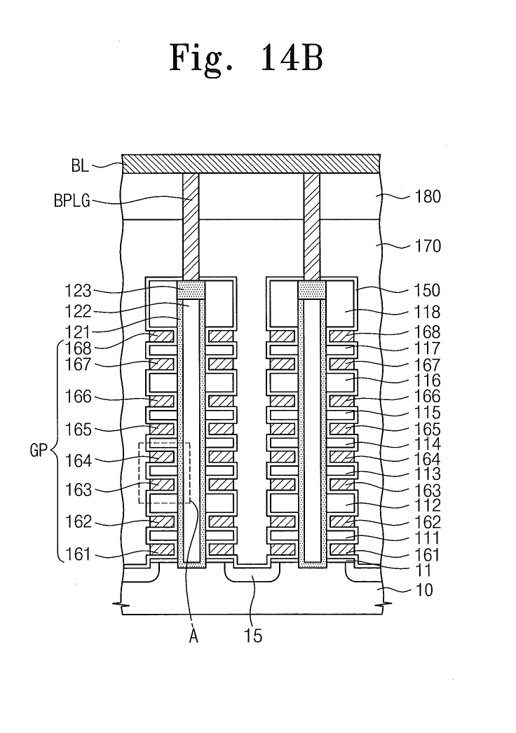

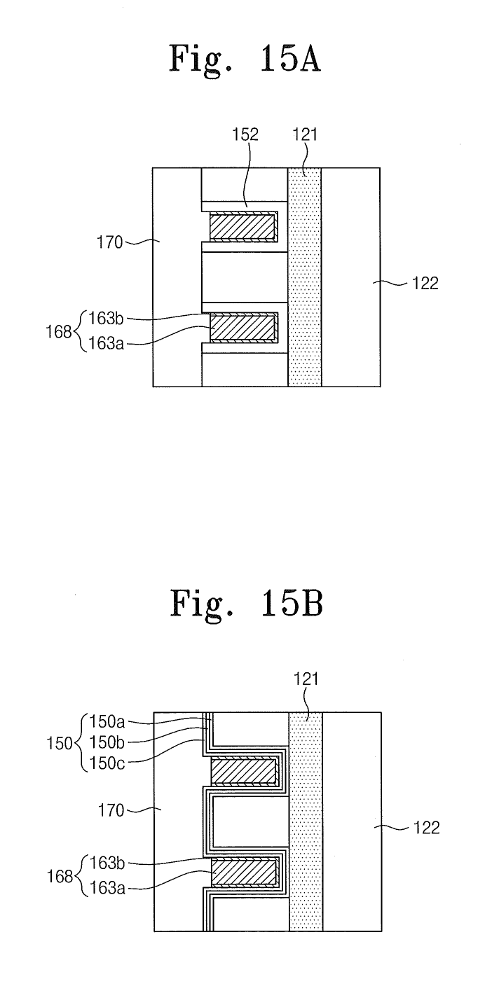

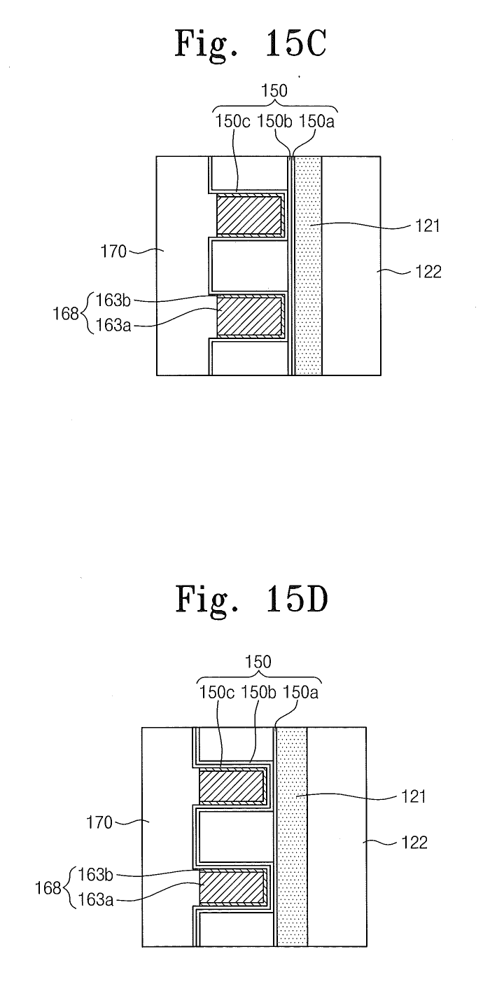

FIG. 4 is a perspective view illustrating a cell array of the three-dimensional semiconductor memory device according to the example embodiments of the inventive concepts. FIGS. 5A through 14A and 5B to FIG. 14B are sectional views illustrating methods of fabricating the three-dimensional semiconductor memory device of FIG. 4. Here, FIGS. 5A through 14A are sectional views illustrating a portion of a cell array region CAR taken parallel to a xz plane of FIG. 4 and a portion of a peripheral circuit region C/P, and FIGS. 5B through 14B are sectional views illustrating a portion of the cell array region CAR taken parallel to a yz plane of FIG. 4. FIGS. 15A through 15D are enlarged sectional views of a portion A of FIG. 14B.

Referring to FIGS. 4, 5A and 5B, peripheral circuits may be formed on a peripheral circuit region C/P of a substrate 10. Some of the peripheral circuits may be configured to write or read data to/from memory cells.

The substrate 10 may be one of a semiconductor substrate (e.g., a silicon wafer), an insulating substrate (e.g., a glass), or a conductive or semiconductor substrate covered with an insulating material. For instance, the substrate 10 may be a silicon wafer having a first conductivity type. The substrate 10 may include the cell array region CAR, the peripheral circuit region C/P and the word line contact region WCTR. Moreover, the substrate 10 may include active regions defined by device isolation layers.

The peripheral circuits may include a word line driver, a sense amplifier, row and column decoders, and control circuits, which may be the same as described with reference to FIG. 1. As shown in FIG. 5A, the peripheral circuits may include peripheral transistors formed on the peripheral circuit region C/P of the substrate 10.

In some embodiments, the peripheral transistors may be formed using the following exemplary process. A peripheral gate insulating layer and a peripheral gate layer may be sequentially stacked on the whole surface of the substrate 10. A peripheral gate pattern 22 and a peripheral gate insulating pattern 21 may be formed by sequentially patterning the peripheral gate insulating layer and the peripheral gate layer. Here, the peripheral gate pattern 22 may serve as a gate electrode of the peripheral transistor and be formed of doped polysilicon or a metallic material, and the peripheral gate insulating pattern 21 may serve as a gate insulating layer of the peripheral transistor and be formed of silicon oxide using, for example, a thermal oxidation process. Subsequently, peripheral impurity regions 23 serving as source and drain electrodes of the peripheral transistors may be formed in the substrate 10 on both sides of the peripheral gate patterns 22. In some embodiments, the lower gate insulating layer 11 may not patterned during the formation of the peripheral gate pattern 22. As a result, the lower gate insulating layer 11 may remain in the cell array region CAR to cover a top surface of the substrate 10.

Thereafter, a peripheral insulating pattern 30 may be formed on the substrate 10 provided with the peripheral transistors. In some embodiments, the peripheral insulating pattern 30 may be formed of silicon oxide and cover the peripheral circuits on the peripheral circuit region C/P.

The formation of the peripheral insulating pattern 30 may include forming an insulating layer on the whole top surface of the substrate 10 provided with the peripheral transistors and selectively removing the insulating layer from the cell array region CAR. As a result, the peripheral insulating pattern 30 may be partially disposed on the peripheral circuit region C/P to expose the cell array region CAR and the word line contact region WCTR of the substrate 10. In addition, as shown in FIG. 5A, a peripheral etch stop layer 32 may be formed on the peripheral insulating pattern 30. The peripheral etch stop layer 32 may be formed of a material (e.g., silicon nitride) having an etch selectivity with respect to the peripheral insulating pattern 30.

Thereafter, a stacked layer structure ST may be formed on the substrate 10. In some embodiments, the stacked layer structure ST may include a plurality of insulating layers 111 to 118 and a plurality of sacrificial layers SC1 to SC8, which may be formed on the entire top surface of the substrate 10. For instance, the stacked layer structure ST may be formed to cover the lower gate insulating layer 11 in the cell array region CAR and the word line contact region WCTR and to cover the peripheral etch stop layer 32 or the peripheral insulating pattern 30 in the peripheral circuit region C/P. The insulating layers 111 to 118 and the sacrificial layers SC1 to SC8 may be alternatingly deposited using deposition processes, as shown in FIGS. 5A and 5B. The insulating layers 111 to 118 and the sacrificial layers SC1 to SC8 may be formed of materials having an etch selectivity with respect to each other in a subsequent wet etching process. For instance, the insulating layers 111 to 118 may be formed of at least one of silicon oxide and silicon nitride, and the sacrificial layers SC1 to SC8 may be formed of at least one selected from silicon, silicon oxide, silicon carbide and silicon nitride, which may be different from the insulating layers 111 to 118. In some embodiments, the insulating layers 111 to 118 may be formed of silicon oxide. In addition, the insulating layers 111 to 118 may further include at least one high-k dielectric material capable of contributing to formation of an inversion region as explained with reference to FIG. 3. Here, the high-k dielectric material may be a dielectric material having a greater dielectric constant than silicon oxide. For example, the high-k dielectric material may include at least one of silicon nitride, silicon oxynitride, and/or metal oxide.

Thicknesses of the sacrificial layers SC1 to SC8 may determine channel lengths of the selection and memory cell transistors described with reference to FIG. 3. In some embodiments, the insulating layers 111 to 118 may be formed in such a way that two adjacent inversion regions induced by the fringe field can be overlap with each other. In this case, an electric path passing through each of the cell strings can be adjustably formed depending on voltages applied to the gate electrodes.

In some embodiments, the sacrificial layers SC1 to SC8 may be formed to have the substantially same thickness. In other embodiments, for the sacrificial layers SC1 to SC8, the lowermost and uppermost sacrificial layers SC1 and SC8 may be thicker than other sacrificial layers SC2 to SC7 interposed therebetween. Here, the intervening sacrificial layers SC2 to SC7 may be formed to have the substantially same thickness.

The insulating layers 111 to 118 may be formed to have the substantially same thickness. Alternatively, the uppermost insulating layer 118 may be thicker than other insulating layers 111 to 117 disposed thereunder. Here, the underlying insulating layers 111 to 117 may be formed to have the substantially same thickness. In other embodiments, at least one of the insulating layers 111 to 118 (for instance, insulating layers between the lower selection line and the word line and between the upper selection line and the word line in FIG. 3) may be thicker than one of the remaining insulating layers, as shown.

In some embodiments, a height of the stacked layer structure ST on the substrate of the cell array region CAR may be at least two times greater than that of the peripheral insulating pattern on the peripheral circuit region. For instance, the height of the stacked layer structure ST may be in a range of about 10,000 Å to about 40,000 Å. In some embodiments, the number of layers constituting the stacked layer structure ST may be 2n or 2n+1 where n is a positive integer, and in this case, the peripheral gate pattern 22 may have a top surface located between the substrate 10 and the n-th layer in terms of vertical position.

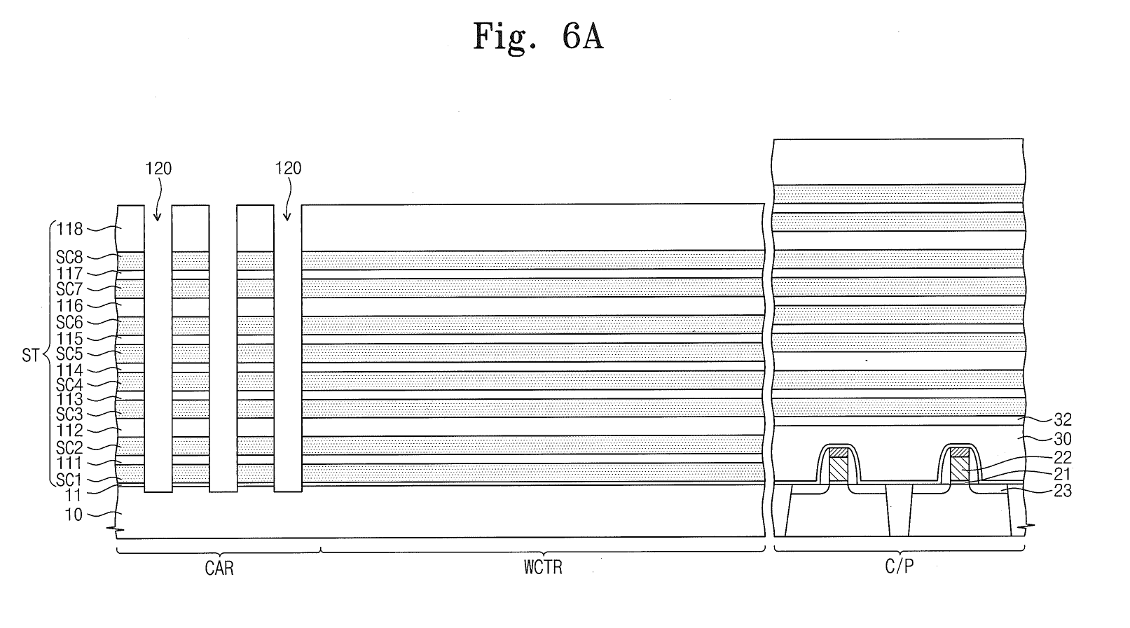

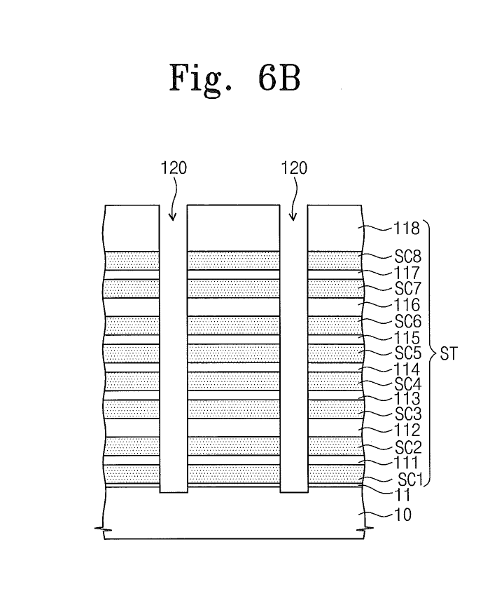

Referring to FIGS. 4, 6A and 6B, the stacked layer structure ST may be patterned to form openings 120 exposing the substrate 10 of the cell array region CAR.

For instance, the formation of the openings 120 may include forming a mask pattern (not shown) defining arrangement of the openings 120 on the stacked layer structure ST and anisotropically etching the stacked layer structure ST using the mask pattern as an etch mask.

The openings 120 may be formed to expose or define inner walls of the sacrificial layers SC1 to SC8 and insulating layers 111 to 118. Furthermore, the openings 120 may penetrate the lower gate insulating layer 11 to expose a top surface of the substrate 10. In some embodiments, as the result of over-etching during the formation of the openings 120, the substrate 10 under the opening 120 may be recessed by a specific depth.

A depth of the opening 120 may be at least five times greater than a width of the opening 120, and as the result of the anisotropic etching process, a width of the opening 120 may vary depending on a distance from the substrate 10. For instance, a width of the opening 120 may be proportional to a distance from a top surface of the substrate 10.

In some embodiments, the openings 120 may be two-dimensionally arranged and/or regularly arranged on the substrate 10 or xy-plane of FIG. 4, and each of the openings 120 may be shaped like a cylinder or rectangular parallelepiped. In other word, the openings 120 may be empty spaces spaced apart from each other.

In other embodiments, from a plan view, each of the openings 120 may be shaped like a linear trench, and the linear openings 120 may be formed parallel with each other. In still other embodiments, the openings 120 may be arranged in a zigzag manner. In this case, a density of the openings 120 may be increased due to the zigzag arrangement of the openings 120.

In other embodiments, during the formation of the openings 120 in the cell array region CAR, the stacked layer structure ST may be removed from the peripheral circuit region C/P. For instance, as a result of the etching process for forming the opening 120, a top surface of the peripheral etch stop layer 32 or the peripheral insulating pattern 30 may be exposed in the peripheral circuit region C/P.

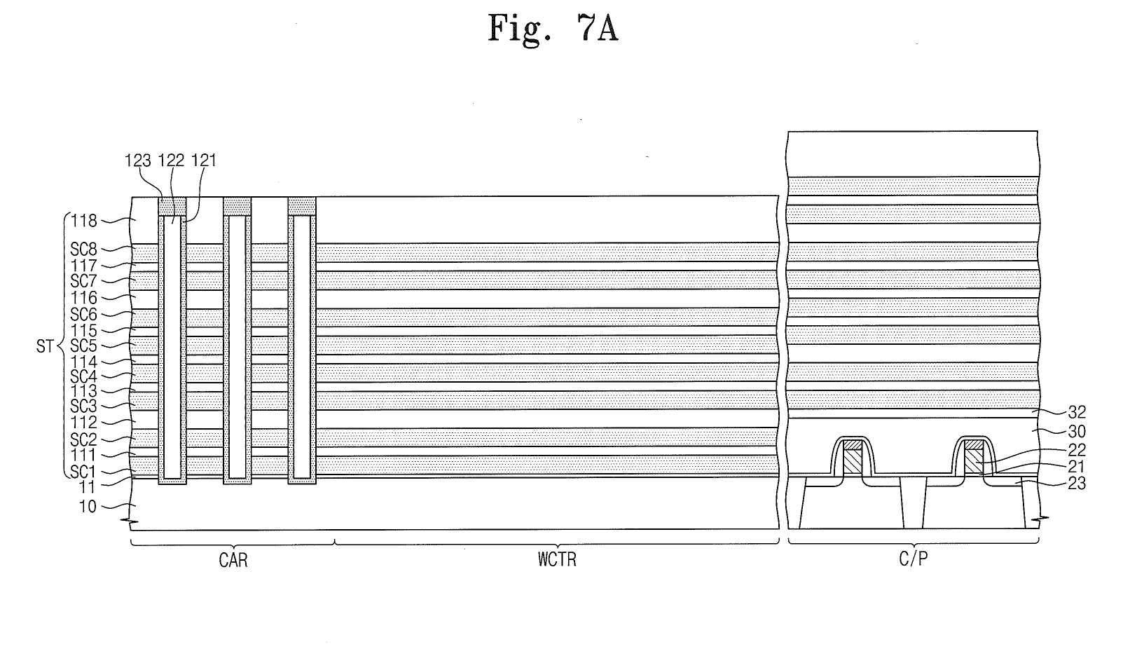

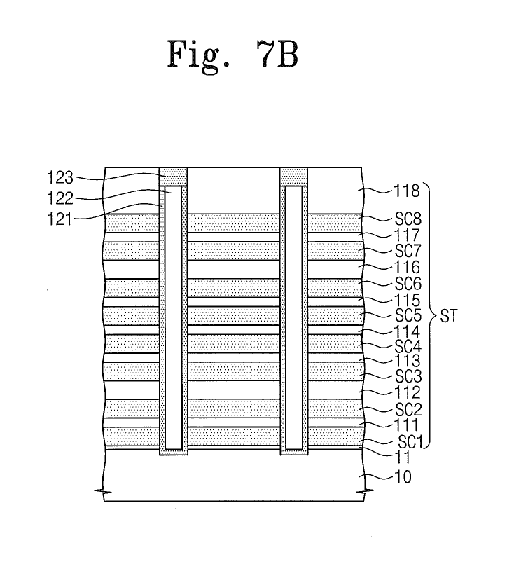

Referring to FIGS. 4, 7A and 7B, semiconductor patterns 121 may be formed in the openings 120, respectively.

The semiconductor pattern 121 may be formed of, for instance, silicon (Si), germanium (Ge), carbon (C), an organic semiconductor material or any combination thereof. In some embodiments, the semiconductor pattern 121 may be formed of a doped semiconductor or a substantially undoped semiconductor (e.g., intrinsic semiconductor). The semiconductor pattern 121 may be formed to have one of a single-crystalline structure, an amorphous structure, or a polycrystalline structure.

The semiconductor pattern 121 may be formed in the respective openings 120 by a chemical vapor deposition (CVD) process or an atomic layer deposition (ALD) process. In some embodiments, the semiconductor pattern 121 may include at least a single-crystalline structure obtained from a phase transition of an amorphous or polycrystalline silicon layer. The phase transition may be realized by a thermal treatment such as a laser annealing process. In other embodiments, the semiconductor pattern 121 may be formed in the respective openings by an epitaxial process using portions of the substrate 10 exposed by the openings 120 as a seed layer.

In some embodiments, formation of the semiconductor pattern 121 may include sequentially depositing a semiconductor layer and a gap-fill insulating layer on the stacked layer structure ST provided with the openings 120 and performing a planarization process to expose a top surface of the stacked layer structure ST. In certain embodiments, the semiconductor layer may be deposited to have a smaller thickness than half the width of the opening 120. Accordingly, the semiconductor pattern 121 may partially fill the opening 120 and define an empty space in a central portion of the opening 120. According to some aspects of the inventive concepts, a thickness of the semiconductor pattern 121 (i.e., a thickness of the semiconductor pattern 121 deposited on a sidewall of the opening 120) may be smaller than a width of a depletion region, which may be formed in the semiconductor pattern 121 during operating the semiconductor memory device, or than a mean size of polysilicon grains constituting the semiconductor pattern 121. As a result, the semiconductor pattern 121 in the opening 120 may be shaped like a pipe, a hollow cylinder, or a cup. According to other aspects of the inventive concepts, in the case that the semiconductor pattern 121 is formed using a deposition method, a discontinuous interface (e.g., an interface dislocation) may be formed between the semiconductor pattern 121 and the substrate 10 due to a difference in crystal structure therebetween. Thereafter, a gap-fill insulating pattern 122 may be formed to fill the empty space defined by the semiconductor pattern 121. The gap-fill insulating pattern 122 may be formed of an insulating material having a good gap-filling property. For instance, the gap-filling insulating pattern 122 may be formed of at least one of a high-density-plasma (HDP) oxide, a spin-on-glass (SOG) layer, or a CVD oxide.

In other embodiments, the semiconductor layer may be formed to have a thickness greater than half the width of the opening 120. Thereafter, the semiconductor layer may be planarized until the top surface of the stacked layer structure ST is exposed, and as a result, the semiconductor patterns 121 may be disposed in the openings 120, respectively. In this case, the semiconductor pattern 121 may fully fill the opening 120, thereby having a solid cylindrical shape.

In the case that the openings 120 are formed to have a linear shape, a plurality of the semiconductor patterns 121 and a plurality of insulating patterns interposed therebetween may be formed in each of the openings 120. For instance, the formation of the semiconductor patterns 121 may include sequentially forming a semiconductor layer and a gap-filling insulating layer in the openings 120, patterning the semiconductor layer and the gap-filling insulating layer to form the semiconductor patterns 121 having a rectangular shape from a top view in the opening 120. The semiconductor pattern 121 may have a substantially “U”-shape from a sectional view.

After forming the semiconductor patterns 121, contact pads 123 may be formed on the semiconductor patterns 121, respectively. In some embodiments, the contact pad 123 may be formed on a top surface of the gap-fill insulating pattern 122 and the semiconductor pattern 121. For instance, the contact pad 123 may be formed of a doped polysilicon. Alternatively, the contact pad 123 may be formed by doping an upper portion of the semiconductor pattern 121 with dopants. The contact pads 123 may have a different conductivity type from the semiconductor pattern 121, and thus, the contact pad 123 and the semiconductor pattern 121 may constitute a rectifying element, such as a diode.

In some embodiments, the formation of the contact pads 123 may include recessing top surfaces of the gap-fill insulating patterns 122 and filling gap regions formed thereby with a conductive pattern (e.g., a polysilicon pattern or a metal pattern). In other embodiments, the formation of the contact pads 123 may include depositing a conductive layer on the stacked layer structure ST provided with the semiconductor patterns 121, patterning the conductive layer to form conductive patterns on the semiconductor patterns 121, respectively. The conductive layer may include a metallic material (e.g., tungsten), and furthermore, the conductive layer may further include a barrier metal layer (e.g., metal nitride) that is deposited before forming the metal layer.

In still other embodiments, the formation of the contact pads 123 may include forming an upper insulating layer (not shown) on the stacked layer structure ST, patterning the upper insulating layer to form holes exposing the semiconductor patterns 121, and forming polysilicon patterns in the holes. In even other embodiments, the formation of the contact pads 123 may include injecting impurities, which have a different conductivity type from the semiconductor pattern 121, into an upper portion of the semiconductor patterns 121 using an ion implantation technique.

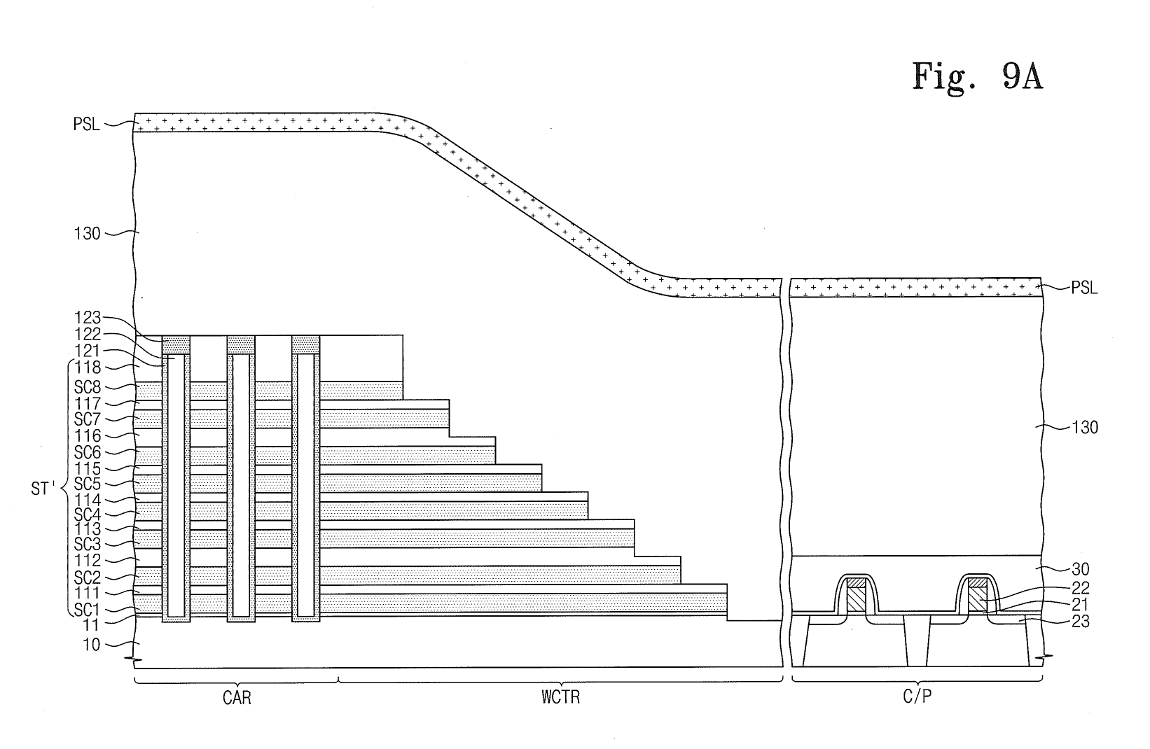

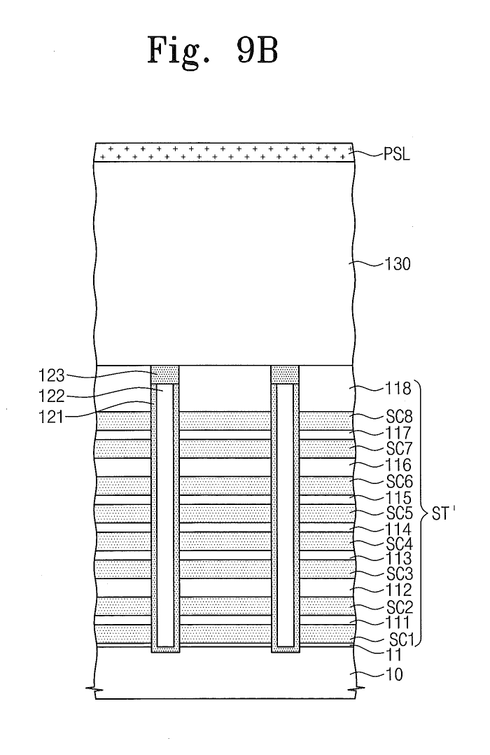

In further embodiments, the formation of the contact pads 123 on the cell array region CAR may follow a formation of gate electrodes on the substrate 10. In still further embodiments, the formation of the semiconductor patterns 121 and the contact pads 123 on the cell array region CAR may follow a formation of an interlayer insulating pattern 134 which will be described with reference to FIGS. 9A through 11A.

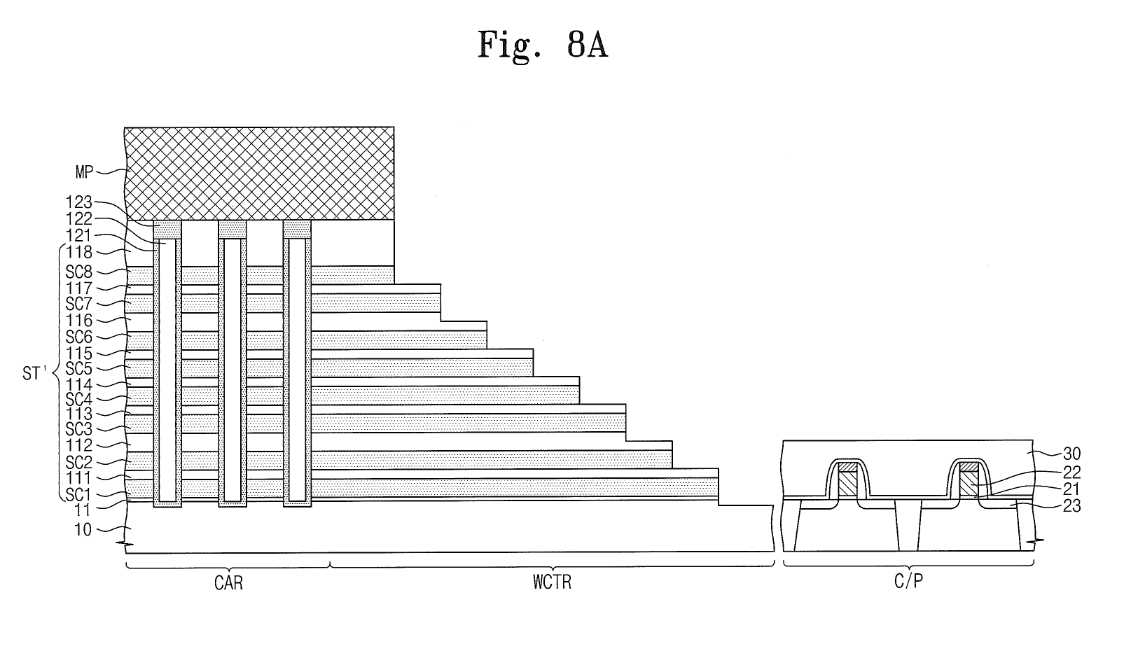

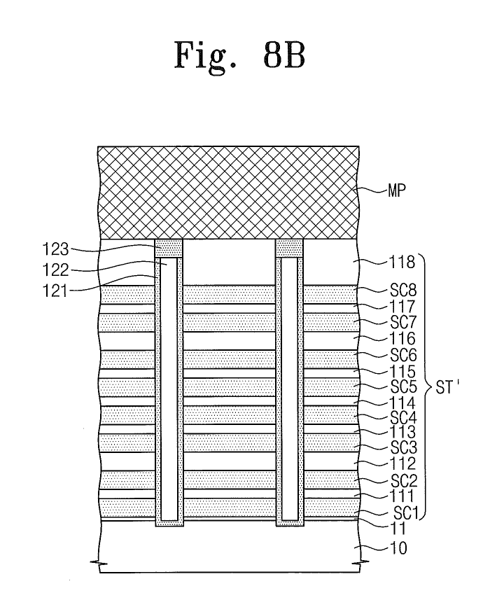

Referring to FIGS. 4, 8A and 8B, the stacked layer structure ST may be patterned to form a stepwise stacked layer structure ST′ that has a contact portion of stepwise shape on the word line contact region WCTR. Since the stepwise stacked layer structure ST′ has the contact portion of stepwise shape, word lines, which will be formed on the cell array region CAR, can be easily connected to the peripheral circuits.

In some embodiments, the patterning of the stepwise stacked layer structure ST′ may include steps of reducing a horizontal area occupied by a mask pattern MP and etching the stacked layer structure ST, which are alternately performed.

The mask pattern MP may include at least one material having an etch selectivity with respect to the insulating layers 111 to 118 and the sacrificial layers SC1 to SC8. In some embodiments, the mask pattern MP may be formed of at least one of organic materials and/or photoresist materials. An initial thickness of the mask pattern MP may be greater than a width of the word line contact region WCTR.

The step of reducing the horizontal area occupied by the mask pattern MP may be performed to enlarge a horizontal area of a region exposed by the mask pattern MP. As the number of times of the steps of etching the stacked layer structure ST increases, a width and a thickness of the mask pattern MP may be reduced. The mask pattern MP may have enough an initial thickness to be able to remain on the stepwise stacked layer structure ST′ after patterning the lowermost gate insulating layer 11. The remaining mask pattern MP may be removed after finishing the formation of the stepwise stacked layer structure ST′.

A way of etching the stacked layer structure ST may vary depending on the layer number of the sacrificial layers SC1 to SC8. For instance, an etched amount of the stacked layer structure ST may be decrease with a reduction in the horizontal area of the mask pattern MP. As the stacked layer structure ST is repeatedly etched, the insulating layers 111 to 118 may have edge portions having exposed top surfaces. In other words, each of top surfaces of the insulating layers 111 to 118 constituting the stepwise stacked layer structure ST′ may be partially exposed in the word line contact region WCTR. In other embodiments, each of top surfaces of the sacrificial layers SC1 to SC8, not the top surfaces of the insulating layers 111 to 118, may be partially exposed in the word line contact region WCTR.

As described above, since the stepwise stacked layer structure ST′ may have the stepwise structure, the insulating layers 111 to 118 and/or the sacrificial layers SC1 to SC8 thereof may have the edge portions sequentially exposed on the word line contact region WCTR. The farther a distance from the insulating layers 111 to 118 and the sacrificial layers SC1 to SC8 to the substrate 10 is, the smaller the area occupied by the insulating layers 111 to 118 and the sacrificial layers SC1 to SC8 may be. In other words, as the sacrificial layers SC1 to SC8 and the insulating layers 111 to 118 are vertically farther from the substrate 10, sidewalls of the sacrificial layers SC1 to SC8 and the insulating layers 111 to 118 are laterally farther from the peripheral circuit region C/P. In some embodiments, a height of the stepwise stacked layer structure ST′ may be in a range of about 15,000 Å to about 40,000 Å. Further, a height difference between top surfaces of the stepwise stacked layer structure ST′ and the peripheral gate pattern 22 may be in a range of about 10,000 Å to about 30,000 Å.

In some embodiments, as the result of the patterning of the stacked layer structure ST, a portion of the substrate 10 may be exposed in the word line contact region WCTR adjacent to the peripheral circuit region C/P. In some embodiments, the stepwise stacked layer structure ST′ may be removed from the peripheral circuit region C/P. In other words, the peripheral insulating pattern 30 or the peripheral etch stop layer 32 may be exposed on the peripheral circuit region C/P.

In the case that the stepwise stacked layer structure ST′ is removed from the peripheral circuit region C/P, there may be a height difference between top surfaces of the stepwise stacked layer structure ST′ and a peripheral structure (e.g., the peripheral insulating pattern 30) remaining on the peripheral circuit region C/P. In some aspects of the inventive concepts, the height difference may be proportional to an integration density of the three-dimensional semiconductor memory device or the layer number of the sacrificial layers SC1 to SC8 and the insulating layers 111 to 118.

Referring to FIGS. 4, 9A and 9B, an interlayer dielectric 130 may be formed on the substrate 10 to cover the stepwise stacked layer structure ST′ and the peripheral circuits.

The interlayer dielectric 130 may be formed of a material having an etch selectivity with respect to the sacrificial layers SC1 to SC8 during a subsequent process of removing the sacrificial layers SC1 to SC8 from the stepwise stacked layer structure ST′. Alternatively, the interlayer dielectric 130 may be formed of a material having an etch selectivity with respect to the insulating layers 111 to 118 and the sacrificial layers SC1 to SC8 during the subsequent process of removing the sacrificial layers SC1 to SC8 from the stepwise stacked layer structure ST′.

The interlayer dielectric 130 may be formed using a physical vapor deposition (PVD) method, a chemical vapor deposition (CVD) method, a sub-atmospheric CVD (SACVD) method, a low-pressure CVD (LPCVD) method, a plasma-enhanced CVD (PECVD) method, or a high-density plasma CVD (HDP CVD) method.

Since the interlayer dielectric 130 is formed using a deposition method, the interlayer dielectric 130 may conformally cover the underlying structure in at least the cell array region CAR and the peripheral circuit region C/P. The interlayer dielectric 130 may be deposited to a greater thickness than the height difference between the top surfaces of the stepwise stacked layer structure ST′ and the peripheral structure. In other words, the interlayer dielectric 130 may have such a sufficient thickness that a top surface of the interlayer dielectric 130 in the peripheral circuit region C/P can be located at a higher level than the top surface of the stepwise stacked layer structure ST′ (e.g., a top surface of the contact pads 123).

The interlayer dielectric 130 may be formed of, for example, at least one of high-density plasma (HDP) oxide, tetraethyl orthosilicate (TEOS), plasma-enhanced TEOS (PE-TEOS), O3-TEOS, undoped silicate glass (USG), phosphosilicate glass (PSG), borosilicate glass (BSG), borophosphosilicate glass (BPSG), fluoride silicate glass (FSG), spin on glass (SOG), tonen silazene (TOSZ), or any combination thereof. Alternatively, the interlayer dielectric 130 may include at least one of silicon nitride, silicon oxynitride or low-k dielectrics.

The interlayer dielectric 130 may have a top surface morphology depending on the underlying structure. For instance, a top surface of the interlayer dielectric 130 in the cell array region CAR may be higher than a top surface of the interlayer dielectric 130 in the peripheral circuit region C/P. In addition, the interlayer dielectric 130 may have a portion having an inclined top surface between the cell array region CAR and the peripheral circuit region C/P (i.e., on the word line contact region WCTR).

In some embodiments, the interlayer dielectric 130 may include an upper portion disposed on the cell array region CAR, a lower portion disposed on the peripheral circuit region C/P, and a sloped portion connecting the upper portion with the lower portion. The upper portion, the sloped portion, and the lower portion may be continuously connected with each other. The upper portion and the sloped portion of the interlayer dielectric 130 may cover a central portion including the contact pads 123 and the stepwise contact portion of the stepwise stacked layer structure ST′, respectively. The lower portion may cover the peripheral circuits, and further, extend toward the word line contact region WCTR to partially cover an edge portion of the stepwise stacked layer structure ST′.

In some embodiments, a top surface of the lower portion or the lowermost top surface of the interlayer dielectric 130 may be positioned at a higher level than the top surface of the stepwise stacked layer structure ST′. When a height difference between top surfaces of the stepwise stacked layer structure ST′ and the lower portion of the interlayer dielectric 130 is small, a subsequent planarization process on the interlayer dielectric 130 may be easily performed.

Accordingly, the uneven or curved top surface of the interlayer dielectric 130 may result in technical difficulties during a subsequent process of forming contact plugs and interconnection lines. For instance, the formation of the contact plugs may include a step of forming contact holes through the interlayer dielectric 130, but due to the uneven or curved top surface of the interlayer dielectric 130, the contact holes may be formed not to penetrate the interlayer dielectric 130. Furthermore, due to the uneven or curved top surface of the interlayer dielectric 130 may result in a thickness variation of the interconnection line.

According to example embodiments of the inventive concepts, these difficulties may be overcome by a planarization process for reducing the height difference of the interlayer dielectric 130. The planarization process may be performed to expose the uppermost top surface of the underlying structure covered with the interlayer dielectric 130. In some embodiments, the planarization process may be performed to expose the top surface of the stepwise stacked layer structure ST′. Since the top surface of the stepwise stacked layer structure ST′ may be substantially coplanar with the top surface of the contact pad 123, the contact pads 123 penetrating the stepwise stacked layer structure ST′ may be exposed after the planarization process.

The planarization process on the interlayer dielectric 130 may be performed using a chemical mechanical polishing (CMP) technique. During the planarization process using the CMP technique, the interlayer dielectric 130 may be mechanically polished using a polishing pad configured to rotate on the substrate 10 (i.e., wafer) and simultaneously, chemically etched using a polishing solution containing slurries, which may be supplied between the substrate 10 and the polishing pad. A removal rate of the interlayer dielectric 130 in the planarization process may be affected by various factors, such as a slurry type, a configuration of the polishing pad, a structure and type of a polishing head, a rotating speed of the polishing pad relative to the substrate 10, a pressure applied by the polishing pad to the substrate 10, and a material and shape of the interlayer dielectric 130. In some embodiments, the slurry may be one selected to exhibit an excellent polishing property with respect to a target material (e.g., the lower insulating layer 130), in consideration of factors changing the removal rate of the interlayer dielectric 130.

In the case that the planarization process on the interlayer dielectric 130 is performed to expose the contact pad 123, a top surface of the interlayer dielectric 130 may be unintentionally recessed on the word line contact region WCTR and the peripheral circuit region C/P, because the contact pad 123 may have a different removal rate from the interlayer dielectric 130. In other words, the interlayer dielectric 130 on the word line contact region WCTR and the peripheral circuit region C/P may be etched faster than the contact pads 123 of the cell array region CAR. As a result, a technical difficulty, known as a dishing, may occur in the word line contact region WCTR and the peripheral circuit region C/P. In addition, some of the contact pads 123 may be damaged by chemical and/or physical attacks during the planarization process using the CMP technique.

The dishing of the interlayer dielectric 130 may cause a difficulty in the subsequent processes of forming the contact plugs and the interconnection lines on the word line contact region WCTR and the peripheral circuit region C/P. In addition, due to the damage on some of the contact pads 123, there may be a uniformity issue associated with the contact pads 123. For instance, top surfaces of the contact pads 123 may be positioned at different levels according to their positions on the substrate 10.

Moreover, the spatial height difference of the interlayer dielectric 130 may result in a reduction of a process margin (for instance, associated with a depth of focus (DOF)) in a subsequent patterning process for forming the contact plug and the interconnection line.

In some embodiments, as shown in FIGS. 9A and 9B, a polishing stop layer PSL may be formed on the interlayer dielectric 130. The polishing stop layer PSL may be able to reduce or prevent the damage on the contact pads 123 in the cell array region CAR and/or a dishing of the interlayer dielectric 130 in the word line contact region WCTR and the peripheral circuit region C/P during the planarization of the interlayer dielectric 130.

In more detail, referring to FIGS. 9A and 9B, the polishing stop layer PSL may be conformally formed on the interlayer dielectric 130 having the height difference between the cell array region CAR and the peripheral circuit region C/P.

In some embodiments, the polishing stop layer PSL may serve as a sacrificial layer preventing or retarding the dishing phenomenon from occurring on the word line contact region WCTR and the peripheral circuit region C/P during the planarization of the interlayer dielectric 130.

The polishing stop layer PSL may be formed using a deposition technique such as CVD, PVD or ALD technique. The polishing stop layer PSL may be formed of a material having a lower etch rate than the interlayer dielectric 130 in the planarization of the interlayer dielectric 130. For instance, the polishing stop layer PSL may be formed of at least one of silicon nitride (SiN), silicon oxynitride (SiON), silicon carbide (SiC), silicon oxycarbide (SiOC), a conductive material, SiLK available from DuPont, Black Diamond available from Applied Materials, CORAL available from Novellus Systems, BN (Boron Nitride), an anti-reflective coating (ARC) layer, and/or any combination thereof. In some embodiments, since the polishing stop layer PSL is formed on the interlayer dielectric 130, it may be located at a higher level than the top surface of the stacked layer structure ST.

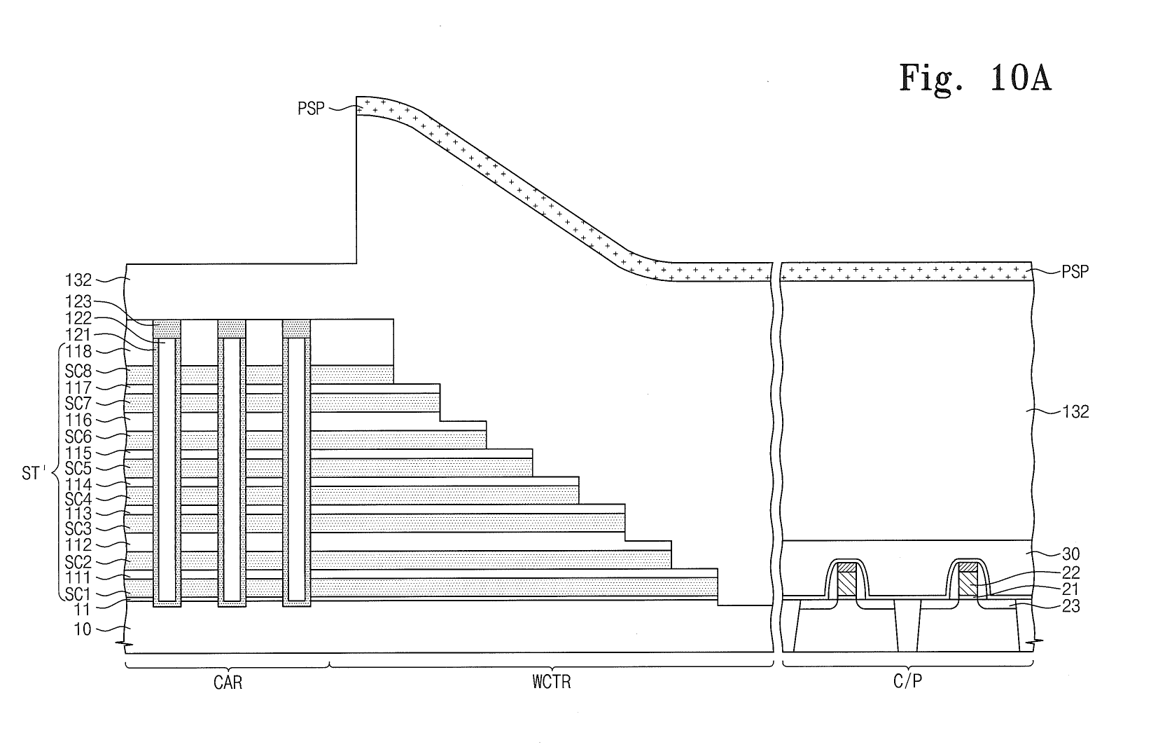

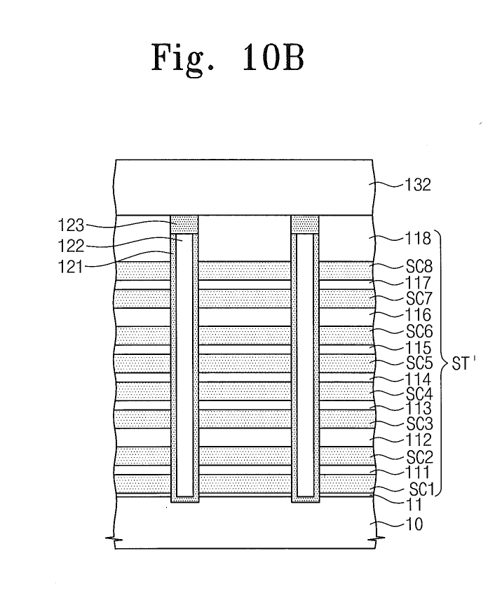

As shown in FIGS. 10A and 10B, the interlayer dielectric 130 may be partially removed from the cell array region CAR to reduce the height difference of the interlayer dielectric 130 between the cell array region CAR and the peripheral circuit region C/P.

In other words, the partial removal of the interlayer dielectric 130 may be performed to reduce a difference in a top surface level from the substrate 10 of the interlayer dielectric 130 between on the cell array region CAR and on the peripheral circuit region C/P.

For instance, the partial removal of the interlayer dielectric 130 may include forming a photoresist pattern (not shown) to expose a portion disposed on the cell array region CAR of the polishing stop layer PSL and anisotropically etching the polishing stop layer PSL and the interlayer dielectric 130 using the photoresist pattern.

During the partial removal of the interlayer dielectric 130, the photoresist pattern may be formed to expose the sloped portion of the interlayer dielectric 130. In this case, the sloped portion of the interlayer dielectric 130 may be etched and have a top surface located at a lower level than the top surface of the stacked layer structure ST′. As a result, the top surface of the interlayer dielectric 130 may not be fully planarized by a subsequent polishing process. According to example embodiments of the inventive concepts, the interlayer dielectric 130 may be partially etched from the cell array region CAR. For instance, the upper portion of the interlayer dielectric 130 may be etched by a specific depth.

The partial removal of the interlayer dielectric 130 from the cell array region CAR may reduce the height difference of the interlayer dielectric 130 between the cell array region CAR and the peripheral circuit region C/P. In other words, the height difference between top surfaces of the upper portion and the lower portion of the interlayer dielectric 130 can be reduced. In some embodiments, the top surface of the upper portion may be positioned at the substantially same as that of the lower portion, but example embodiments of the inventive concepts may not be limited thereto. For instance, the top surface of the upper portion may be positioned at a higher or lower level than that of the lower portion.

The sloped portion of the interlayer dielectric 130 may not be etched during the partial removal of the interlayer dielectric 130 and remain between the cell array region CAR and the peripheral circuit region C/P. In some embodiments, the sloped portion of the interlayer dielectric 130 may protrude relative to the recessed upper portion or the lower portion of the interlayer dielectric 130.

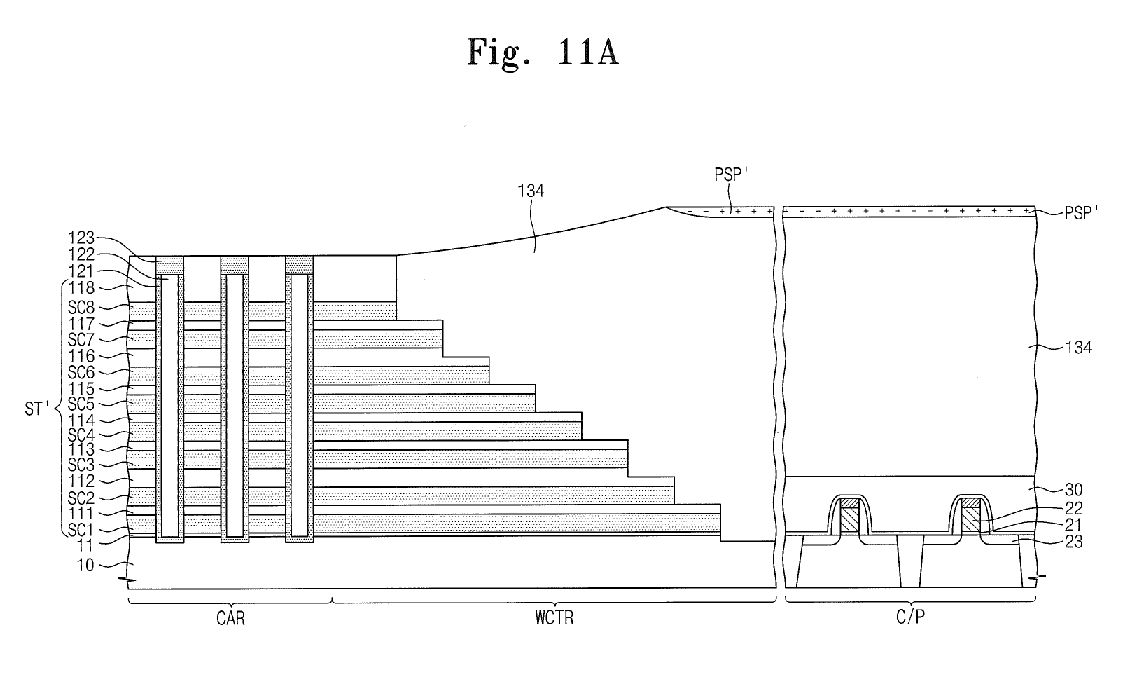

Referring to FIGS. 11A and 11B, the interlayer dielectric 130 may be patterned to form an interlayer insulating pattern 134 having a planarized top surface on the peripheral circuit region C/P and the word line contact region WCTR. The patterning of the interlayer dielectric 130 may be performed using a chemical mechanical polishing process.

In some embodiments, the interlayer insulating pattern 134 may be formed to expose the stacked layer structure ST′ and the top surfaces of the contact pads 123 on the cell array region CAR. The polishing stop layer PSL may prevent the interlayer dielectric 130 on the peripheral circuit region C/P and the word line contact region WCTR from being excessively polished during the polishing of the interlayer dielectric 130. In other embodiments, the contact pads 123 of the cell array region CAR may be formed after the formation of the interlayer insulating pattern 134. In this case, the polishing process of the interlayer dielectric 130 may be performed to expose the top surface of the semiconductor pattern 121 on the cell array region CAR.

In more detail, the polishing process of the interlayer dielectric 130 may include a first polishing step of removing the sloped protruding portion of the interlayer dielectric 130 and a second polishing step of exposing the top surfaces of the contact pads 123.

During the polishing process of the interlayer dielectric 130, removal rates of the interlayer dielectric 130 and the polishing stop layer PSL may be affected by various factors, such as a slurry type, a configuration of the polishing pad, a structure and type of a polishing head, a rotating speed of the polishing pad relative to the substrate 10, a pressure applied by the polishing pad to the substrate 10, a material, shape and/or type of target patterns to be polished, and uniformities of the interlayer dielectric 130 and the polishing stop layer PSL.

In some embodiments, the first polishing step may be performed to remove a portion of the interlayer dielectric 130 located above the recessed upper portion. For instance, after the first polishing step, the highest top surface of the resultant structure may be located at the substantially same level as the top surface of the recessed upper portion. As a result, the height difference of the interlayer dielectric 130 may be partially removed (for instance, from the word line contact region WCTR).

In the first polishing step, a polishing time may be controlled in consideration of thicknesses of the interlayer dielectric 130 measured before/after performing the first polishing step. For instance, an end-point detection (EPD) technique may be employed to control the first polishing step. In the EPD technique, a polishing state of the interlayer dielectric 130 may be monitored to determine a point in time at which the polishing process is finished. For instance, during the first polishing step, a polishing time may be controlled by measuring a change in a thickness of the interlayer dielectric 130 from an initial value. In the case that the top surface of the upper portion of the interlayer dielectric 130 is higher than that of the lower portion thereof, the first polishing step may be terminated when the highest top surface of the resultant structure is located at the substantially same level as the top surface of the recessed upper portion. In some embodiments, the first polishing step on the interlayer dielectric 130 may be performed in such a way that the stacked layer structure ST or the contact pads 123 are not exposed.

In some embodiments, the slurry supplied during the first polishing step may have an etch selectivity (e.g., an etching ratio of from 4:1 to 10:1) between the interlayer dielectric 130 and the polishing stop layer PSL. For instance, the slurries for the first polishing step may include at least one selected from silica, ceria, mangania, alumina, titania, zirconia, germania, or any combination thereof. When the interlayer dielectric 130 is formed of silicon oxide and the polishing stop layer PSL are formed of silicon nitride, silica and/or ceria slurries may be used for the first polishing step.

During the first polishing step, a mechanical stress may be concentrated at the sloped protruding portion of the interlayer dielectric 130 by the polishing pad. This may result in a fracture of the sloped protruding portion, not the intended planarization thereof. Furthermore, a portion of the polishing stop layer PSL covering the sloped protruding portion may be removed during the first polishing step. This difficulty may be overcome by using a slurry selected in such a way that the polishing stop layer PSL exhibits a lower removal rate than the interlayer dielectric 130 during the first polishing step. In some embodiments, the sloped protruding portion may be chemically removed and a portion of the polishing stop layer PSL disposed thereon may be mechanically removed.

The second polishing step may be performed to expose the contact pads 123 on the cell array region CAR. The second polishing step may be controlled using the EPD technique. In some embodiments, the end point of the second polishing step may be determined in consideration of a change of operational characteristics (e.g., rotating speed) of the polishing pad and/or an optical change of monitoring light, which may occur when an underlying layer having a different removal rate from the interlayer dielectric 130 is exposed during the second polishing step.

The second polishing step may be performed using a slurry having an etch selectivity (e.g., an etching rate of from 4:1 to 10:1) between the interlayer dielectric 130 and the polishing stop layer PSL.

During the second polishing step on the interlayer dielectric 130, a removal rate of the polishing stop layer PSL may be lower than that of the interlayer dielectric 130, and thus, the polishing stop layer PSL may prevent the interlayer dielectric 130 disposed under the polishing stop layer PSL from being polished. In other words, it is possible to prevent the interlayer dielectric 130 on the peripheral circuit region C/P and the word line contact region WCTR from being excessively polished.

As the second polishing step goes on, the top surfaces of the contact pads 123 may be exposed in the cell array region CAR and an interlayer insulating pattern 134 having a planarized top surface may be formed on the word line contact region WCTR and the peripheral circuit region C/P. In addition, a portion of the polishing stop layer PSL may remain on the interlayer insulating pattern 134 to form a polishing stop pattern PSP.

The polishing stop pattern PSP may extend from the peripheral circuit region C/P to the word line contact region WCTR to cover a portion of the interlayer insulating pattern 134. For instance, as shown in FIG. 11A, the polishing stop pattern PSP may have a portion disposed on the edge portion of the stepwise stacked layer structure ST′. In other words, the polishing stop pattern PSP may be disposed on end portions of the insulating layers 111 to 118 and the sacrificial layers SC1 to SC8. The higher top surface of the resultant structure on the cell array region CAR may be lower than that of the interlayer insulating pattern 134, and the interlayer insulating pattern 134 may have a curved or sloped top surface on the word line contact region WCTR.

After finishing the first and the second polishing steps, de-ionized water may be used to remove a slurry material and/or a remaining substance (e.g., a by-product formed in first and the second polishing steps).

In some embodiments, the polishing stop pattern PSP remaining on the interlayer insulating pattern 134 may be removed after the first and second polishing steps. For instance, the polishing stop pattern PSP may be removed by using an etch recipe having an etch selectivity with respect to the interlayer insulating pattern 134 and the contact pads 123 in an anisotropic or isotropic etch manner. In the case that the polishing stop pattern PSP is formed of silicon nitride, it may be isotropically etched using, for example, an etchant with phosphoric acid.

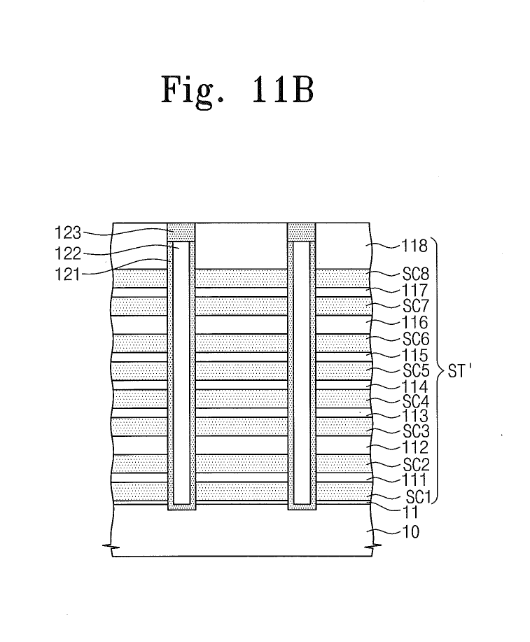

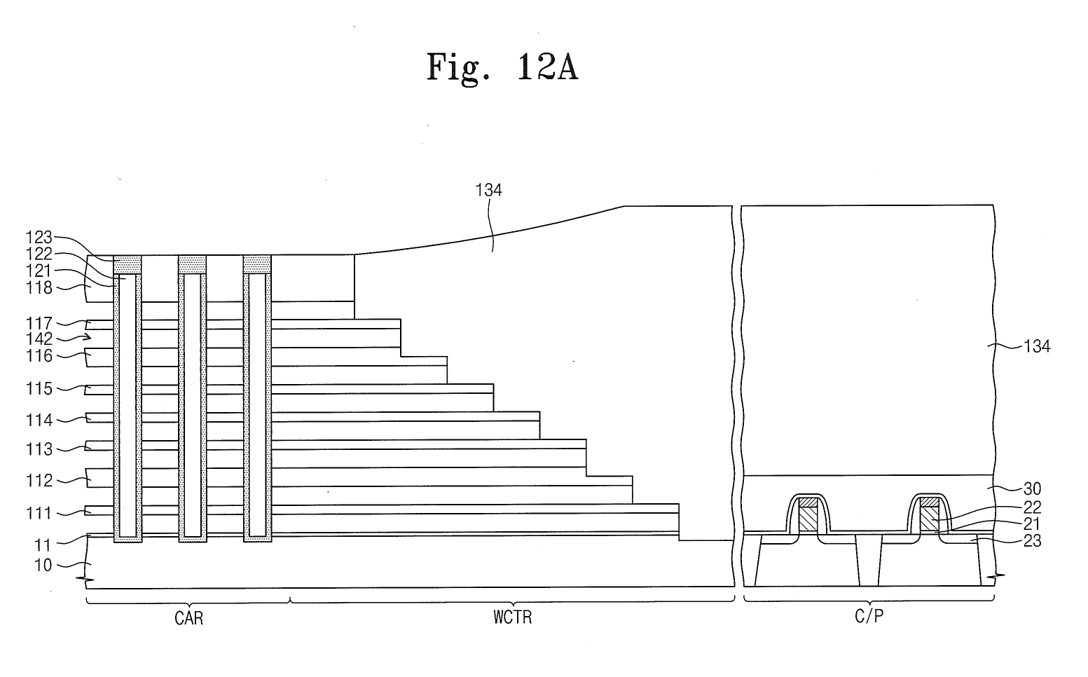

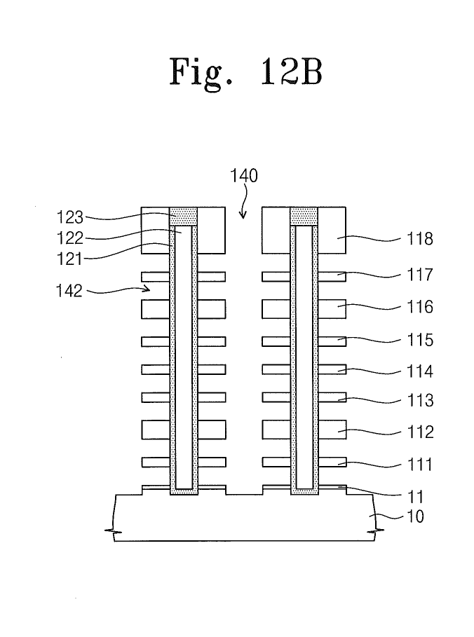

In other embodiments, the polishing stop pattern PSP may be removed during removing the sacrificial layers SC1 to SC8 of the stacked layer structure ST shown in FIGS. 12A and 12B, not using an additional etching process.

Referring to FIGS. 12A and 12B, after the formation of the interlayer insulating pattern 134, gate electrodes may be sequentially stacked on the substrate 10. The gate electrodes may be formed to face sidewalls of the semiconductor patterns 121. The formation of the gate electrodes may include forming trenches 140 between the semiconductor patterns 121 to partially or fully penetrate the stacked layer structure ST′ and replacing the sacrificial layers SC1 to SC8 of the stacked layer structure ST′ with a conductive layer.

In some embodiments, the formation of the trenches 140 may include patterning the stacked layer structure ST′ to expose the substrate 10 between the semiconductor patterns 121. In more detail, the formation of the trenches 140 may include forming a mask pattern (not shown), which defines two-dimensional arrangement positions of the trenches 140, on the stacked layer structure ST′ and anisotropically etching the stacked layer structure ST′ using the mask pattern as an etch mask.

The trenches 140 may be spaced apart from the semiconductor patterns 121 to expose sidewalls of the sacrificial layers SC1 to SC8 and the insulating layers 111 to 118. From a plan view, the trenches 140 may be formed to have a linear or rectangular shape, and in terms of a vertical depth, the trenches 140 may be formed to expose at least a top surface of the lowermost one of the sacrificial layers SC1 to SC8. In some embodiments, due to an over-etching during the trenches 140, a top surface of the substrate 10 under the trenches 140 may be recessed by a specific depth. The trench 140 may be formed to have a taper shape.

As shown in FIG. 4, due to the presence of the trenches 140, the stacked layer structure ST′ may have a linear shape extending parallel to the trenches 140. In some embodiments, a plurality of the semiconductor patterns 121 may be arranged parallel to the trenches 140 to penetrate each of the linear stacked layer structure ST′. The linear stacked layer structure ST′ may have an inner sidewall adjacent to the semiconductor pattern 121 and an outer sidewall exposed by the trench 140. In other words, the sacrificial layers SC1 to SC8 and the insulating layers 111 to 118 may be patterned to define the outer sidewall of the linear stacked layer structure ST′.

In other embodiments, although the trench 140 is linear, the stacked layer structure ST′ may have end portions connecting linear portions thereof cut by the trench 140 with each other on the word line contact region WCTR. In other words, the stacked layer structure ST′ may have a comb shape or a finger shape.

A doped region may be partially formed in the substrate 10 under the trench 140. The doped region may serve as the common source line described with reference to FIG. 3. In other words, the stacked layer structure ST′ having the trenches 140 may be used as an ion mask during an ion implantation process for forming the doped region process.

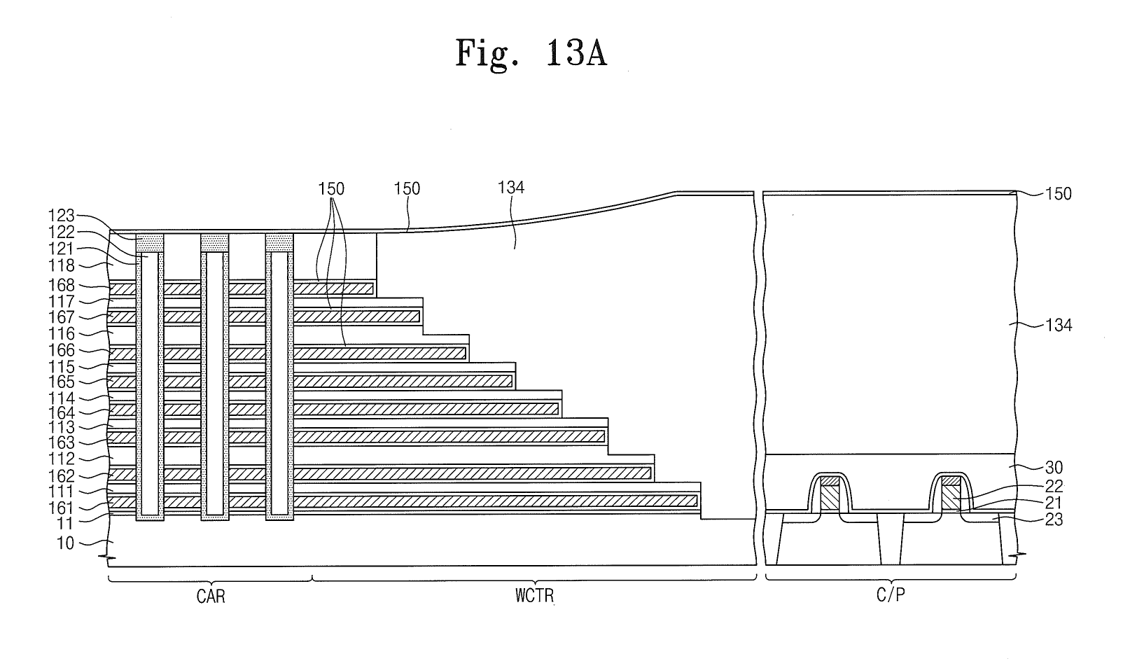

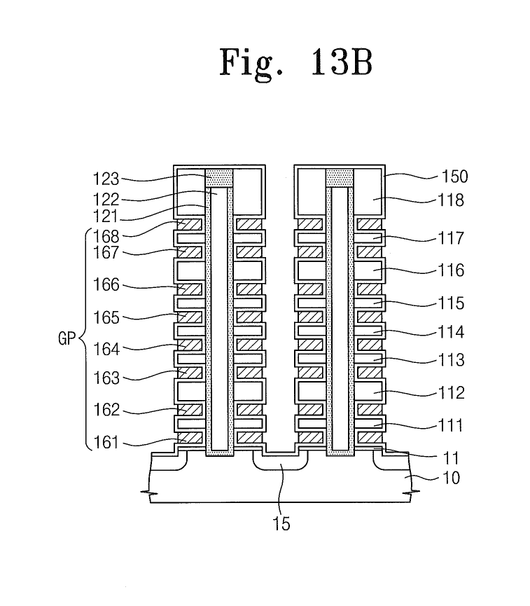

The replacing process may include selectively removing the sacrificial layers SC1 to SC8 exposed by the trenches 140 to form recess regions 142 between the patterned insulating layers 111 to 118, as shown in FIGS. 12A and 12B, and forming a data storing layer 150 and gate electrodes 161 to 168 to fill the recess regions 142, as shown in FIGS. 13A and 13B.

In more detail, referring to FIGS. 12A and 12B, the recess regions 142 may be formed by removing the patterned sacrificial layers SC1 to SC8 between the patterned insulating layers 111 to 118. The removal of the sacrificial layers SC1 to SC8 may be performed to isotropically etch the patterned sacrificial layers SC1 to SC8 using an etch recipe having an etch selectivity with respect to the patterned insulating layers 111 to 118. The patterned sacrificial layers SC1 to SC8 may be fully removed by using an isotropic etch process. For instance, in the case that the patterned sacrificial layers SC1 to SC8 are formed of silicon nitride and the patterned insulating layers 111 to 118 are formed of silicon oxide, the sacrificial layers SC1 to SC8 may be removed using an etchant with phosphoric acid.

The recess regions 142 may be formed to partially expose a sidewall of the semiconductor pattern 121 between the patterned insulating layers 111 to 118 adjacent to the trench 140. Meanwhile, the lowermost one of the recess regions 142 may be defined by the lower gate insulating layer 11. Vertical thicknesses of the recess regions 142 may be determined by initial deposition thicknesses of the sacrificial layers SC 1 to SC8, as described with reference to FIGS. 5A and 5B.

Referring to FIGS. 13A and 13B, the data storing layer 150 and the gate electrodes may be formed in the recess regions 142.

The data storing layer 150 may be conformally formed on the stacked layer structure ST provided with the recess regions 142. As used herein, conformality is a layer property describing how well the topography of the underlying surface is replicated. For example, a conformal layer has substantially the same shape as the surface it covers and/or has substantially the same thickness throughout. The data storing layer 150 may be formed using a deposition technique (e.g., a CVD or ALD technique) capable of providing an excellent step coverage property. The data storing layer 150 may be formed to have a smaller thickness than half the thickness of the recess regions 142. Accordingly, the data storing layer 150 may be formed to partially cover the sidewalls of the semiconductor pattern 121 exposed by the recess regions 142, and it may be laterally extended to cover bottom and top surfaces of the patterned insulating layers 111 to 118 defining the recess regions 142. In addition, the data storing layer 150 may be deposited to cover at least one portion of the top surface of the substrate 10 under the trenches 140, the top surface of the uppermost insulating layer 118, and sidewalls adjacent to the trenches 140 of the insulating layers 111 to 118. Furthermore, the data storing layer 150 may cover a top surface of the substrate 10 or the lower gate insulating layer 11 exposed by the lowermost recess region. Since the formation of the data storing layer 150 may be performed using the deposition technique, the data storing layer 150 may be in direct contact with the interlayer insulating pattern 134 in the word line contact region WCTR.

In some embodiments, as shown in FIGS. 13A and 13B, the data storing layer 150 may be formed to conformally cover the stacked layer structure ST′ provided with the recess regions 142. For instance, the data storing layer 150 may cover the top surfaces of the contact pads 123 and the top surface of interlayer insulating pattern 134. The data storing layer 150 may cover a top surface of the interlayer insulating pattern 134 in the word line contact region WCTR and the peripheral circuit region C/P.

In other embodiments, as shown in FIG. 15A, the data storing layer 150 may be formed to include portions (hereinafter, data storing patterns), each of which is locally disposed between vertically adjacent two ones of the patterned insulating layers 111 to 118 to be vertically spaced apart from the others of the data storing patterns. The data storing patterns spaced apart from each other may prevent electric charges stored therein from diffusing or spreading into an adjacent other data storing pattern. The lowermost one of the data storing pattern may be in direct contact with the top surface of the buffer insulating layer 101 or the substrate 10.

The data storing layer 150 may be a charge storing layer. For example, the data storing layer 150 may include one of a charge trap insulating layer, a floating gate electrode, or an insulating layer including conductive nanodots. In the case that the data storing layer 150 include the charge storing layer, data stored therein may be changed using Fowler-Nordheim (FN) tunneling, caused by a voltage difference between the semiconductor pattern 121 and the gate electrodes (e.g., WL of FIG. 4). In other embodiments, the data storing layer 150 may be formed of materials based on different data-writing principles. For example, the data storing layer DS may include one of materials having a variable resistance property or a phase changeable property.

According to some embodiments, as shown in FIGS. 15B through 15D, the data storing layer 150 may include a tunnel insulating layer 150a, a charge trap layer 150b and a blocking insulating layer 150c stacked sequentially.

The tunnel insulating layer 150a may be formed of a material having a lower dielectric constant than the blocking insulating layer 150c. For example, the tunnel insulating layer 150a may include at least one of oxide, nitride, or oxynitride.

The charge trap layer 150b may be an insulating layer having rich charge trap sites (e.g., a silicon nitride layer) or an insulating layer having conductive grains. According to some embodiments, the tunnel insulating layer 150a may include a silicon oxide layer, the charge trap layer 150b may include a silicon nitride layer, and the blocking insulating layer 150c may include an aluminum oxide layer.

The blocking insulating layer 150c may include at least one of silicon oxide, silicon nitride, silicon oxynitride, and/or high-k dielectric, and it may be a multilayered structure including a plurality of layers. Here, the high-k dielectric refers to an insulating material having a higher dielectric constant than silicon oxide (e.g., tantalum oxide, titanium oxide, hafnium oxide, zirconium oxide, aluminum oxide, yttrium oxide, niobium oxide, cesium oxide, indium oxide, iridium oxide, barium-strontium-titanate (BST) materials, and lead-zirconium-titanate (PZT) materials).

Although not depicted, according to other embodiments, the blocking insulating layer 150c may include a first blocking insulating layer and a second blocking insulating layer. Here, the first and second blocking insulating layers may formed of different materials, and one of the first and second blocking insulating layers may include a material having a bandgap narrower than the tunnel insulating layer and wider than that of the charge trap layer. For instance, the first blocking insulating layer may be formed of one of high-k dielectrics (e.g., aluminum oxide and hafnium oxide), and the second blocking insulating layer may be formed of a material having a smaller dielectric constant than the first blocking insulating layer. According to other embodiments, the second blocking insulating layer may be formed of one of high-k dielectrics, and the first blocking insulating layer may be formed of a material having a smaller dielectric constant than the second blocking insulating layer.

According to still other example embodiments, the data storing layer 150 may also include the tunnel insulating layer 150a, the charge trap layer 150b, and the blocking insulating layer 150c stacked sequentially, but as shown in FIG. 15B, the tunnel insulating layer 150a and the charge trap layer 150b may be formed to run across an inner wall of the stacked layer structure ST adjacent to the semiconductor pattern 121. In other words, the tunnel insulating layer 150a and the charge trap layer 150b may be formed on the inner wall of the opening before the formation of the semiconductor pattern 121 described with reference to FIGS. 7A and 7B. Moreover, the blocking insulating layer 150c may be conformally formed on inner surfaces of the recess regions 142 after forming the recess regions 142. Accordingly, the blocking insulating layer 150c may be in directly contact with top and bottom surfaces of the insulating layers 111 to 118. According to other modified embodiments, as shown in FIG. 15C, the tunnel insulating layer 150a may be formed to cover the inner wall of the opening before forming the semiconductor pattern 121, and the charge trap layer 150b and the blocking insulating layer 150c may be conformally and sequentially formed on the inner surface of the recess region 142.

Referring back to FIGS. 13A and 13B, the gate electrodes 161 to 168 may be formed in the recess regions 142 provided with the data storing layer 150, respectively.

The formation of the gate electrodes 161 to 168 may include forming a gate conductive layer in the recess regions 142 and the trench 140 provided with the data storing layer 150, and then removing the gate conductive layer from the trench 140 to form the gate electrodes 161 to 168 vertically spaced apart from each other.

The gate conductive layer may be formed using a deposition technique (e.g., a CVD or ALD technique) capable of providing an excellent step coverage property. In some embodiments, the gate conductive layer may be formed to fill the recess regions 142 and conformally cover inner walls of the trench 140. For instance, the gate conductive layer may be deposited to have a greater thickness than half a vertical thickness of the recess region 142. In the case that a horizontal width of the trench 140 is greater than the vertical thickness of the recess region 142, the gate conductive layer may partially fill the trench 140 and an empty space having a top-open shape may be formed in a central portion of the trench 140.

The gate conductive layer may include at least one of doped polysilicon, tungsten, metal nitrides, or metal silicides. In some embodiments, the formation of the conductive layer may include sequentially forming a barrier metal layer (e.g., a metal nitride layer) and a metal layer (e.g., a tungsten layer). Moreover, the inventive concepts are not limited to FLASH memory devices and thus material and structure of the conductive layer may be variously changed.

In some embodiments, the removal of the gate conductive layer from the trench 140 may be performed using an anisotropic etching technique.

For instance, the removal of the gate conductive layer from the trench 140 may include anisotropically etching the gate conductive layer using the uppermost insulation layer of the stacked layer structure ST′ or an additional hard mask pattern (not shown) formed on the stacked layer structure ST′ as an etching mask. A portion adjacent to the substrate 10 of the data storing layer 150 may be used as an etch stop layer preventing an unintended recess of the substrate 10.

The anisotropic etching of the gate conductive layer may be performed to expose a portion of the data storing layer 150 that covers the substrate 10. Alternatively, the anisotropic etching of the gate conductive layer may be performed to the top surface of the substrate 10, and in this case, the top surface of the substrate 10 may be recessed as shown in FIGS. 13A and 13B.

In other embodiments, the gate electrodes 161 to 168 may be formed by using an isotropic etch process. The isotropic etch process may be performed until the gate electrodes 161 to 168 are vertically spaced apart from each other. In other words, the isotropic etch process may be performed to expose portions of the data storing layer 150, which are disposed on sidewalls of the insulating layers and on the top surface of the substrate 10. The empty space having a top-open shape may enable the gate conductive layer to be etched at the substantially time during the isotropic etching process. Furthermore, the gate conductive layer may be uniformly etched on the stacked layer structure ST and on the substrate 10, and thus, the gate electrodes 161 to 168 may have the substantially same horizontal width. In some embodiments, the gate electrodes 161 to 168 may have different horizontal widths from each other depending on a vertical level. For instance, at least one of the gate electrodes 161 to 168 may partially fill the corresponding recess region. Each of the gate electrodes 161 to 168 may include a metal pattern 163a and a barrier metal pattern 163b interposed between the metal pattern 163 and the data storing layer 150, as shown in FIGS. 15A through 15D.

The gate electrodes 161 to 168 may constitute at least one gate structure GP. For instance, each of the gate structure GP may include the gate electrodes 161 to 168 arranged between two adjacent trenches 140. In this case, as shown in FIG. 4, each of the gate structures GP may have a line shape parallel to the trench 140 and be penetrated by a plurality of the semiconductor patterns 141 arranged along the direction parallel to the trench 140. The gate electrodes 161 to 168 may include outer sidewalls adjacent to the trench 140 and inner sidewalls adjacent to the semiconductor pattern 121. The gate electrodes 161 to 168 may be formed to partially envelope or run across a sidewall of the semiconductor pattern 121. Alternatively, the gate electrodes 161 to 168, which are disposed in one block of memory cell array, may be connected with each other in the word line contact region WCTR to form a comb or finger structure.

In some embodiments, the gate electrodes 161 to 168 may serve as the string selection line SSL, the ground selection line GSL, and the word lines WL described with reference to FIG. 2. For example, the uppermost and lowermost gate electrodes 161 and 168 may serve as the string selection line SSL and the ground selection line GSL, respectively, and the gate electrodes 162 to 167 interposed therebetween may serve the word lines WL.

Alternatively, as described with reference to FIG. 3, two uppermost gate electrodes 167 and 168 may serve as the string selection line SSL of FIG. 2, and two lowermost the gate electrodes 161 and 162 may serve as the ground selection line GSL of FIG. 2. Some of the gate electrodes serving as the string or ground selection lines SSL or GSL of FIG. 2 may be horizontally separated from each other, and thus, the string or ground selection lines disposed at the same level may be electrically separated from each other.

As shown in FIG. 15A, portions exposed by the trench 140 of the data storing layer 150 may be selectively removed after the formation of the gate structure GP. The removal of the data storing layer 150 may be performed using an etch gas or an etching solution having an etch selectivity with respect to the gate conductive layer. For instance, the data storing layer 150 may be etched by an isotropic etch process using an etch solution such as HF, O3/HF, phosphoric acid, sulfuric acid, and LAL (a mixture of NH4F and HF). In addition, a fluoride-based etching solution and a phosphoric or sulfuric acid solution may be used to remove the data storing layer 150.

After the formation of the gate structures GP, doped regions 15 may be formed in the substrate 10 between the gate structure GP, and they may serve as the common source line described with reference to FIG. 3.

For instance, the doped regions 15 may be formed by an ion implantation process using the gate structures GP as an ion mask. The doped region 15 may have a line shape parallel to the trench 140. Moreover, the doped regions 15 may horizontally overlap a portion of the lower region of the gate structure GP due to the diffusion of impurities. Additionally, the doped regions 15 may have a different conductivity type from the substrate 10.

Thereafter, a gate separation insulating layer 170 may be formed between the adjacent gate structures GP to fill the trenches 140.

The gate separation insulating layer 170 may be formed of at least one of silicon oxide, silicon nitride, or silicon oxynitride. The gate separation insulating layer 170 may be deposited on the uppermost insulating layer 118 using a deposition technique. For instance, as shown in FIGS. 13A and 13B, the gate separation insulating layer 170 may be formed on the data storing layer 150 covering the contact pads 123 and the interlayer insulating pattern 134 to fill the trenches 140. In some embodiments, the gate separation insulating layer 170 may be formed to have a greater thickness than half a width of the trench 140, and in this case, the trenches 140 can be filled with the gate separation insulating layer 170.

In other embodiments, a capping layer (not shown) may be additionally formed before the formation of gate separation insulating layer 170. The capping layer may prevent the gate electrodes 161 to 168 and the doped region 15 to be oxidized. The capping layer may be formed of an insulating nitride material (e.g., silicon nitride).

In still other embodiments, after the formation of the gate separation insulating layer 170, a planarization process on the gate separation insulating layer 170 and the data storing layer 150 may be further performed to expose top surfaces of the contact pads 123. In this case, the gate separation insulating layer 170 may form gate separation insulating patterns localized within the trenches 140.

Referring to FIGS. 4, 14A and 14B, an interconnection structure including contact plugs WPLG, PPLG, and BPLG and interconnection lines WIL, GWL, and BL may be formed to connect the gate electrodes 161 to 168 disposed in the cell array region CAR with the peripheral circuits disposed in the peripheral circuit region C/P.

In some embodiments, the formation of word line contact plugs WPLG and peripheral contact plugs PPLG may include forming contact holes to penetrate the interlayer insulating pattern 134 in the word line contact region WCTR and the peripheral circuit region C/P, and filling the contact holes with a conductive material. Since the gate structure GP has a stepwise structure in the word line contact region WCTR, the word line contact plugs WPLG can be connected to the gate electrodes 161 to 168 located at different levels from each other, using the same process. The peripheral contact plugs PPLG may be connected to the peripheral circuits. In some embodiments, the word line contact plugs WPLG and the peripheral contact plugs PPLG may be formed of a metallic material (e.g., tungsten). The formation of the word line contact plugs WPLG and the peripheral contact plugs PPLG may include sequentially forming a barrier metal layer (e.g., a metal nitride layer) and a metal layer (e.g., a tungsten layer).

In the case that the data storing layer 150 and the gate separation insulating layer 170 are removed on the interlayer insulating pattern 134, the word line contact plugs WPLG and the peripheral contact plugs PPLG may be formed to penetrate the interlayer insulating pattern 134. Otherwise, as shown in FIG. 14A, the word line contact plugs WPLG and the peripheral contact plugs PPLG may be formed to penetrate the gate separation insulating layer 170, the data storing layer 150 and the interlayer insulating pattern 134.

In addition, the gate electrodes 161 to 168 may be electrically connected to the peripheral circuits via global word lines GWL. In some embodiments, the gate electrodes disposed at the same level may be coupled to the same voltage delivered from the peripheral circuit. For instance, word line connecting lines WIL may be formed between the word line contact plugs WPLG and the global word lines GWL to connect the gate electrodes disposed at the same level. The word line connecting lines WIL may be disposed to run across the gate electrodes 161 to 168. In addition, conductive pads may be formed on the peripheral contact plugs PPLG, respectively.

The formation of the word line connecting lines WIL and the conductive pads may include depositing a conductive layer on the gate separation insulating layer 170 and then patterning the conductive layer. An upper insulating layer (not shown) may be formed on the gate separation insulating layer 170 to cover the global word lines GWL and the conductive pads. The upper insulating layer may be formed using a deposition technique and then, it may be planarized to have a flat top surface.

The global word lines GWL may be formed on the upper insulating layer and connected to the word line connecting lines WIL, respectively. In some embodiments, the global word lines GWL may be electrically coupled to the peripheral circuits. Bit line plugs BPLG and bit lines BL may be formed in the upper insulating layer, and the bit line plugs BPLG may penetrate the gate separation insulating layer 170 and the upper insulating layer to be connected to the contact pads 123 on the cell array region CAR.

In some embodiments, the formation of the bit line plugs BPLG may include patterning the data storing layer 150, the gate separation insulating layer 170 and the first interlayer dielectric to form contact holes exposing the contact pads 123, and then filling the contact holes with a conductive material. The bit lines BL may be formed to run across the gate electrodes 161 to 168, as shown in FIG. 4.

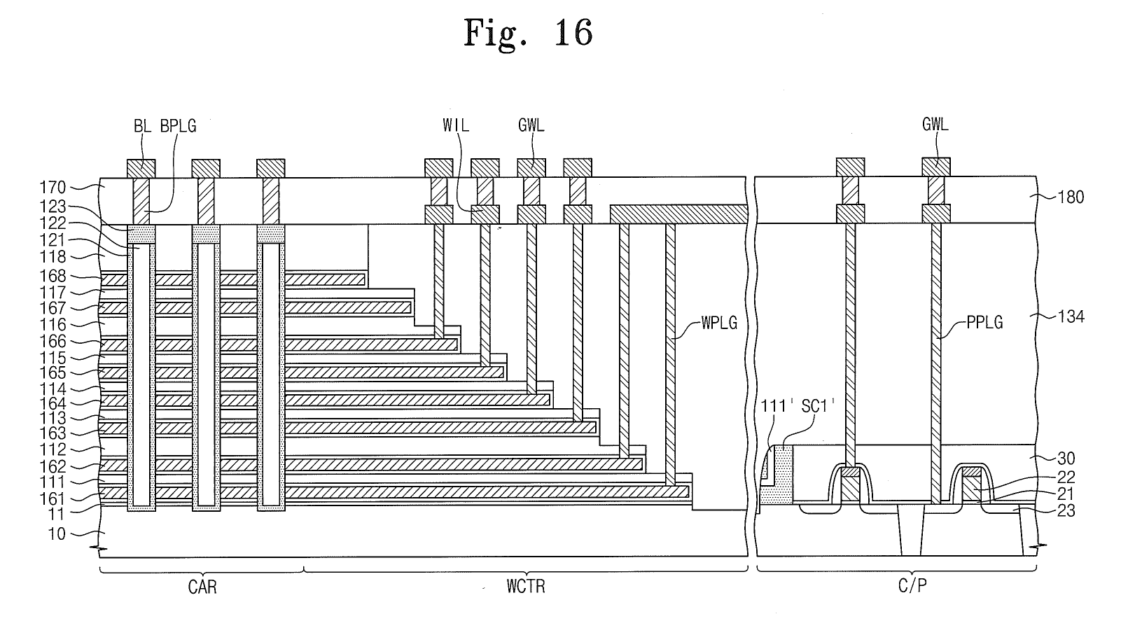

FIG. 16 is a sectional view of a three-dimensional semiconductor device according to modifications of the example embodiments of the inventive concepts.

According to these embodiments, when the stacked layer structure ST described with reference to FIGS. 8A and 8B is patterned to have the stepwise structure on the word line contact region WCTR, a portion of the stacked layer structure ST may remain on a sidewall of the peripheral insulating pattern 30 adjacent to the word line contact region WCTR.

In more detail, due to the presence of the peripheral circuits and the peripheral insulating pattern 30, the stacked layer structure ST may be formed to conformally cover sidewalls of the peripheral circuits and the peripheral insulating pattern 30 in the peripheral circuit region C/P.

During repeated and anisotropic etching steps on the stacked layer structure ST, the portion covering the peripheral insulating pattern 30 of the stacked layer structure ST may remain to form remaining pattern SCF and 111′. In other words, the remaining pattern SC1′ and 111′ may be portions of the sacrificial layers SC1 to SC8 and the insulating layers 111 to 118, respectively, of the stacked layer structure ST. The remaining pattern SC1′ and 111′ may be covered with the subsequent interlayer insulating pattern 134.

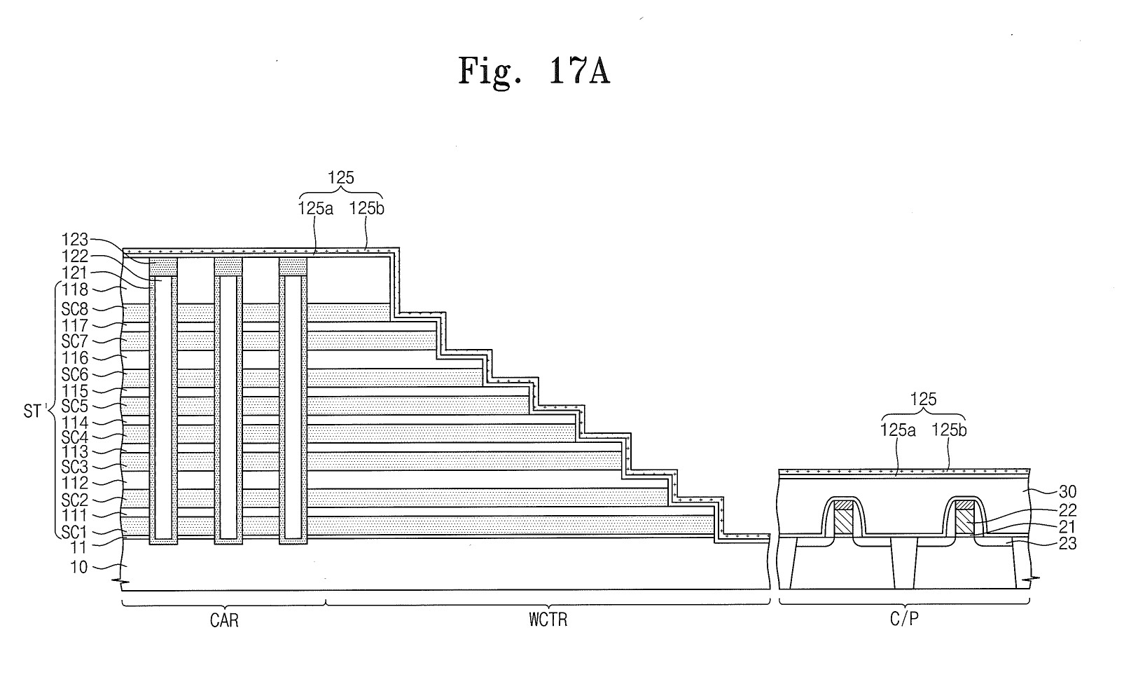

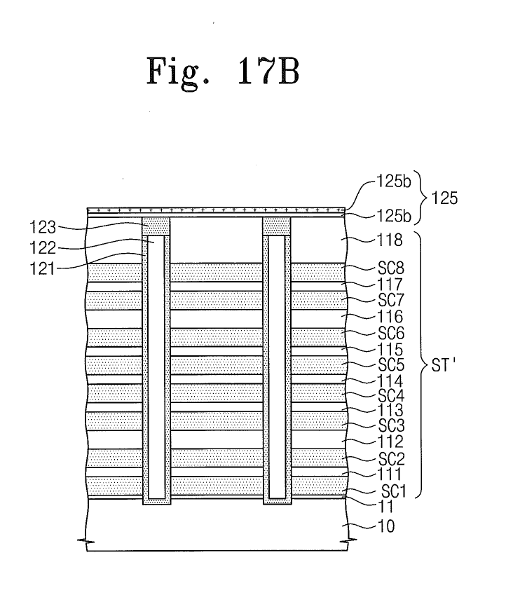

FIGS. 17A through 22A and FIGS. 17B through 22B are sectional views illustrating a method of fabricating a three-dimensional semiconductor memory device according to other example embodiments of the inventive concepts.

In these embodiments, the same elements as in the embodiments previously described with reference to FIGS. 5A through 14A and FIGS. 5B through 14B will be denoted by the same reference numbers therein, and for concise description, overlapping description of elements previously described with reference to FIGS. 5A through 14A and FIGS. 5B through 14B may be omitted.

According to other example embodiments, as shown in FIGS. 17A and 17B, an etch stop layer 125 may be conformally formed on the substrate 10, after forming the stacked layer structure ST having the stepwise structure. The etch stop layer 125 may cover an exposed surface of the stacked layer structure ST, a top surface of the peripheral insulating pattern 30, and/or a portion of a top surface of the substrate 10. The etch stop layer 125 may cover top surfaces of the contact pads 123 in the cell array region CAR and end portions of the sacrificial layers SC1 to SC8 in the word line contact region WCTR.

In some embodiments, the etch stop layer 125 may be formed of a material having an etch selectivity with respect to the stacked layer structure ST. For instance, the etch stop layer 125 may be formed of a material having an etch selectivity with respect to the sacrificial layers SC1 to SC8 and the insulating layers 111 to 118 of the stacked layer structure ST. In some embodiments, the etch stop layer 125 may include at least one of silicon carbide (SiC), silicon nitride (SiN), silicon oxynitride (SiON) and/or silicon oxycarbide (SiOC).

In some embodiments, the etch stop layer 125 may include a first stop layer 125a having an etch selectivity with respect to the sacrificial layers SC1 to SC8 and a second stop layer 125b having an etch selectivity with respect to the insulating layers 111 to 118. The first stop layer 125a may be formed to conformally cover an exposed surface of the stacked layer structure ST. In some embodiments, the first stop layer 125a may cover sidewalls of the sacrificial layers SC1 to SC8 in the contact region WCTR, and the second stop layer 125b may be conformally formed on the first stop layer 125a. In some embodiments, the first stop layer 125a may be formed of silicon oxide and the second stop layer 125b may be formed of silicon nitride. In other embodiments, the etch stop layer 125 may be a single layer, which is formed of a material having an etch selectivity with respect to the sacrificial layers SC1 to SC8 and the insulating layers 111 to 118.

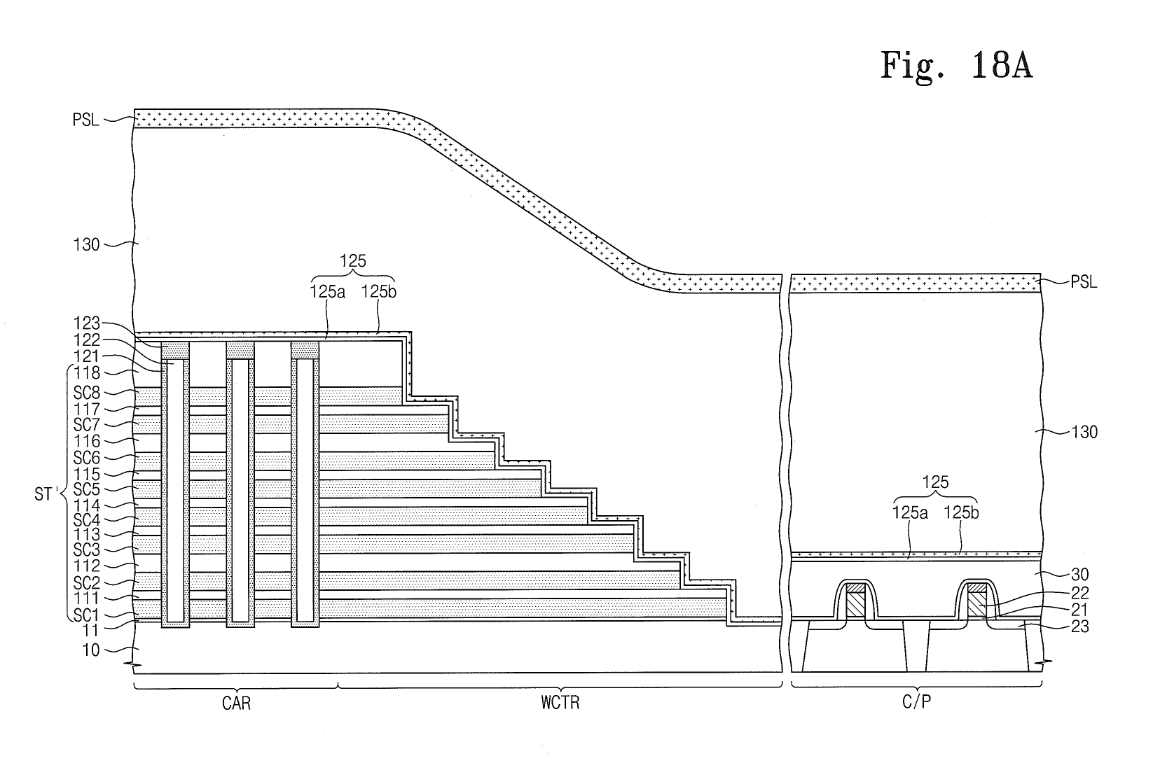

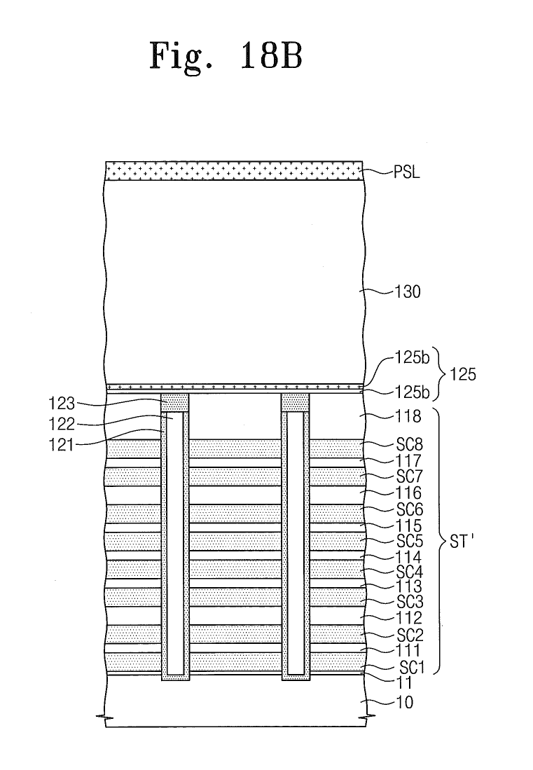

Referring to FIGS. 18A and 18B, as described with reference to FIGS. 9A and 9B, the interlayer dielectric 130 and the polishing stop layer PSL may be sequentially formed on the etch stop layer 125. The interlayer dielectric 130 may be formed to have a height difference between the cell array region CAR and the peripheral circuit region C/P, due to the height difference of the underlying structure. For instance, a top surface of the interlayer dielectric 130 on the cell array region CAR may be located at a higher level than that of the interlayer dielectric 130 on the peripheral circuit region C/P. Furthermore, the interlayer dielectric 130 may include a portion with a sloped top surface between the cell array region CAR and the peripheral circuit region C/P (i.e., on the word line contact region WCTR).

In some embodiments, the interlayer dielectric 130 may include a lower portion disposed on the peripheral circuit region C/P and an upper portion disposed on the cell array region CAR. Here, a top surface of the lower portion may be located at a higher level than that of the stacked layer structure ST. According to some aspects of the inventive concepts, a subsequent planarization process on the interlayer dielectric 130 may be easily performed, when a height difference between the top surfaces of the stacked layer structure ST and the lower portion of the interlayer dielectric 130 is small.

The polishing stop layer PSL may serve as a sacrificial layer preventing the dishing phenomenon from occurring on the word line contact region WCTR and the peripheral circuit region C/P during the planarization of the interlayer dielectric 130, as described with reference to FIGS. 9A and 9B. The polishing stop layer PSL may be formed of a material exhibiting a slower removal rate than the interlayer dielectric 130, during the planarization of the interlayer dielectric 130. In some embodiments, the polishing stop layer PSL may be formed of the substantially same material as the etch stop layer 125. For instance, the polishing stop layer PSL include at least one of silicon carbide (SiC), silicon nitride (SiN), silicon oxynitride (SiON) and/or silicon oxycarbide (SiOC).

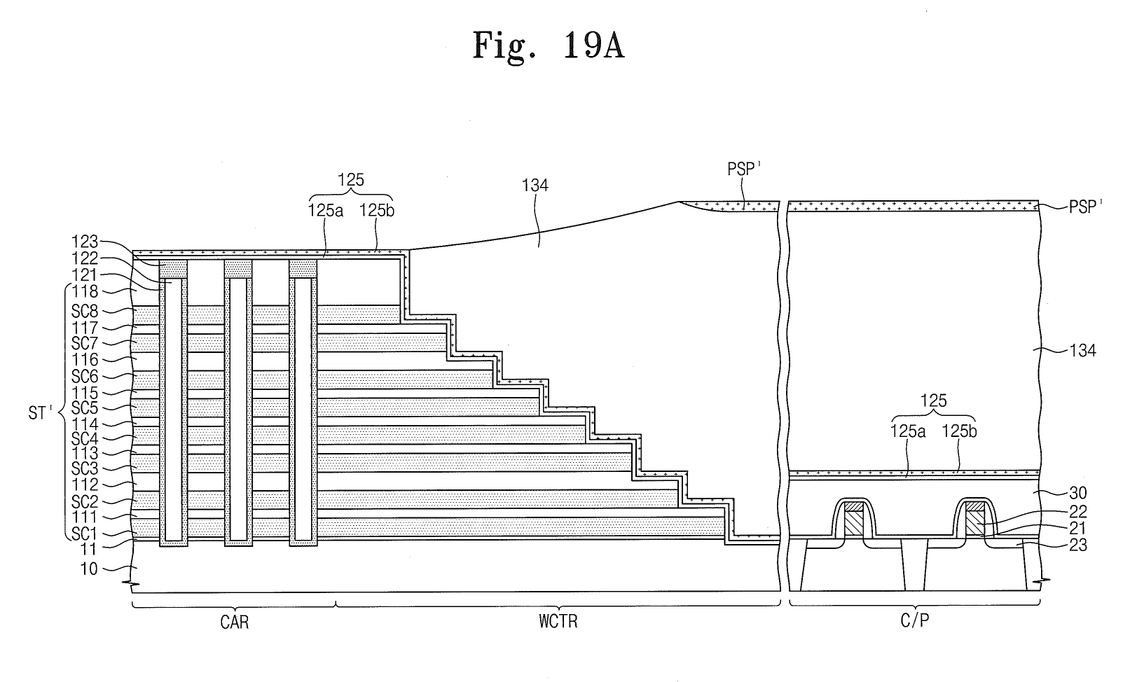

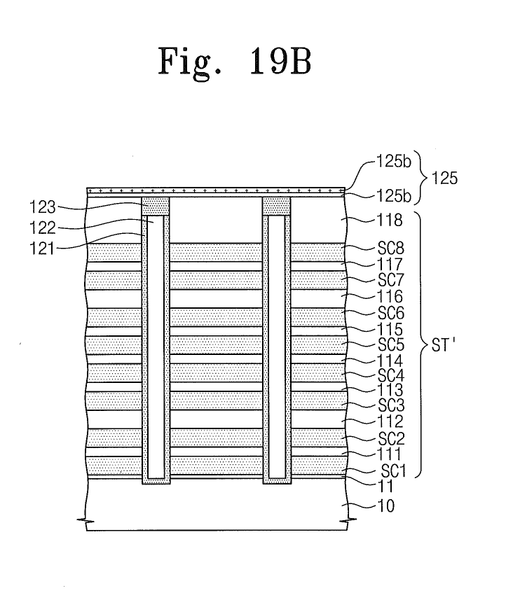

Referring to FIGS. 19A and 19B, a planarization process on the interlayer dielectric 130 may be performed using a chemical mechanical polishing (CMP) technique.

Before the planarization process on the interlayer dielectric 130, a portion disposed on the cell array region CAR of the interlayer dielectric 130 may be removed to reduce the height difference of the interlayer dielectric 130, as described with reference to FIGS. 10A and 10B. For instance, this removal process may include forming a photoresist pattern (not shown) to expose a portion disposed on the cell array region CAR of the polishing stop layer PSL and patterning the polishing stop layer PSL and the interlayer dielectric 130 using the photoresist pattern. In other words, the upper portion of the interlayer dielectric 130 may be partially removed from the cell array region CAR to reduce the height difference of the interlayer dielectric 130 between the cell array region CAR and the peripheral circuit region C/P. The sloped portion of the interlayer dielectric 130 may remain between the cell array region CAR and the peripheral circuit region C/P and protrude relative to the lower portion of the interlayer dielectric 130.

Thereafter, the planarization process on the interlayer dielectric 130 may be performed to form the interlayer insulating pattern 134 having a flat top surface on the peripheral circuit region C/P and the word line contact region WCTR, as described with reference to FIGS. 11A and 11B. The interlayer insulating pattern 134 may be formed to expose the top surface of the etch stop layer 125 in the cell array region CAR.

In detail, the planarization of the interlayer dielectric 130 may include a first polishing step of removing the sloped portion, protruding between the cell array region CAR and the peripheral circuit region C/P, of the interlayer dielectric 130 and a second polishing step of exposing the top surface of the etch stop layer 125.

In the first polishing step, a polishing time may be controlled in consideration of thicknesses of the interlayer dielectric 130 measured before/after performing the first polishing step. The first polishing step may be terminated when the highest top surface of the resultant structure is located at the substantially same level as the top surface of the recessed upper portion of the interlayer dielectric 130.

The second polishing step may be performed to expose the etch stop layer 125 on the cell array region CAR. In the second polishing step, the etch stop layer 125 on the cell array region CAR and/or the polishing stop layer PSL on the peripheral circuit region C/P may be used as a planarization stopping point. The second polishing step may be performed using a slurry having an etch selectivity (e.g., an etching rate of from 4:1 to 10:1) between the interlayer dielectric 130 and the polishing stop layer PSL.

In some embodiments, it is possible to prevent a damage on the contact pads 123 and an over polishing of the interlayer dielectric 130 during the polishing of the interlayer dielectric 130, because the contact pads 123 may be covered with the etch stop layer 125 and the interlayer dielectric 130 may be covered with the polishing stop pattern PSP′ on the peripheral circuit region C/P and the word line contact region WCTR.

The gate electrodes 161 to 168 may be formed after the formation of the interlayer insulating pattern 134. The gate electrodes 161 to 168 may be sequentially stacked on the substrate 10 and face sidewalls of the semiconductor patterns 121. The formation of the gate electrodes 161 to 168 may include forming the trenches 140 penetrating partially or fully the stacked layer structure ST between the semiconductor patterns 121 and replacing the sacrificial layers SC1 to SC8 with a conductive layer, as described with reference to FIGS. 12A and 12B.

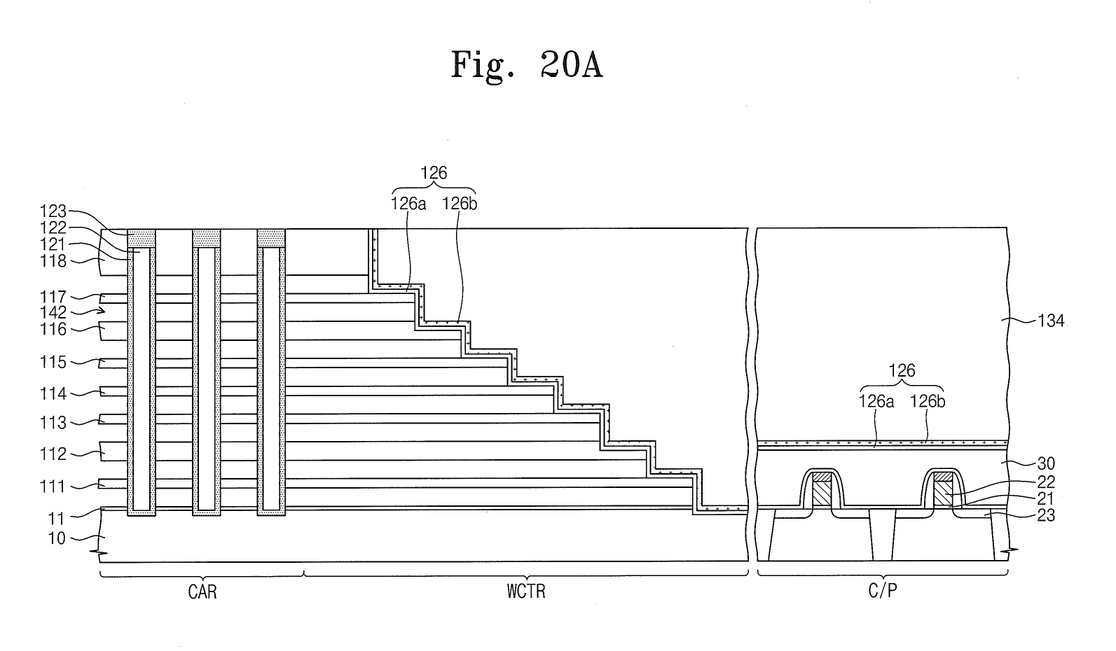

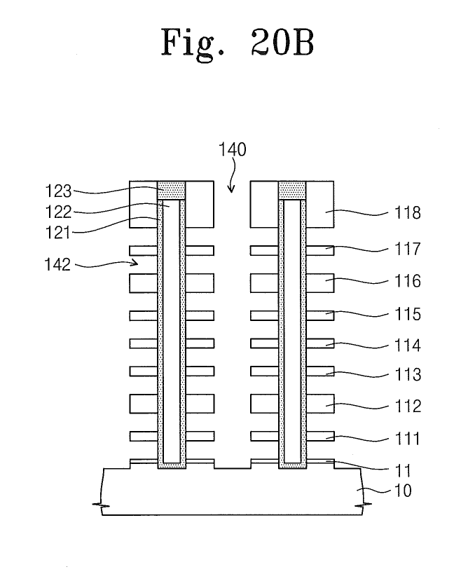

Referring to FIGS. 20A and 20B, the formation of the trenches 140 may include patterning the stacked layer structure ST to expose the substrate 10 between the semiconductor patterns 121. In some embodiments, as described with reference to FIGS. 12A and 12B, the formation of the trenches 140 may include forming a mask pattern (not shown), which defines two-dimensional arrangement positions of the trenches 140, on the stacked layer structure ST and anisotropically etching the stacked layer structure ST using the mask pattern as an etch mask.

The replacing process may include selectively removing the sacrificial layers SC1 to SC8 exposed by the trenches 140 to form recess regions 142 between the insulating layers 111 to 118, as shown in FIGS. 12A and 12B, and then forming a data storing layer 150 and gate electrodes 161 to 168 in the recess regions 142, as shown in FIGS. 13A and 13B.

In some embodiments, when the sacrificial layers SC1 to SC8 are removed, the etch stop layer 125 on the stacked layer structure ST and the polishing stop pattern PSP′ on the interlayer insulating pattern 134 may be removed along with the sacrificial layers SC1 to SC8. As a result, the etch stop layer 125 may form a stepwise etch stop pattern 126 localized on the word line contact region WCTR.

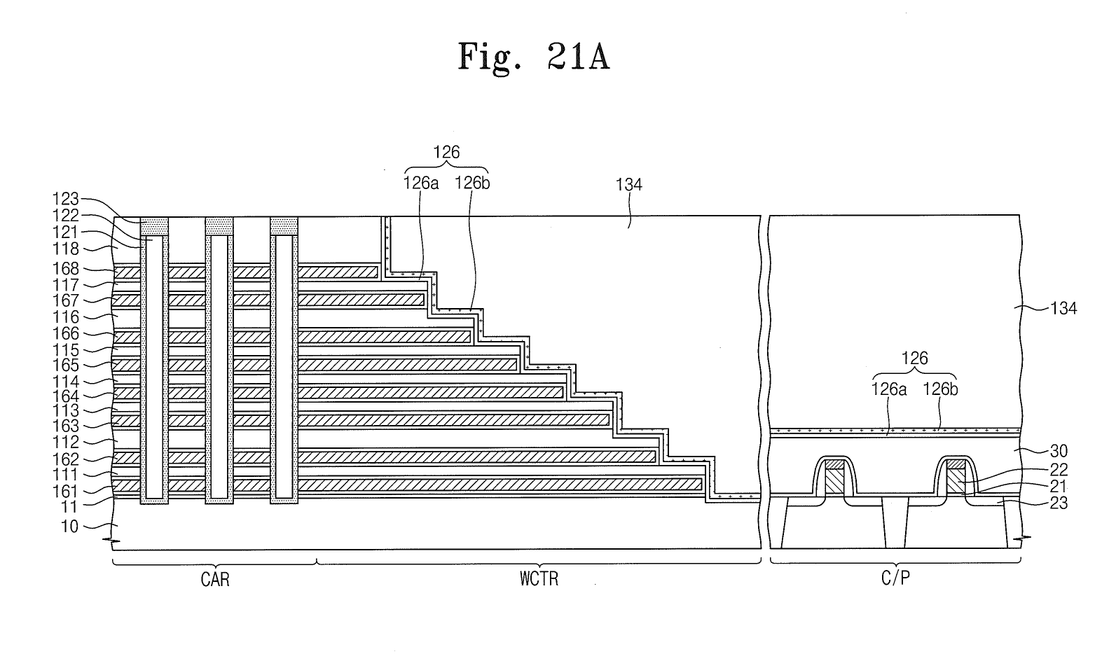

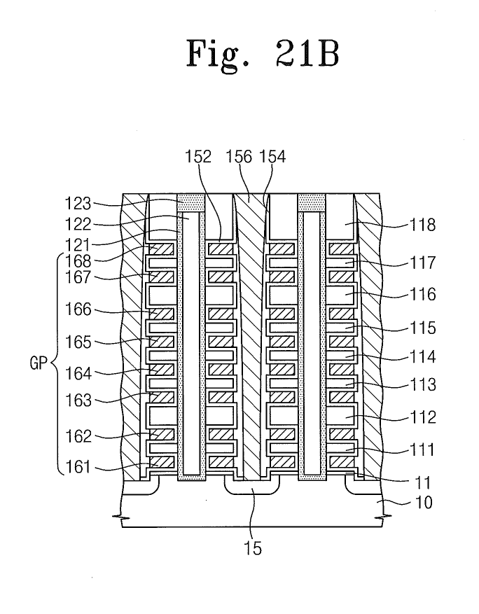

Referring to FIGS. 21A and 21B, the data storing layer 150 may be formed to conformally cover the stacked layer structure ST provided with the recess regions 142, as described with reference to FIGS. 13A and 13B. Thereafter, the gate electrodes 161 to 168 may be formed in the recess regions 142 provided with the data storing layer 150, respectively. The formation of the gate electrodes 161 to 168 may include forming a gate conductive layer in the recess regions 142 and the trench 140 provided with the data storing layer 150 as described with reference to FIGS. 13A and 13B, and then removing the gate conductive layer from the trench 140 to form the gate electrodes 161 to 168 vertically spaced apart from each other.

After the formation of the trenches 140, doped regions 15 serving as the common source line described with reference to FIG. 3 may be formed in the substrate 10 between the gate structures GP by an ion implantation process using the gate structures GP as an ion mask.

Thereafter, as shown in FIGS. 21A and 21B, a vertical conductive pattern 156 may be formed in the trench 140. The vertical conductive pattern 156 may be electrically coupled to the doped region 15. Trench spacers 154 may be additionally formed on a sidewall of the trench 140 to electrically separate the vertical conductive pattern 156 from the gate electrodes 161 to 168.

The vertical conductive pattern 156 may be formed of a metallic material (e.g., tungsten). In some embodiments, the vertical conductive pattern 156 may further include a barrier metal layer (e.g., metal nitride) or a silicide layer (not shown) interposed between the doped region 15 and the vertical conductive pattern 156. The trench spacer 154 may be formed of at least one of insulating materials (e.g., silicon oxide).

For instance, the formation of the trench spacer 154 may include forming an insulating layer to conformally cover an inner wall of the trench 140 and anisotropically etching the insulating layer to expose a top surface of the doped region 15. The data storing layer on the doped region 15 may be removed during trench the formation of the trench spacer 154. The formation of the vertical conductive pattern 156 may include forming a metal layer in the trench 140 provided with the trench spacer 154 and etching the metal layer using a planarization method. The etching of the metal layer may be performed to remove the data storing layer 150 and the etch stop layer 125 and to expose top surfaces of the contact pads 123.

The vertical conductive pattern 156 and the trench spacer 154 may be formed to be substantially perpendicular to the top surface of the substrate 10 and parallel to the gate structure GP. For instance, the vertical conductive pattern 156 may have the substantially same thickness and length as the trench 140.

The vertical conductive pattern 156 may be formed of a material having a lower resistivity than the doped region 15. Accordingly, it is possible to increase a delivery speed of electric signals to or through the doped region 15. A top surface of the vertical conductive pattern 156 may be located at a higher level than that of the uppermost gate electrode 168. This may lead to a reduction of difficulty related to a wiring process for forming an electric pathway to the doped region 15. In addition, the vertical conductive pattern 156 may serve as a shielding layer preventing an electrical cross talk between the gate electrodes 161 to 168. For instance, the vertical conductive pattern 156 may reduce a capacitive coupling between horizontally adjacent ones of the gate electrodes 161 to 168. It is possible to reduce a signal disturbance during a program or read operation.

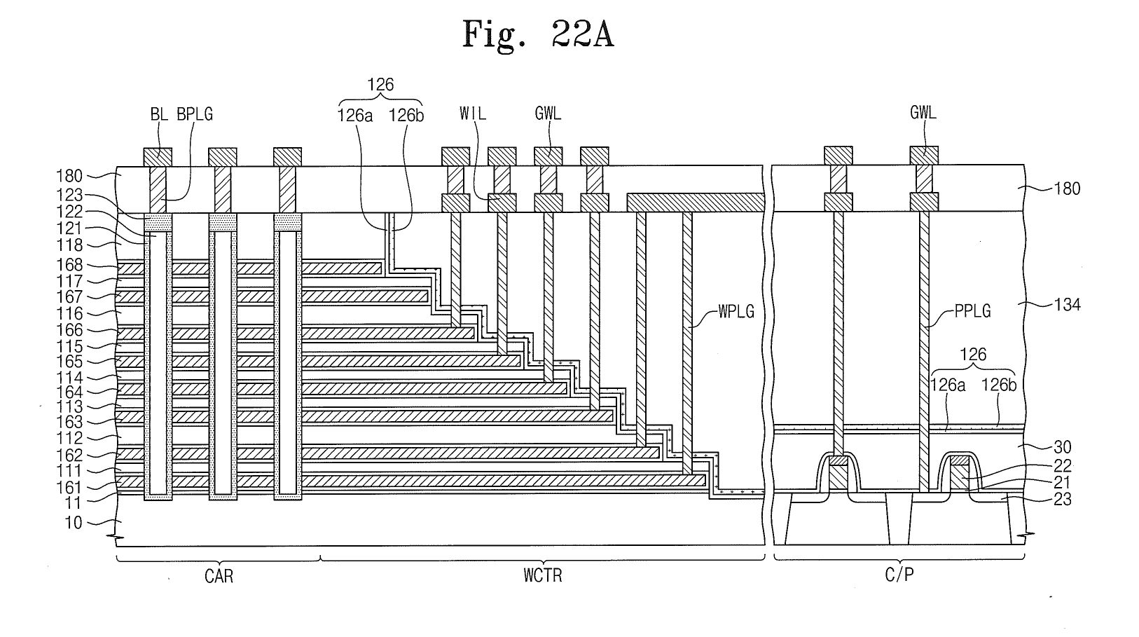

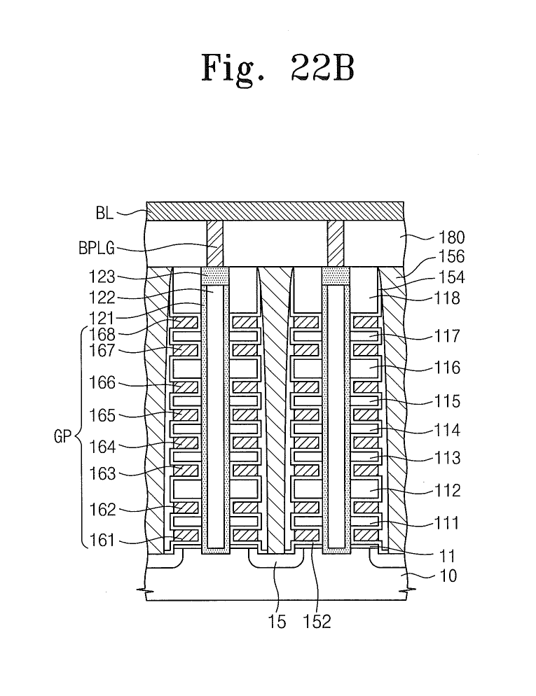

Referring to FIGS. 22A and 22B, an interconnection structure including contact plugs WPLG, PPLG and BPLG and interconnection lines WIL, GWL and BL may be formed.

The gate electrodes 161 to 168 disposed in the cell array region CAR may be electrically connected with the peripheral circuits disposed in the peripheral circuit region C/P via the global word lines GWL. For instance, in the interlayer insulating pattern 134, as described with reference to FIGS. 14A and 14B, the word line contact plugs WPLG may be formed to connect the global word lines GWL and the gate electrodes 161 to 168 and the peripheral contact plugs PPLG may be formed to connect the global word lines GWL and the peripheral circuits.

Since the gate structure GP has a stepwise structure in the word line contact region WCTR, the word line contact plugs WPLG can be connected to the gate electrodes 161 to 168 located at different levels from each other, using the same process. The peripheral contact plugs PPLG may be connected to the peripheral circuits.

In addition, as described with reference to FIGS. 14A and 14B, the semiconductor patterns 121 may be electrically connected to the bit lines BL via the contact pads 123. The bit line plugs BPLG may be formed to connect the contact pads 123 and the bit lines BL.

In other embodiments, the semiconductor patterns 121 and the contact pads 123 on the cell array region CAR may be formed after forming the interlayer insulating pattern 134. In this case, after forming the stacked layer structure ST, the etch stop layer 125 may be formed to conformally cover the stacked layer structure ST. The etch stop layer 125 may be formed of a material having an etch selectivity with respect to the interlayer dielectric 130. Thereafter, the interlayer dielectric 130 may be formed on the etch stop layer 125 and then planarized until a top surface of the etch stop layer 125 is exposed on the cell array region CAR.

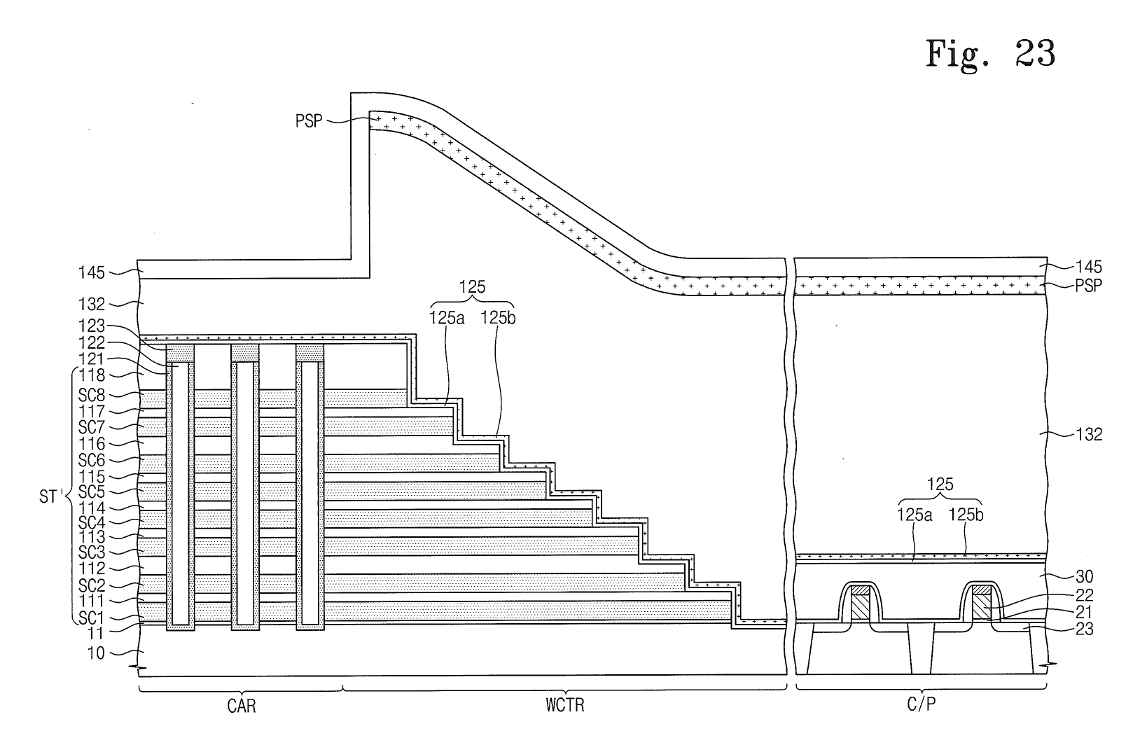

FIGS. 23 through 29 are sectional views provided for describing modifications of other example embodiments of the inventive concepts.

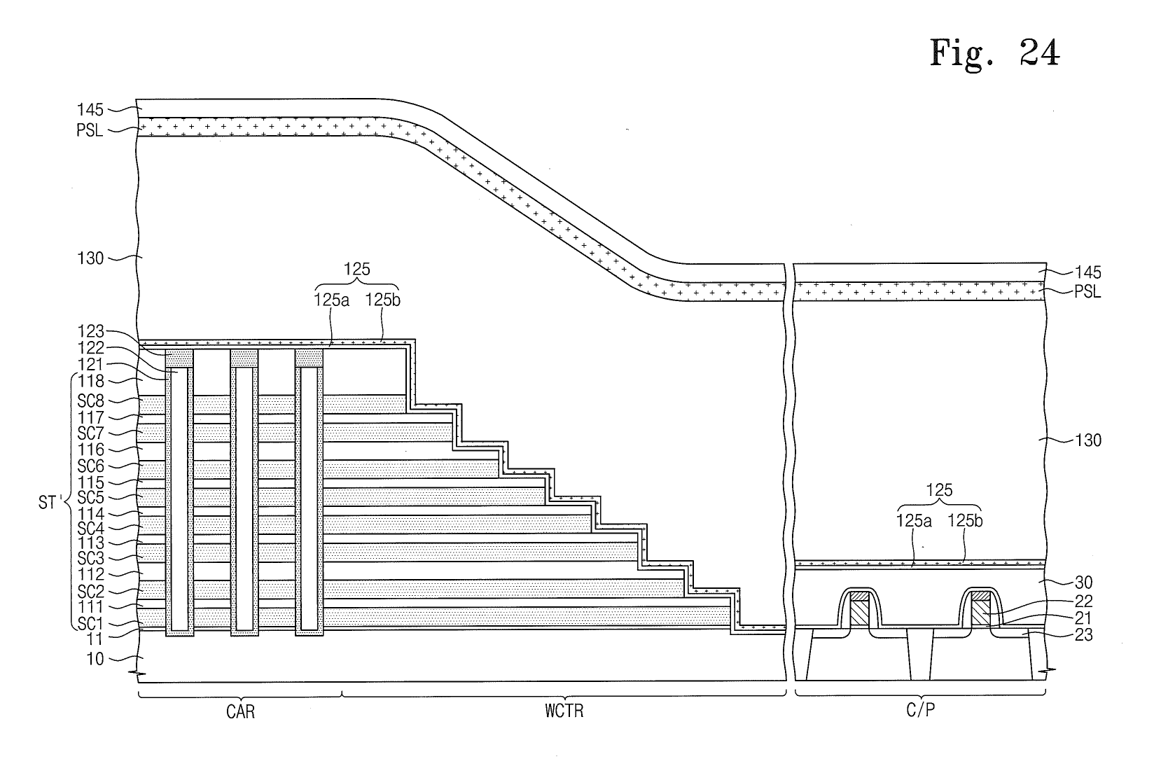

Referring to FIGS. 23 and 24, before planarizing the interlayer dielectric 130, a buffer insulating layer 145 may be formed on the polishing stop layer PSL or the polishing stop pattern PSP.

For instance, as shown in FIG. 23, the buffer insulating layer 145 may be formed after the removal of a portion on the cell array region CAR of the interlayer dielectric 130 described with reference to FIGS. 10A and 10B. In other words, the buffer insulating layer 145 may be formed on an underlying structure having a reduced height difference between the cell array region CAR and the peripheral circuit region C/P. The buffer insulating layer 145 may conformally cover a portion of the polishing stop pattern PSP on the peripheral circuit region C/P and the word line contact region WCTR and the interlayer dielectric 130 on the cell array region CAR.

Alternatively, as shown in FIG. 24, the polishing stop layer PSL and buffer insulating layer 145 may be sequentially formed on the interlayer dielectric 130 having still the upper portion. The buffer insulating layer 145 may be conformally formed on the polishing stop layer PSL.

In some embodiments, the buffer insulating layer 145 may be formed of a material having the substantially same property as the interlayer dielectric 130 and exhibiting a different removal rate from the polishing stop layer PSL during a subsequent polishing process. In other embodiments, the buffer insulating layer 145 may be formed of a material having the substantially same removal rate as the interlayer dielectric 130. Furthermore, the buffer insulating layer 145 may be formed of the same material as the interlayer dielectric 130.

In some embodiments, the subsequent CMP process on the interlayer dielectric 130 may be performed using a slurry selected in such a way that a removal rate of the buffer insulating layer 145 is faster than or equivalent to that of the interlayer dielectric 130.

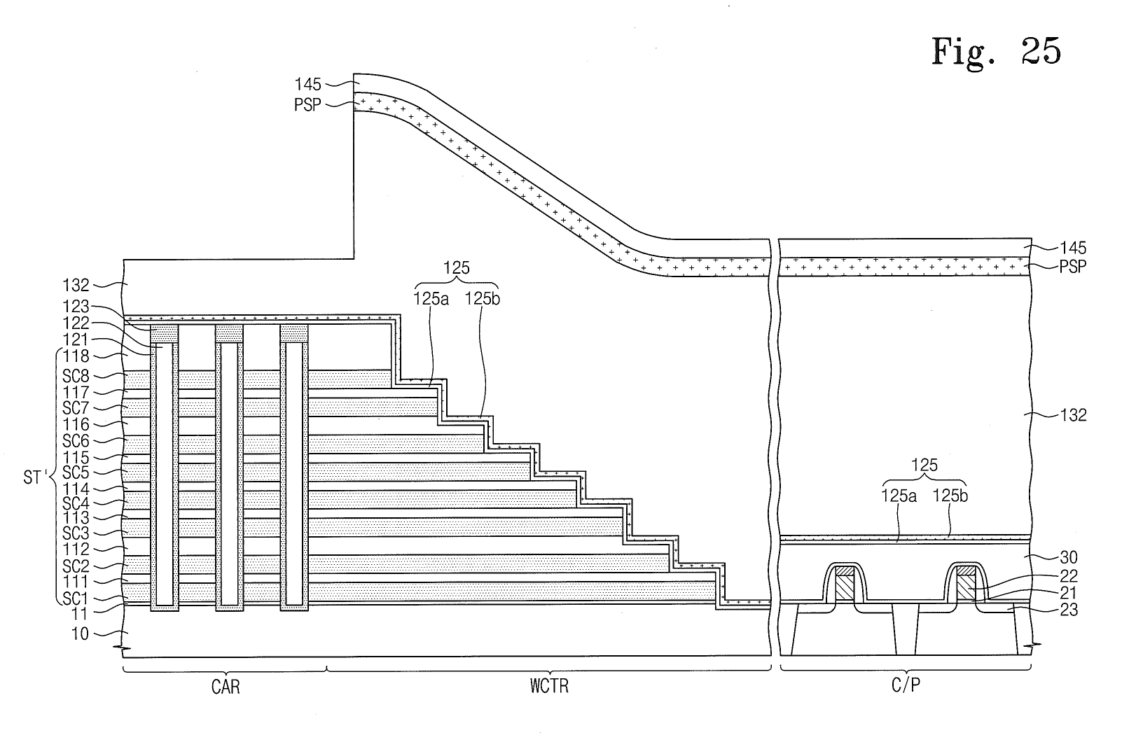

The buffer insulating layer 145, the polishing stop layer PSL and the interlayer dielectric 130 may be locally patterned on the cell array region CAR, as shown in FIG. 25.

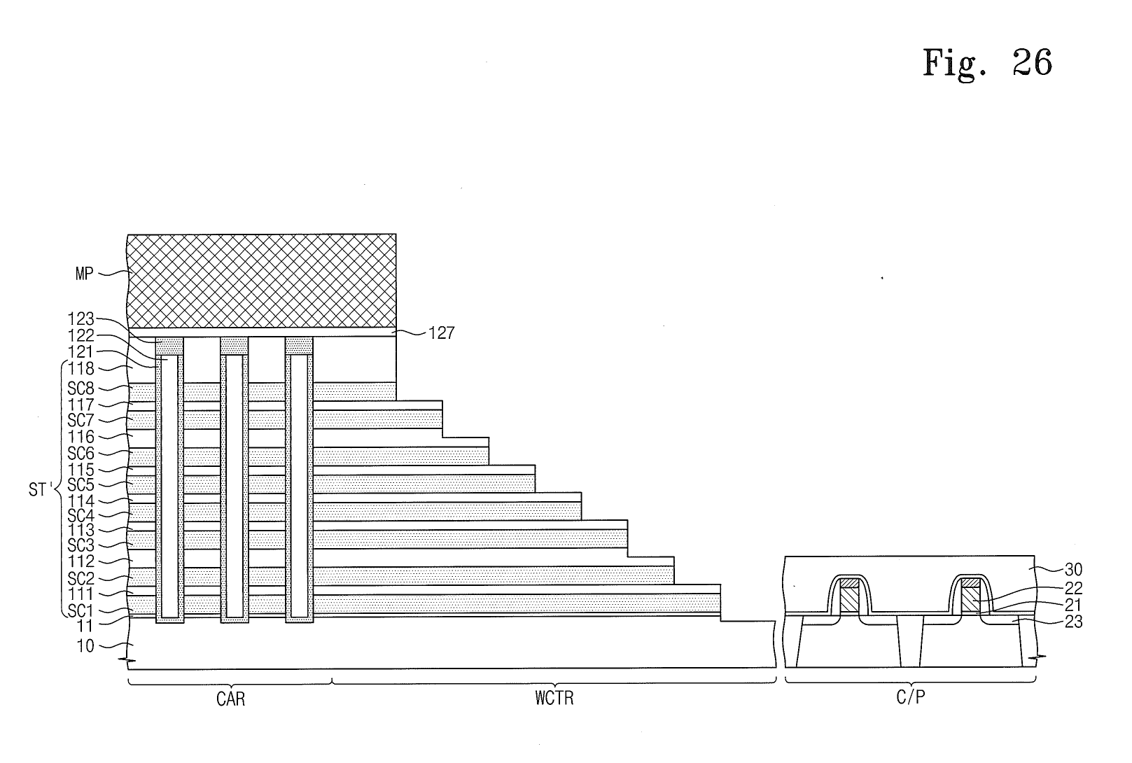

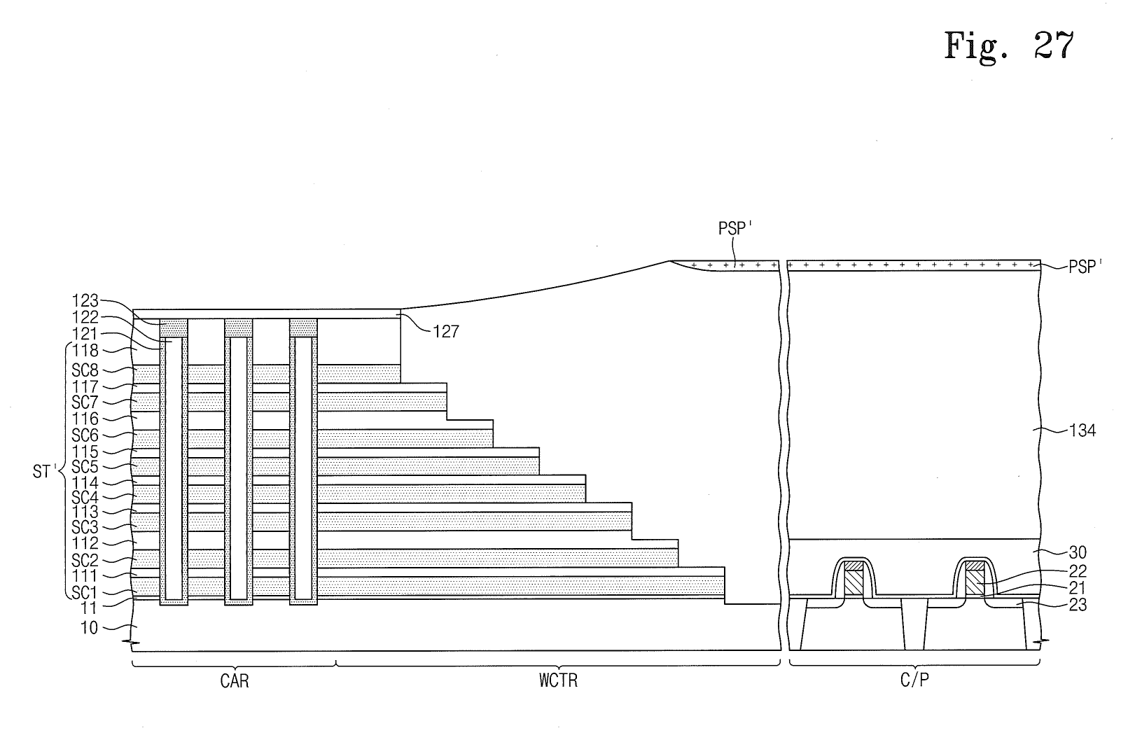

Referring to FIGS. 26 through 27, an etch stop layer 127 may be locally formed on the stacked layer structure ST in the cell array region CAR. The etch stop layer 127 may be a dual or single layer structure, described with reference to FIGS. 17A through 22A. For instance, the etch stop layer 127 may include at least one of silicon carbide (SiC), silicon nitride (SiN), silicon oxynitride (SiON) and/or silicon oxycarbide (SiOC).

The etch stop layer 127 may be formed on the whole top surface of the stacked layer structure ST before forming the stacked layer structure ST. In other words, the etch stop layer 127 may be formed between the mask pattern MP, which may be used as the etch mask for patterning the stacked layer structure ST, the stacked layer structure ST. The etch stop layer 127 may cover top surfaces of the semiconductor patterns 121 or the contact pads 123 as shown in FIG. 26.

When the stacked layer structure ST is patterned using the mask pattern MP as the etch mask as described with reference to FIGS. 8A and 8B, the etch stop layer 127 on the word line contact region WCTR may be patterned along with the stacked layer structure ST and locally remain on the stacked layer structure ST in the cell array region CAR.

The localized etch stop layer 127 may be used as an end point of the CMP process on the interlayer dielectric 130 described with reference to FIGS. 9A through 11A. For instance, the CMP process on the interlayer dielectric 130 may be terminated when an etch stop layer 127 on the cell array region CAR is exposed, as shown in FIG. 27. As a result, it is possible to prevent the contact pads 123 or the semiconductor patterns 121 from being damaged during the CMP process. The polishing stop layer PSL may prevent the dishing phenomenon from occurring on the peripheral circuit region C/P during the CMP process on the interlayer dielectric 130.

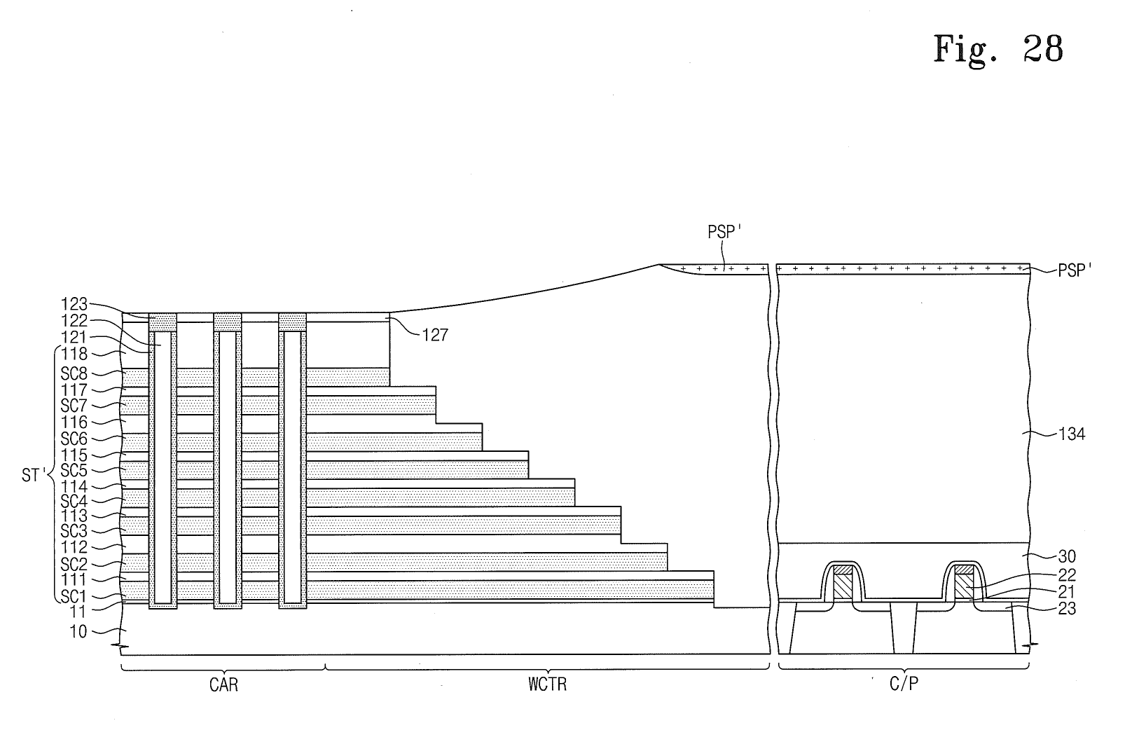

According to embodiments shown in FIG. 28, the patterning of the stacked layer structure ST for forming a stepwise structure and the formation of the planarized interlayer insulating pattern 134 may be followed by the formation of the semiconductor patterns 121 and the contact pads 123 on the cell array region CAR. In other words, as described with reference to FIGS. 9A through 11A, after the planarization process on the interlayer dielectric 130, the semiconductor patterns 121 and the contact pads 123 may be formed on the cell array region CAR. Referring to FIG. 28, the etch stop layer 127 may be partially formed on the cell array region CAR before forming the interlayer dielectric 130 to cover the stacked layer structure ST. The etch stop layer 127 may be used as an end point of a planarization process on the interlayer dielectric 130 as described with reference to FIGS. 26 and 27. Thereafter, as described with reference to FIGS. 6A through 7B, openings may be formed on the cell array region CAR to penetrate the stacked layer structure ST, and the semiconductor patterns 121 and the contact pads 123 may be formed in the openings. The etch stop layer 127 may be patterned during the formation of the openings penetrating the stacked layer structure ST.

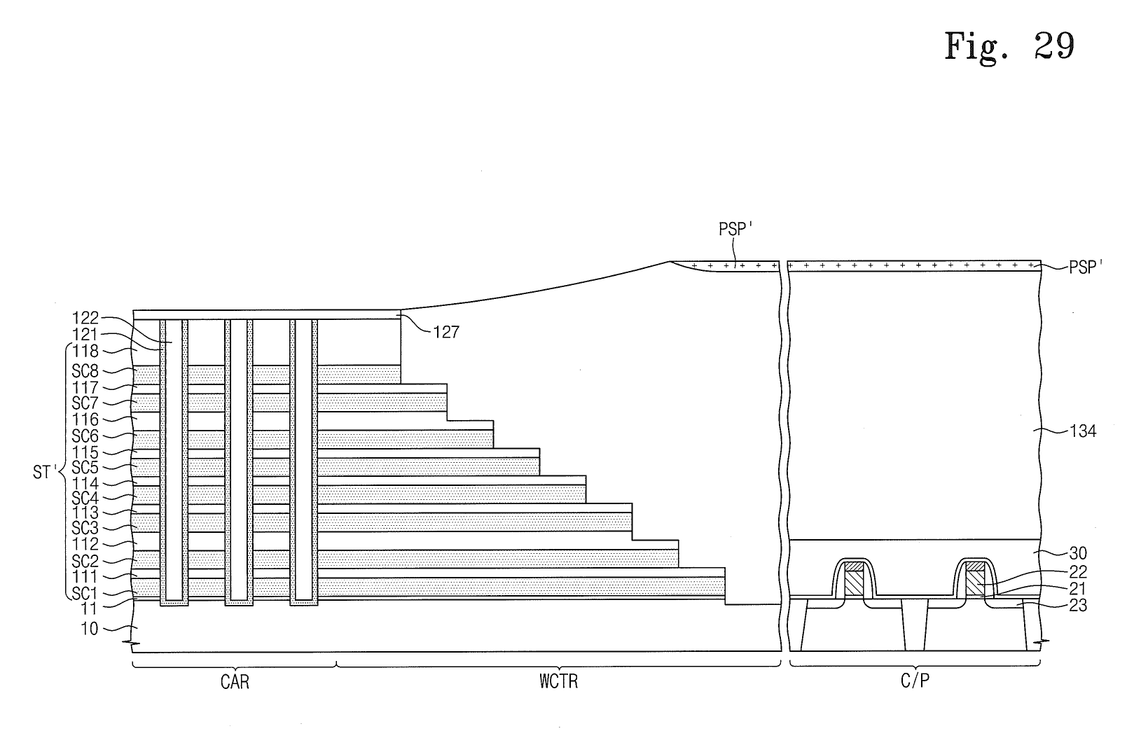

According to embodiments shown in FIGS. 29 and 30, contact pads BLPAD may be formed on the semiconductor patterns 121. The contact pads BLPAD may be formed during the formation of the interconnection lines WIL and GWL. In some embodiments, the contact pads BLPAD may be used as a polishing stop point of the planarization process on the interlayer dielectric 130. The contact pads BLPAD may include a metallic material; for instance, the formation of the contact pads BLPAD may include sequentially forming a barrier metal layer (e.g., metal nitride) and a metal layer (e.g., tungsten).

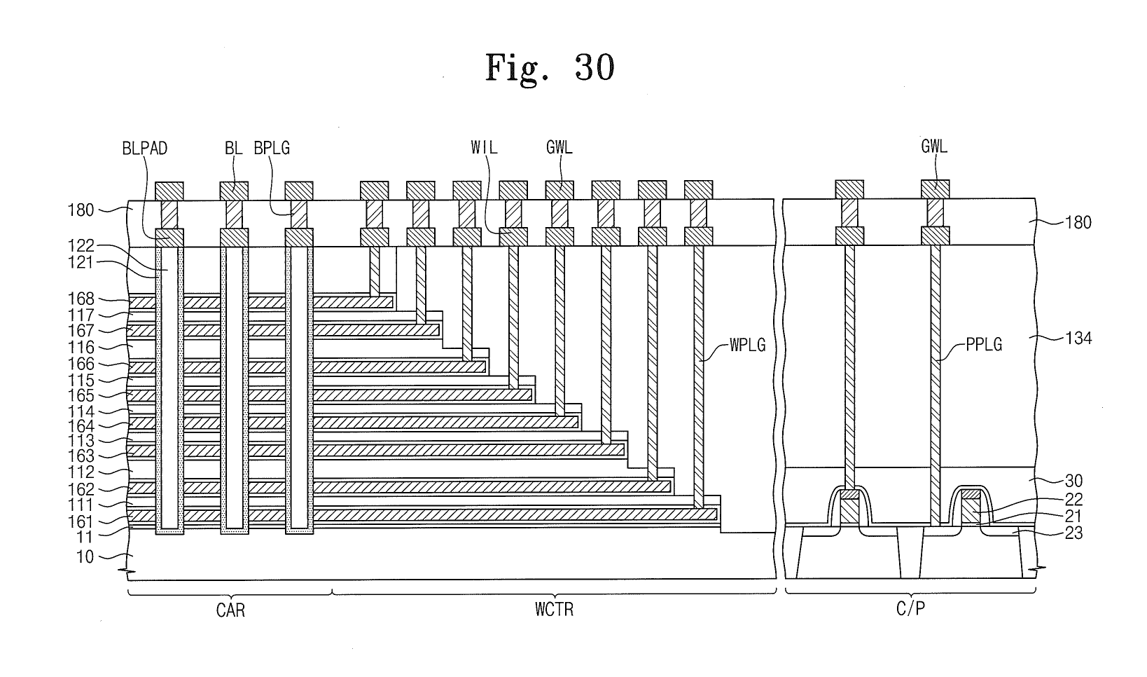

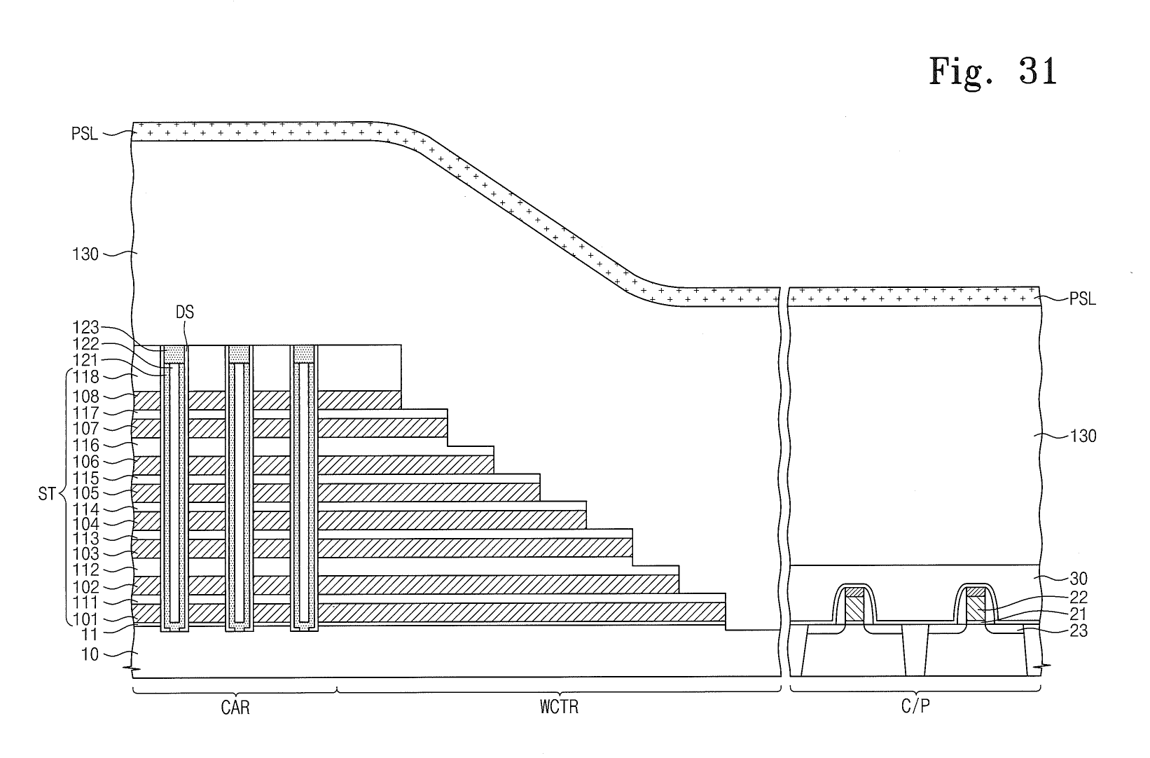

FIGS. 31 through 34 are sectional views illustrating methods of fabricating a three-dimensional semiconductor memory device according to still other embodiments of the inventive concepts.

In these embodiments, the same elements as in the embodiments previously described with reference to FIGS. 5A through 14A and FIGS. 5B through 14B will be denoted by the same reference numbers therein, and for concise description, overlapping description of elements previously described with reference to FIGS. 5A through 14A and FIGS. 5B through 14B may be omitted.

According to still other embodiments, as described with reference to FIGS. 5A and 5B, the peripheral circuits and the peripheral insulating pattern 30 may be formed on the peripheral circuit region C/P, and the stacked layer structure ST may be formed on the cell array region CAR and the word line contact region WCTR. In some embodiments, the stacked layer structure ST may include gate conductive layers 101 to 108 and the insulating layers 111 to 118 alternatingly stacked on the substrate 10.

The gate conductive layers 101 to 108 may be a polysilicon or amorphous silicon layer doped with n- or p-type impurities (e.g., boron or phosphorous). A lower gate insulating layer 11 may be formed between the lowermost gate conductive layer 101 and the substrate 10. The lower gate insulating layer 11 may be thinner than the gate conductive layers 101 to 108 or the insulating layers 111 to 118, and formed of oxide (e.g., thermal oxide).

The gate conductive layers 101 to 108 may serve as the word lines WL01 to WL3 and the selection lines GSL and SSL described with reference to FIG. 2. In some embodiments, the gate conductive layers 101 to 108 may be formed using a deposition technique, and vertical thicknesses of the gate conductive layers 101 to 108 may define channel lengths of vertical transistors (e.g., MCT of FIG. 2) using the gate conductive layers 101 to 108 as their gate electrodes. As a result, each of the vertical transistors according to example embodiments of the inventive concepts may have a more precisely controlled channel length, compared with using a patterning method to define the channel length.

Spaces between vertically adjacent ones of the gate conductive layers 101 to 108 or thicknesses of the insulating layers 111 to 118 may be controlled in such a way that two adjacent inversion regions can be overlap with each other in the semiconductor pattern 121. In some embodiments, the gate conductive layers 101 to 108 may be formed to have the substantially same thickness. In other embodiments, the uppermost and lowermost gate conductive layers 101 and 108 may be thicker than other gate conductive layers 102 to 107 interposed therebetween. Some of the insulating layers (e.g., 112 and 117) may be thicker than other insulating layers (e.g., 111, 113 to 116, and 118). The layer number, thicknesses and materials of layers constituting the stacked layer structure ST may be variously modified in consideration of electric characteristics of the memory cell transistor and technical difficulties in subsequent patterning processes.

In some embodiments, a doped region 15 may be formed in the substrate 10 before the formation of the stacked layer structure ST. The doped region 15 may be used as a common source line (e.g., CSL of FIG. 2).

Thereafter, as described with reference to FIGS. 6A and 6B, the stacked layer structure ST may be patterned to form openings 120 exposing the substrate 10. The formation of the openings 120 may include forming the mask pattern (not shown), which may define two-dimensional arrangement of the openings 120, on the stacked layer structure ST, and then anisotropically etching the stacked layer structure ST using the mask pattern as an etch mask. A top surface of the substrate 10 may be recessed by a specific depth, due to an over-etching during forming the openings 120.

Next, a data storing layer DS and a semiconductor pattern 121 may be formed in the openings 120, as shown in FIG. 31.

The data storing layer DS may be formed using a deposition technique (e.g., a CVD or ALD technique) capable of providing an excellent step coverage property. The data storing layer DS may be formed to have a smaller thickness than half a width of the opening 120. Accordingly, the data storing layer DS may be formed to partially cover the sidewalls of the gate conductive layers 101 to 108 and the insulating layers 111 to 118 exposed by the opening 120. In addition, since the formation of the data storing layer DS may be performed using the deposition technique, the data storing layer DS may be conformally deposited on the top surface of the substrate 10 exposed by the opening 120. The data storing layer DS may be a charge storing layer. For example, the data storing layer DS may include one of a charge trap insulating layer, a floating gate electrode, or an insulating layer including conductive nanodots. In some embodiments, the data storing layer DS may include a blocking insulating layer, a charge trap layer and a tunnel insulating layer stacked sequentially.

In some embodiments, the semiconductor pattern 121 in the opening 120 may be electrically connected to the substrate 10. For instance, the data storing layer DS may be patterned to expose the top surface of the substrate 10, before forming the semiconductor pattern 121 in the openings 120. The patterning of the data storing layer DS may include forming mask spacers (not shown) in the opening 120 to cover an inner sidewall of the data storing layer DS. The mask spacers may suppress an etch damage on the data storing layer DS, which may occur during patterning the data storing layer DS. The mask spacers may include at least one material having an etch selectivity with respect to the data storing layer DS and/or the semiconductor pattern 121. For instance, when the data storing layer DS is formed of silicon oxide, the mask spacers may be formed of silicon nitride. In modified embodiments, the mask spacers may be formed of the same material as the semiconductor pattern 121. For example, the mask spacers may be formed of amorphous or polycrystalline silicon. In this case, the mask spacer may not be removed to serve as a portion of the semiconductor pattern 121. The data storing layer DS may be etched using the mask spacer as an etch mask. As a result, the top surface of the substrate 10 may be exposed under the openings 120. The mask spacers may be removed using an etching method having an etch selectivity with respect to the data storing layer DS, after etching the data storing layer DS.

The semiconductor pattern 121 may be formed to cover the data storing layer DS and be in contact with the substrate 10 via a bottom surface of the opening 120. The semiconductor pattern 121 may be shaped like a pipe, a hollow cylinder, a shell, or a cup. A gap-fill insulating pattern 122 may be formed to fill an empty space defined by the semiconductor pattern 121. In other embodiments, the semiconductor pattern 121 may be deposited to fill the opening 120.

The contact pads 123 may be formed on the semiconductor patterns 121, respectively. The contact pads 123 may be formed on the gap-fill insulating pattern 122 and/or the semiconductor pattern 121. In some embodiments, the contact pads 123 may be formed of doped polysilicon. Alternatively, the contact pad 123 may be formed by doping an upper portion of the semiconductor pattern 121 with dopants. The contact pads 123 may have a different conductivity type from the semiconductor pattern 121, and thus, the contact pad 123 and the semiconductor pattern 121 may constitute a rectifying element such as a diode.

Similar to the embodiments described with reference to FIGS. 8A and 8B, the stacked layer structure ST may be patterned to form a stepwise stacked layer structure sr that has a contact portion of stepwise shape on the word line contact region WCTR. Since the stepwise stacked layer structure ST′ may have the stepwise structure, the insulating layers 111 to 118 and/or the sacrificial layers SC1 to SC8 thereof may have the edge portions sequentially exposed on the word line contact region WCTR. The farther a distance from the insulating layers 111 to 118 and the sacrificial layers SC1 to SC8 to the substrate 10 is, the smaller the area occupied by the insulating layers 111 to 118 and the sacrificial layers SC1 to SC8 may be. In other words, as the sacrificial layers SC1 to SC8 and the insulating layers 111 to 118 are vertically farther from the substrate 10, sidewalls of the sacrificial layers SC1 to SC8 and the insulating layers 111 to 118 are laterally farther from the peripheral circuit region C/P.

During the patterning of the stacked layer structure ST, a portion covering the peripheral insulating pattern 30 of the stacked layer structure ST may remain to form remaining pattern SC1′ and 111′, similar to the embodiments described with reference to FIG. 16. In other words, the remaining pattern SC1′ and 111′ may be formed on a sidewall of the peripheral insulating pattern 30 to have a spacer shape. The remaining pattern SC1′ and 111′ may be portions of the sacrificial layers SC1 to SC8 and the insulating layers 111 to 118, respectively, of the stacked layer structure ST.

Thereafter, the interlayer dielectric 130 may be formed on the whole top surface of the substrate 10 to cover the stepwise stacked layer structure ST′ and the peripheral circuits, as described with reference to FIGS. 9A and 9B. The interlayer dielectric 130 may have such a sufficient thickness that an top surface of the interlayer dielectric 130 on the peripheral circuit region C/P can be located at a higher level than the top surface of the stepwise stacked layer structure ST′ (e.g., a top surface of the contact pads 123).

The interlayer dielectric 130 may have a top surface morphology depending on the underlying structure. For instance, a top surface of the interlayer dielectric 130 may be higher in the cell array region CAR than in the peripheral circuit region C/P. In addition, the interlayer dielectric 130 may have a portion having an inclined top surface between the cell array region CAR and the peripheral circuit region C/P (i.e., on the word line contact region WCTR).

In some embodiments, the interlayer dielectric 130 may include an upper portion disposed on the cell array region CAR, a lower portion disposed on the peripheral circuit region C/P, and a sloped portion connecting the upper portion with the lower portion. The upper portion, the sloped portion, and the lower portion may be continuously connected with each other without. The upper portion and the sloped portion of the interlayer dielectric 130 may cover a central portion including the contact pads 123 and the stepwise contact portion of the stepwise stacked layer structure ST′, respectively. The lower portion may cover the peripheral circuits, and further, extend toward the word line contact region WCTR to partially cover an edge portion of the stepwise stacked layer structure ST′.

Next, a polishing stop layer PSL may be conformally formed on the interlayer dielectric 130 having the height difference between the cell array region CAR and the peripheral circuit region C/P.

The polishing stop layer PSL may be formed of a material having a slower etch rate than the interlayer dielectric 130 in a subsequent CMP process on the interlayer dielectric 130. Moreover, the polishing stop layer PSL may be formed at a higher level than a top surface of the stacked layer structure ST or the contact pad 123.

Referring to FIG. 32, the interlayer dielectric 130 may be planarized using a polishing method. The planarization of the interlayer dielectric 130 may be performed using, for instance, the methods described with reference to FIGS. 10A and 11A and FIGS. 10B and 10B. For example, the planarization of the interlayer dielectric 130 may include partially removing the upper portion of the interlayer dielectric 130 to reduce the height difference between the cell array region CAR and the peripheral circuit region C/P as described with reference to FIGS. 10A and 10B, and then performing the first and second polishing steps described with reference to FIGS. 11A and 11B.

In some embodiments, the planarization process on the interlayer dielectric 130 may be performed until the contact pads 123 are exposed on the cell array region CAR. After the planarization process, a polishing stop pattern PSP′ having a different removal rate from the interlayer dielectric 130 may remain on the interlayer dielectric 130 in the peripheral circuit region C/P and the word line contact region WCTR. Due to the presence of the polishing stop pattern PSP′, it is possible to prevent a dishing issue of an interlayer insulating pattern 134 from occurring on the peripheral circuit region C/P and the word line contact region WCTR. The polishing stop pattern PSP′ may extend from the peripheral circuit region C/P to the word line contact region WCTR to cover a portion of the interlayer insulating pattern 134. The polishing stop pattern PSP′ may be disposed on an outer edge of the stepwise end portion of the stacked layer structure ST as shown.

After finishing the first and second polishing steps, the polishing stop pattern PSP′ may be removed. For instance, the removal of the polishing stop pattern PSP′ may include anisotropically or isotropically etching the polishing stop pattern PSP′ using an etchant having an etch selectivity with respect to the interlayer insulating pattern 134 and the contact pads 123. In some embodiments, the polishing stop pattern PSP′ may be formed of silicon nitride, and in this case, the removal of the polishing stop pattern PSP′ may be performed by an isotropic etching process using, for example, an etchant with phosphoric acid.

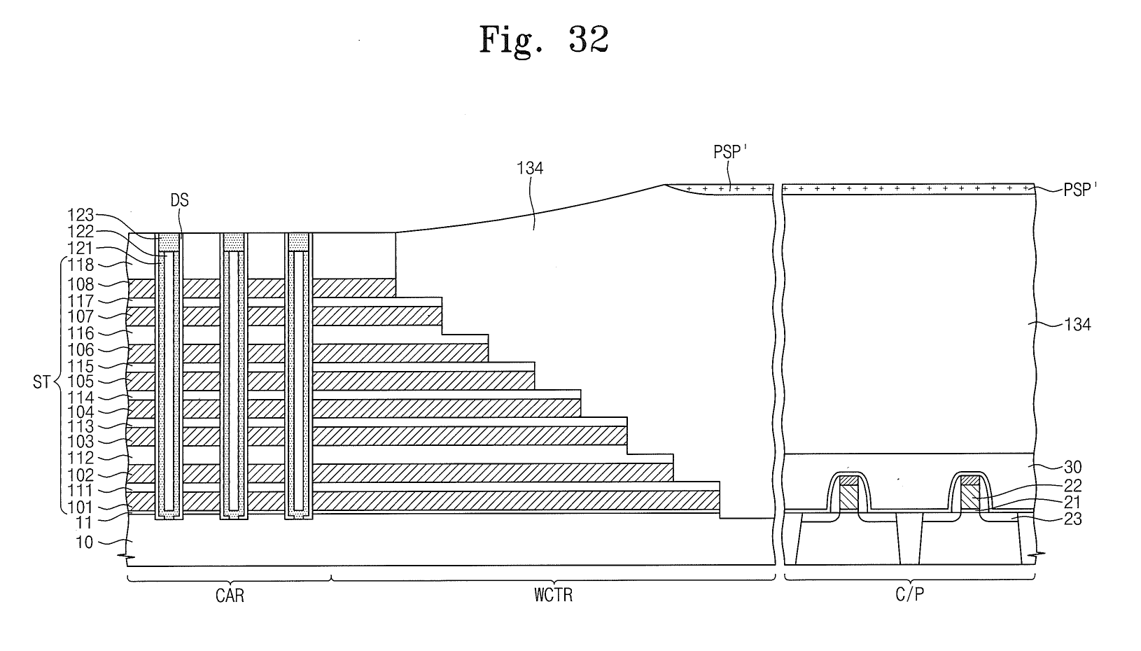

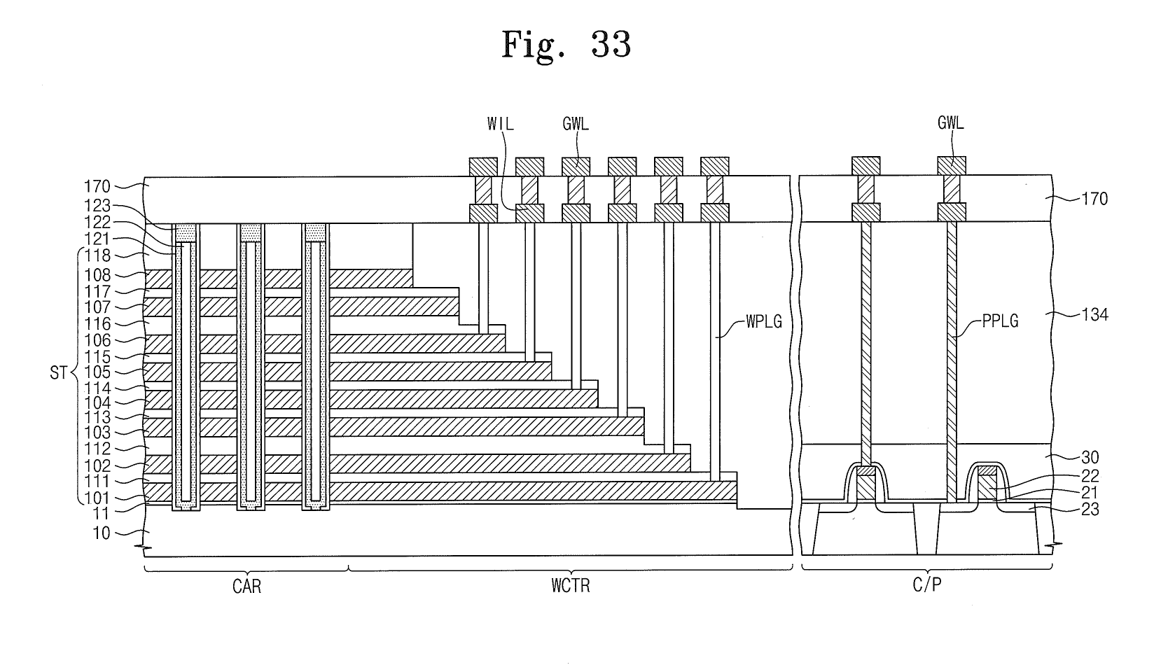

Referring to FIG. 33, an interconnection structure including contact plugs WPLG, PPLG and BPLG and interconnection lines WIL, GWL and BL may be formed.

Each of the gate conductive layers 101 to 108 may be electrically connected with the peripheral circuits disposed in the peripheral circuit region C/P via the global word lines GWL. For instance, similar to the embodiments described with reference to FIGS. 14A and 14B, the word line contact plugs WPLG may be formed in the interlayer insulating pattern 134 to connect the global word lines GWL and the gate conductive layers 101 to 108, and the peripheral contact plugs PPLG may be formed in the interlayer insulating pattern 134 to connect the global word lines GWL and the peripheral circuits.

Since the stepwise stacked layer structure ST′ has a stepwise structure in the word line contact region WCTR, the word line contact plugs WPLG can be connected to the gate conductive layers 101 to 108 located at different levels from each other, by the same process. The peripheral contact plugs PPLG may be connected to the peripheral circuits. In some embodiments, the gate conductive layers 101 to 108 may be shaped like a plate or a line. The word line connecting lines WIL may connect some of the gate conductive layers 101 to 108 disposed at the same level with each other.

Similar to the embodiments described with reference to FIGS. 14A and 14B, the semiconductor patterns 121 may be electrically connected to the bit lines BL via the contact pads 123. The bit line plugs BPLG may be formed to connect the contact pads 123 and the bit lines BL.

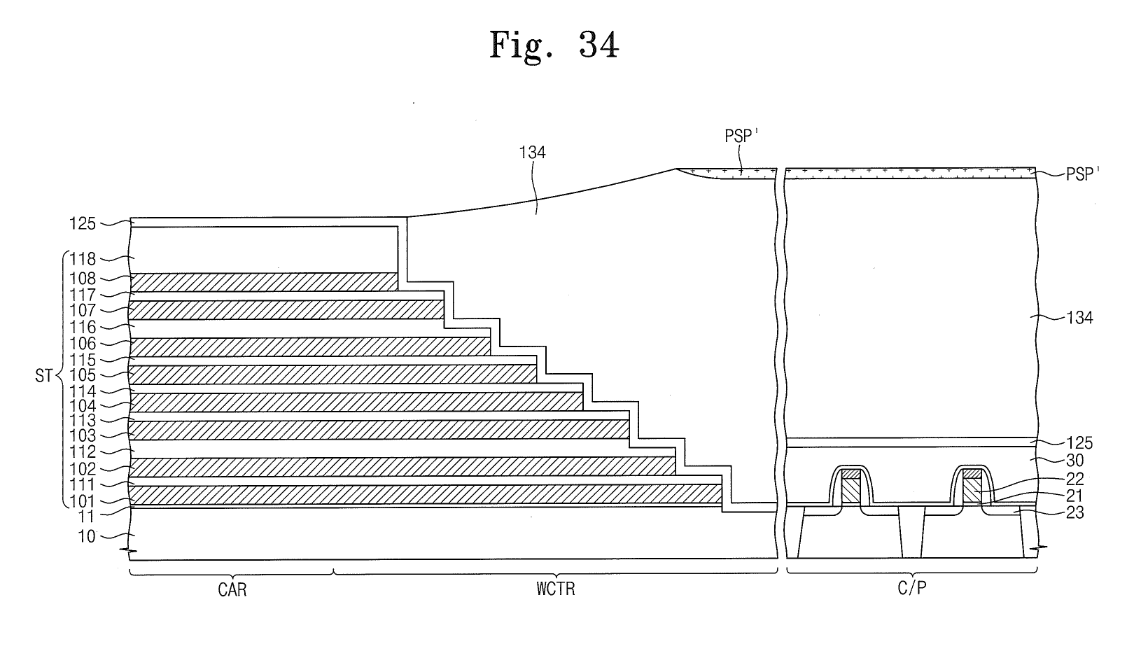

FIG. 34 is a sectional view illustrating methods of fabricating a three-dimensional semiconductor memory device according to modifications of the still other embodiments of the inventive concepts.

Referring to FIG. 34, before the formation of the semiconductor patterns 121, the stacked layer structure ST may be patterned to form a stepwise stacked layer structure ST′ that has a contact portion of stepwise shape on the word line contact region WCTR.

In some embodiments, an etch stop layer 125 may be formed to conformally cover the stacked layer structure ST. In other embodiments, the etch stop layer 125 may be formed after patterning the stacked layer structure ST provided with the semiconductor patterns 121, as shown in FIG. 31.

In some embodiments, during the planarization of the interlayer dielectric 130, a polishing process may be performed until the etch stop layer 125 is exposed.

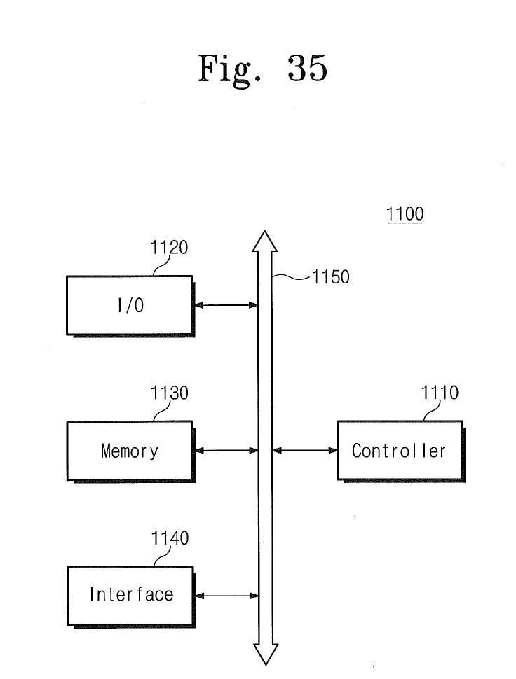

FIG. 35 is a block diagram illustrating an example of a memory system including a semiconductor memory device according to some embodiments of the inventive subject matter.

Referring to FIG. 35, a memory system 1100 can be applied to a PDA (personal digital assistant), a portable computer, a web tablet, a wireless phone, a mobile phone, a digital music player, a memory card and/or all the devices that can transmit and/or receive data in a wireless communication environment.

The memory system 1100 includes a controller 1110, an input/output device 1120 such as a keypad and a display device, a memory 1130, an interface 1140 and a bus 1150. The memory 1130 and the interface 1140 communicate with each other through the bus 1150.

The controller 1110 includes at least one microprocessor, at least one digital signal processor, at least one micro controller or other process devices similar to the microprocessor, the digital signal processor and the micro controller. The memory 1130 may be used to store an instruction executed by the controller 1110. The input/output device 1120 can receive data or a signal from the outside of the system 1100 or transmit data or a signal to the outside of the system 1100. For example, the input/output device 1120 may include a keyboard, a keypad and/or a displayer.

The memory 1130 includes the nonvolatile memory device according to embodiments of the inventive subject matter. The memory 1130 may further include a different kind of memory, a volatile memory device capable of random access and various kinds of memories.

The interface 1140 transmits data to a communication network or receives data from a communication network.

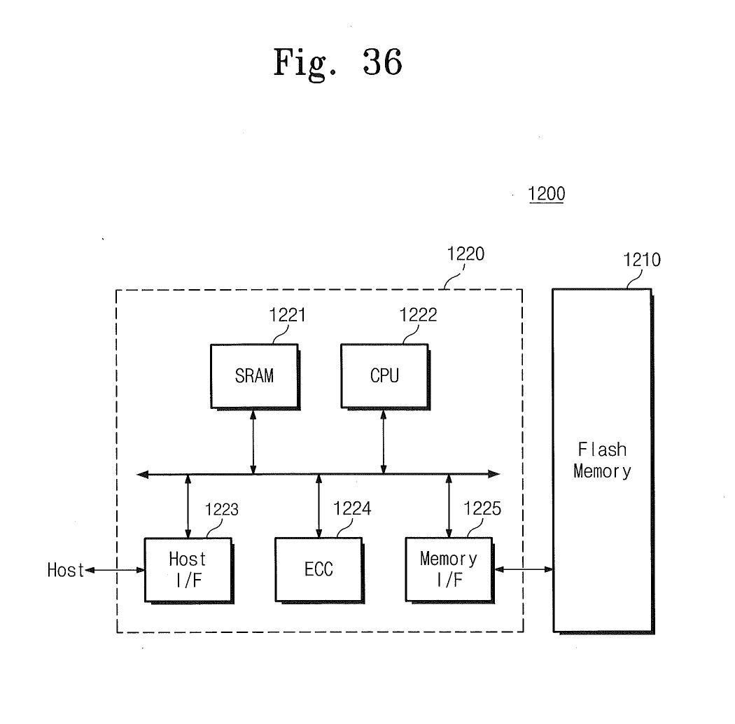

FIG. 36 is a block diagram illustrating an example of a memory card including a semiconductor memory device according to some embodiments of the inventive subject matter.

Referring to FIG. 36, the memory card 1200 for supporting a storage capability of a large capacity is fitted with a flash memory device 1210 according to some embodiments of the inventive subject matter. The memory card 1200 according to some embodiments of the inventive subject matter includes a memory controller 1220 controlling every data exchange between a host and the flash memory device 1210.

A static random access memory (SRAM) 1221 is used as an operation memory of a processing unit 1222. A host interface 1223 includes data exchange protocols of a host to be connected to the memory card 1200. An error correction block 1224 detects and corrects errors included in data readout from a multi bit flash memory device 1210. A memory interface 1225 interfaces with the flash memory device 1210 of some embodiments of the inventive subject matter. The processing unit 1222 performs every control operation for exchanging data of the memory controller 1220. Even though not depicted in drawings, it is apparent to one of ordinary skill in the art that the memory card 1200 according to some embodiments of the inventive subject matter can further include a ROM (not shown) storing code data for interfacing with the host.

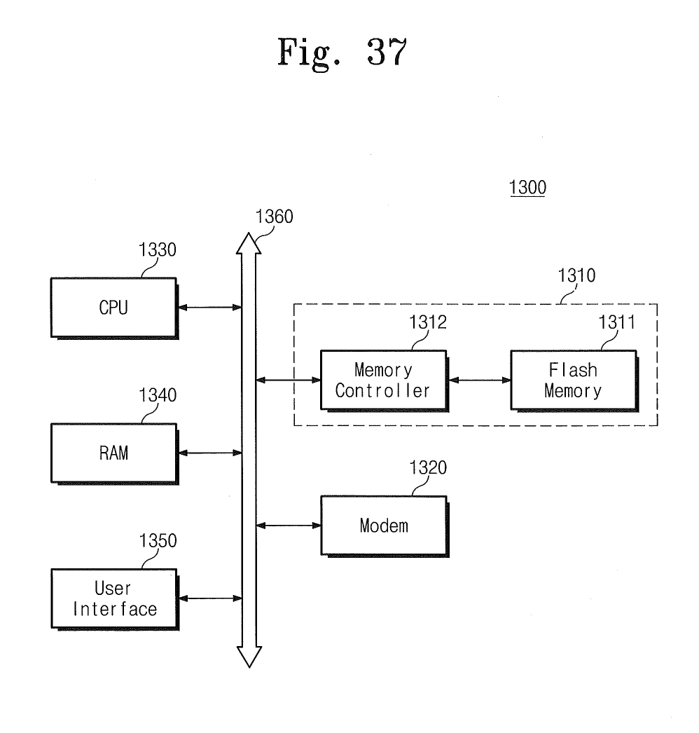

FIG. 37 is a block diagram illustrating an example of an information processing system including a semiconductor memory device according to some embodiments of the inventive subject matter.

Referring to FIG. 37, a flash memory system 1310 of the inventive subject matter is built in a data processing system such as a mobile product or a desk top computer. The data processing system 1300 according to the inventive subject matter includes the flash memory system 1310 and a modem 1320, a central processing unit 1330, a RAM, a user interface 1350 that are electrically connected to a system bus 1360. The flash memory system 1310 may be constructed so as to be identical to the memory system or the flash memory system described above. The flash memory system 1310 stores data processed by the central processing unit 1330 or data inputted from an external device. The flash memory system 1310 may include a solid state disk (SSD) and in this case, the data processing system 1310 can stably store huge amounts of data in the flash memory system 1310. As reliability is improved, the flash memory system 1310 can reduce resources used to correct errors, thereby providing a high speed data exchange function to the data processing system 1300. Even though not depicted in the drawings, it is apparent to one of ordinary skill in the art that the data processing unit 1300 according to some embodiments of the inventive subject matter can further include an application chipset, a camera image processor (CIS) and/or an input/output device.

Semiconductor memory devices or memory systems according to example embodiments of the inventive concepts can be mounted with various types of packages. For example, semiconductor memory devices or memory systems according to example embodiments of the inventive concepts can be packaged in various types of packages, such as package on package (PoP), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multichip package (MCP), wafer-level fabricated package (WFP), wafer-level processed stack package (WSP).

Forming a plurality of vertically stacked memory cells in a cell array region may result in a height difference between structures in the cell array region and structures in a peripheral circuit region. For instance, an interlayer dielectric covering the memory cells may have a different height in the cell array region than in the peripheral circuit region. According to example embodiments of the inventive concepts, a polishing stop layer may be formed before planarizing the interlayer dielectric. The polishing stop layer may reduce or prevent a dishing problem of the interlayer dielectric from occurring on a contact region and/or the peripheral circuit region during the planarization of the interlayer dielectric.

Furthermore, it is possible to reduce or prevent damage from occurring to the contact pads on the semiconductor patterns in the cell array region during planarization of the interlayer dielectric. A process of forming contact plugs and interconnection lines can be performed with a sufficient process margin.

While example embodiments of the inventive concepts have been particularly shown and described, it will be understood by one of ordinary skill in the art that variations in form and detail may be made therein without departing from the spirit and scope of the attached claims.

What is claimed is:

1. A method of manufacturing a semiconductor device, comprising:
providing a substrate including a cell array region and a peripheral circuit region;
forming a peripheral structure including peripheral circuits in the peripheral circuit region and outside the cell array region;
forming a cell structure including first and second layers alternatingly stacked on the substrate in the cell array region, the cell structure having a greater height than the peripheral structure;
forming an interlayer dielectric on the peripheral structure and the cell structure;
forming a polishing stop layer on the interlayer dielectric in the peripheral circuit region and the cell array region; and
planarizing the interlayer dielectric using a portion of the polishing stop layer disposed on the peripheral circuit region as a planarization stop pattern.

2. The method of claim 1, wherein the polishing stop layer comprises a material having a lower removal rate than the interlayer dielectric, during the planarizing of the interlayer dielectric.

3. The method of claim 1, wherein forming the interlayer dielectric comprises depositing an insulating layer having a greater thickness than the stacked layer structure.

4. The method of claim 1, wherein the planarizing of the interlayer dielectric comprises:
removing portions of the interlayer dielectric and the polishing stop layer from the cell array region to form a protruding portion between the cell array region and the peripheral circuit region, the protruding portion having a height greater than the height of the peripheral structure; and
polishing the interlayer dielectric using a chemical mechanical polishing to remove the protruding portion.

5. The method of claim 1, further comprising, before the forming of the interlayer dielectric, forming penetrating structures including semiconductor patterns penetrating the stacked layer structure on the cell array region,
wherein the planarizing of the interlayer dielectric comprises exposing top surfaces of the penetrating structures.

6. The method of claim 5, wherein each of the penetrating structures includes a contact pad disposed on the semiconductor pattern, and planarizing the interlayer dielectric exposes top surfaces of the contact pads.

7. The method of claim 1, further comprising, before forming the interlayer dielectric, forming an etch stop layer on forming the stacked layer structure,
wherein planarizing the interlayer dielectric is performed to expose a top surface of the etch stop layer in the cell array region.

8. The method of claim 1, wherein forming the peripheral structure comprises forming a peripheral insulating pattern in the peripheral circuit region of the substrate over the peripheral circuits.

9. The method of claim 8, wherein forming the cell structure comprises repeatedly patterning the stacked layer structure to sequentially expose top surfaces of the first layers between the cell array region and the peripheral circuit region, and portions of the first and second layers remain on a sidewall of the peripheral insulating pattern adjacent to the cell array region.

10. The method of claim 1, wherein forming the cell structure comprises repeatedly patterning the stacked layer structure to sequentially expose end portions of the first layers between the cell array region and the peripheral circuit region, and
planarizing the interlayer dielectric comprises polishing the interlayer dielectric to form an interlayer insulating pattern covering a portion of the cell structure located between the cell array region and the peripheral circuit region and the peripheral structure disposed on the peripheral circuit region.

11. The method of claim 10, further comprising:
forming contact plugs that vertically penetrate the interlayer insulating pattern and that are connected to the exposed end portions of the first layers, respectively; and
forming interconnection lines that connect to the contact plugs.

12. The method of claim 10, further comprising, before planarizing the interlayer dielectric, forming a buffer insulating layer on the polishing stop layer,
wherein the buffer insulating layer comprises a material having a greater removal rate than the polishing stop layer during the planarizing of the interlayer dielectric.

13. The method of claim 1, further comprising, after the planarizing of the interlayer dielectric, removing the first layers to form recess regions between the second layers; and
forming a data storing layer and a conductive pattern in the recess region.

14. The method of claim 1, wherein the first layer comprises a conductive material and the second layer comprises an insulating material, and the method further comprises forming semiconductor patterns and a data storing layer, before forming the interlayer dielectric, the semiconductor pattern penetrating the stacked layer structure in the cell array region and the data storing layer being interposed between the semiconductor pattern and the stacked layer structure.

15. The method of claim 1, wherein forming the cell structure comprises forming a stacked layer structure including the first and second layers alternatingly stacked on the substrate in the cell array region, and removing the stacked layer structure from the peripheral circuit region.

16. A method of manufacturing a semiconductor device, comprising:
providing a substrate including a cell array region and a peripheral circuit region;
forming a stacked layer structure including first and second layers alternatingly stacked on the substrate, the stacked layer structure including a contact portion interposed between the cell array region and the peripheral circuit region and having a stepwise structure;
forming penetrating structures in the stacked layer structure, each of the penetrating structure including a semiconductor pattern penetrating the stacked layer structure;
forming an interlayer dielectric having a height difference between the cell array region and the peripheral circuit region on the substrate provided with the stacked layer structure;
forming a polishing stop layer on the interlayer dielectric; and
planarizing the interlayer dielectric to form an interlayer insulating pattern on the peripheral circuit region and the contact portion of the stacked layer structure, wherein planarizing the interlayer dielectric is performed using a portion of the polishing stop layer disposed on the peripheral circuit region and top surfaces of the penetrating structures as a planarization stop.

17. The method of claim 15, wherein forming the interlayer dielectric comprises depositing an insulating layer having a greater thickness than the stacked layer structure.

18. The method of claim 15, wherein forming the interlayer insulating pattern comprises:
forming a mask pattern on the polishing stop layer to expose the cell array region;
anisotropically etching the polishing stop layer and the interlayer dielectric using the mask pattern as an etch mask to form a protruding portion between the cell array region and the peripheral circuit region; and
performing a polishing process using the contact pads as a polishing stop to remove the protruding portion.

19. The method of claim 15, further comprising:
forming contact plugs vertically penetrating the interlayer insulating pattern and connected to the contact portions of the first layers, respectively; and
forming interconnection lines connected to the contact plugs.

20. The method of claim 15, further comprising forming a buffer insulating layer on the polishing stop layer, the buffer insulating layer having a greater removal rate than the polishing stop layer during the planarizing of the interlayer dielectric.

21. A method of manufacturing a semiconductor device, comprising:
providing a substrate including a cell array region; a peripheral circuit region, and a contact region interposed between the cell array region and the peripheral circuit region;
forming a peripheral structure including peripheral circuits on the peripheral circuit region;
forming a stacked layer structure including first and second layers alternatingly stacked on the cell array region, the stacked layer structure being thicker than the peripheral structure and comprising a stepwise shaped portion disposed on the contact region;
forming an interlayer dielectric on the peripheral structure and the stacked layer structure;
forming a polishing stop pattern on the interlayer dielectric, the polishing stop pattern extending from the peripheral circuit region to the contact region and disposed over at least a portion of one of the first layers in the contact region; and
planarizing the interlayer dielectric using the polishing stop pattern as a planarization stop.

22. A method of manufacturing a semiconductor device, comprising:
providing a substrate including a cell array region and a peripheral circuit region;
forming a peripheral structure in the peripheral circuit region;
forming a cell structure in the cell array region of the substrate, the cell structure having a greater height than the peripheral structure;
forming a dielectric layer on the peripheral structure and the cell structure;
forming a polishing stop pattern on the dielectric layer over the peripheral structure, wherein the cell array region is free of the polishing stop pattern; and
planarizing the dielectric layer using the polishing stop pattern as a planarization stop.

23. The method of claim 22, wherein forming the dielectric layer comprises depositing an insulating layer having a greater thickness than the stacked layer structure.

24. The method of claim 22, wherein planarizing the dielectric layer comprises:
forming a polishing stop layer on the dielectric layer in the cell array region and in the peripheral circuit region;
selectively removing portions of the dielectric layer and the polishing stop layer in the cell array region to form a protruding portion between the cell array region and the peripheral circuit region; and
polishing the interlayer dielectric using chemical mechanical polishing to remove the protruding portion.

25. The method of claim 22, wherein the cell structure comprises a stacked layer structure, the method further comprising forming penetrating structures including semiconductor patterns that penetrate the stacked layer structure, wherein planarizing the interlayer dielectric comprises exposing top surfaces of the penetrating structures.
